(19) United States
(12) Patent Application Publication
(10) Pub. No.: US 2025/0373284 A1
(43) Pub. Date: Dec. 4, 2025

(54) WIRELINE RECEIVER WITH IMPROVED TIMING AND RELATED MARGINS

(71) Applicant: M31 TECHNOLOGY CORPORATION, Hsinchu County (TW)

(72) Inventors: Po-Chen KUO, Hsinchu County (TW); Huai-Te Wang, Hsinchu County (TW); Zheng-Bin Lou, Hsinchu County (TW); Chih-Huang Lin, Hsinchu County (TW); Shun-Tung Lu, Hsinchu County (TW); Ting-Chun Huang, Hsinchu County (TW)

(21) Appl. No.: 19/304,645

(22) Filed: Aug. 20, 2025

(30) Foreign Application Priority Data
Oct. 7, 2024 (TW) 113138113

(51) Int. Cl. H04B 3/14; H04B 3/23

(52) U.S. Cl. CPC H04B 3/14; H04B 3/232

(57) ABSTRACT

A wireline receiver with improved timing and related margins, may comprise a data sampler, a first edge sampler, a second edge sampler, a base phase detection circuit, an additional phase detection circuit, a clock circuit and a phase shifting circuit. The data sampler, the first edge sampler and the second edge sampler may, when triggered by a data clock, a first edge clock and a second edge clock respectively, sample and compare a receiver signal to determine whether the receiver signal exceeds a data threshold level, a first threshold level and a second threshold level, and may therefore provide basis for phase detection. According to the phase detection, the clock circuit may provide the first edge clock and the data clock, and the phase shifting circuit may provide the second edge clock by phase shifting.

This application claims the benefit of Taiwan application Serial No. 113138113, filed Oct. 7, 2024, the subject matters of which is incorporated herein by reference.

### TECHNICAL FIELD

The present disclosure involves a wireline receiver with improved timing and related margins; more particularly, a wireline receiver which may comprises a data sampler, a first edge sampler and/or a third edge sampler, a second edge sampler, a base phase detection circuit, an additional phase detection circuit, a clock circuit and a phase shifting circuit; wherein the data sampler may, when triggered by a data clock, sample and compare a receiver signal to determine whether the receiver signal exceeds a data threshold level, and may accordingly contribute to forming of a data signal; the first edge sampler and the third edge sampler may, when triggered by a first edge clock, sample and compare the receiver signal to determine whether the receiver signal respectively exceeds a first threshold level and a third threshold level, and may accordingly provide a first edge signal and a third edge signal; the second edge sampler, when triggered by a second edge clock, may sample and compare the receiver signal to determine whether the receiver signal exceeds a second threshold level, and may accordingly provide a second edge signal; the base phase detection circuit may provide a base timing control signal according to the data signal, the second edge signal and at least one of the first edge signal and the third edge signal; the additional phase detection circuit may provide an additional timing control signal according to the data signal and at least one of the first edge signal to the third edge signal; the clock circuit may provide the data clock and the first edge clock according to the base timing control signal, and the phase shifting circuit may provide the second edge clock by performing phase shifting according to the additional timing control signal.

### BACKGROUND

Wireline receivers capable of receiving high speed (high frequency, high rate) signals via physical conductive wires are essential building blocks of modern semiconductor integrated circuits.

### SUMMARY

An objective of the present disclosure is providing a wireline receiver (e.g., 100 in FIG. 1a) with improved timing and related margins; the wireline receiver may comprise a sampler block (e.g., 110, 210, 310, 510, 1400 or 1500 in FIG. 1a, FIG. 2a, FIG. 3a, FIG. 5a, FIG. 14 or FIG. 15a), a phase detection circuit block (e.g., 120, 220, 320, 420, 520, 620, 720, 820, 920, 1020, 1120, 1220 or 1520 in FIG. 1a, FIG. 2a, FIG. 3a, FIG. 4a, FIG. 5a, FIG. 6a, FIG. 7a, FIG. 8a, FIG. 9a, FIG. 10a, FIG. 11a, FIG. 12a or FIG. 15b) and a clock circuit block (130, 230 or 1530 in FIG. 1a, FIG. 2a or FIG. 15c). The sampler block may comprise a data sampler (e.g., sa0 in FIG. 2a, or one of sa01 to sa04 in FIG. 15a), a first edge sampler (e.g., sa1 in FIG. 2a, or one of sale and sa1o in FIG. 15a) and a second edge sampler (e.g., sa2 in FIG. 2a, or one of sa2e and sa2o in FIG. 15a). The phase detection circuit block may comprise a base phase detection circuit (e.g., 222, 322, 422, 522, 622 or 1522 in FIG. 2a, FIG. 3a, FIG. 4a, FIG. 5a, FIG. 6a or FIG. 15b) and an additional phase detection circuit (e.g., 224, 324, 424, 524, 624, 724, 824, 924, 1024, 1124, 1224 or 1524 in FIG. 2a, FIG. 3a, FIG. 4a, FIG. 5a, FIG. 6a, FIG. 7a, FIG. 8a, FIG. 9a, FIG. 10a, FIG. 11a, FIG. 12a or FIG. 15b). The clock circuit block may comprise a clock circuit (e.g., 240 or 1540 in FIG. 2a or FIG. 15c) and a phase shifting circuit (e.g., 250 or 1550 in FIG. 2a or FIG. 15c). The data sampler may, when triggered by a data clock (e.g., ck0 in FIG. 2a, or one of cke and ckOo in FIG. 15a), sample and compare a receiver signal (e.g., sr1 in FIG. 2a, or one of sr1e and sr1o in FIG. 15a) to determine whether the receiver signal exceeds a data threshold level (e.g., L0 in FIG. 2a, or one of +h_1 and −h_1 in FIG. 15a), and may accordingly contribute to forming of a data signal (e.g., sd1 in FIG. 2a or FIG. 15a). The first edge sampler may, when triggered by a first edge clock (e.g., cke1 in FIG. 2a, or one of cke1e and cke1o in FIG. 15a), sample and compare the receiver signal to determine whether the receiver signal exceeds a first threshold level (e.g., L1 in FIG. 2a or FIG. 15a), and may accordingly provide a first edge signal (e.g., x1 in FIG. 2a, or one of x1e and x1o in FIG. 15a). The second edge sampler may, when triggered by a second edge clock (e.g., cke2 in FIG. 2a, or one of cke2e or cke2o in FIG. 15a), sample and compare whether the receiver signal exceeds a second threshold level (e.g., L2 in FIG. 2a or FIG. 15a) f, and may accordingly provide a second edge signal (e.g., x2 in FIG. 2a, or one of x2e and x2o in FIG. 15a). The base phase detection circuit may be coupled to the data sampler, the first edge sampler and the second edge sampler, and may provide a base timing control signal (e.g., scr1 in FIG. 2a or FIG. 15b) according to the data signal, the first edge signal and the second edge signal. The additional phase detection circuit may provide an additional timing control signal (e.g., scr2 in FIG. 2a or FIG. 15b) according to the data signal and at least one of the first edge signal and the second edge signal. The clock circuit may be coupled to the base phase detection circuit, may provide the first edge clock and the data clock according to the base timing control signal, and may cause a phase difference between the data clock and the first edge clock to substantially equal a predetermined base offset value (e.g., d_p0 in FIG. 2b or FIG. 15d). The phase shifting circuit may be coupled to the additional phase detection circuit, may provide the second edge clock by phase shifting, and may cause a phase difference between the second edge clock and the first edge clock to substantially equal an additional offset value (e.g., d_phi in FIG. 2b or FIG. 15d). The first threshold level and the second threshold level may be different, and the additional offset value may be controlled by the additional timing control signal.

In an embodiment (e.g., FIG. 2a to FIG. 2f, or FIG. 15a to FIG. 15d), the base phase detection circuit may comprise a first pattern phase detection unit (e.g., pd1 in FIG. 2a, or one of pd1e and pd1o in FIG. 15b). When the base phase detection circuit provides the base timing control signal according to the data signal, the first edge signal and the second edge signal, if the data signal matches a first pattern (e.g., p1 in FIG. 2a or FIG. 15b), then the first pattern phase detection unit may assert a speed-up message (e.g., UP in FIG. 2c) or a speed-down message (e.g., DN in FIG. 2c) in the base timing control signal according to a current signal value (e.g., x1[i], in FIG. 2b, or one of x1e[i] and x1o[i] in FIG. 15d) of the first edge signal; if the data signal does not match the first pattern, the first pattern phase detection unit may not assert the speed-up message and the speed-down message in the base timing control signal.

In an embodiment (e.g., FIG. 2a to FIG. 2f, or FIG. 15a to FIG. 15d), if three consecutive signal values (e.g., sd1[i−1], sd1[i] and sd1[i+1] in FIG. 2b, or sd1[2i−1], sd1[2i] and sd1[2i+1] in FIG. 15d, or sd1[2i−2], sd1[2i−1] and sd1[2i] also in FIG. 15d) of the data signal equal a first definition value (e.g., H in FIG. 2a), the first definition value and a second definition value (e.g., L in FIG. 2a) respectively, then the data signal matches the first pattern. When the data signal matches the first pattern and the first pattern phase detection unit asserts the speed-up message or the speed-down message in the base timing control signal according to the current signal value of the first edge signal, if the current signal value of the first edge signal equals the second definition value, then the first pattern phase detection unit may assert the speed-up message in the base timing control signal; otherwise, the first pattern phase detection unit may assert the speed-down message in the base timing control signal.

In an embodiment (e.g., FIG. 2a to FIG. 2f, or FIG. 15a to FIG. 15d), when the data sampler samples and compares the receiver signal to determine whether the receiver signal exceeds the data threshold level under triggering of the data clock, and accordingly contributes to forming of the data signal, if it is determined that the receiver signal exceeds the data threshold level, then the data sampler may cause a current signal value (e.g., sd1[i] in FIG. 2b, sd1[2i] in FIG. 15d or sd1[2i−1] also in FIG. 15d) of the data signal to equal the first definition value; otherwise, the data sampler may cause the current signal value of the data signal to equal the second definition value.

In an embodiment (e.g., FIG. 2a to FIG. 2f, or FIG. 15a to FIG. 15d), the wireline receiver may further comprise a third edge sampler (e.g., sa3 in FIG. 2a, or one of sa3e and sa3o in FIG. 15a); the third edge sampler may, when triggered by the first edge clock, sample and compare the receiver signal to determine whether the receiver signal exceeds a third threshold level (e.g., L3 in FIG. 2a or FIG. 15a), and may accordingly provide a third edge signal (e.g., x3 in FIG. 2a, or one of x3e and x3o in or FIG. 15a). The third threshold level may differ from the first threshold level, and may differ from the second threshold level. When the base phase detection circuit provides the base timing control signal according to the data signal, the first edge signal and the second edge signal, the base phase detection circuit may provide the base timing control signal according to the data signal, the first edge signal, the second edge signal and the third edge signal. When the additional phase detection circuit provides the additional timing control signal according to the data signal and at least one of the first edge signal and the second edge signal, the additional phase detection circuit may provide the additional timing control signal according to the data signal and at least one of the first edge signal, the second edge signal and the third edge signal.

In an embodiment (e.g., FIG. 2b), the second threshold level may substantially equal an average of the first threshold level and the third threshold level.

In an embodiment (e.g., FIG. 2a to FIG. 2f, or FIG. 15a to FIG. 15d), the base phase detection circuit may further comprise a third pattern phase detection unit (e.g., pd3 in FIG. 2a, or one of pd3e and pd3o in FIG. 15b). When the base phase detection circuit provides the base timing control signal according to the data signal, the first edge signal, the second edge signal and the third edge signal, if the data signal matches a third pattern (e.g., p3 in FIG. 2a or FIG. 15b), then the third pattern phase detection unit may assert the speed-up message or the speed-down message in the base timing control signal according to a current signal value (e.g., x3[i] in FIG. 2b, or one of x3e[i] and x3o[i] in FIG. 15d) of the third edge signal; if the data signal does not match the third pattern, then the third pattern phase detection unit may not assert the speed-up message and the speed-down message in the base timing control signal.

In an embodiment (e.g., FIG. 2a to FIG. 2f, or FIG. 15a to FIG. 15d), if three consecutive signal values (e.g., sd1[i−1] to sd1[i+1] in FIG. 2b, sd1[2i−1] to sd1[2i+1] in FIG. 15d, or sd1[2i−2] to sd1[2i] also in FIG. 15d) of the data signal equal the second definition value, the second definition value and the first definition value respectively, then the data signal matches the third pattern. When the data signal matches the third pattern and the third pattern phase detection unit asserts the speed-up message or the speed-down message in the base timing control signal according to the current signal value of the third edge signal, if the current signal value of the third edge signal equals the first definition value, then the third pattern phase detection unit may assert the speed-up message in the base timing control signal; otherwise, the third pattern phase detection unit may assert the speed-down message in the base timing control signal.

In an embodiment (e.g., FIG. 2a to FIG. 2f, or FIG. 15a to FIG. 15d), the base phase detection circuit may further comprise a second pattern phase detection unit (e.g., pd2 in FIG. 2a, or one of pd2e and pd2o in FIG. 15b). When the base phase detection circuit provides the base timing control signal according to the data signal, the first edge signal and the second edge signal, if the data signal matches a second pattern (e.g., p2 in FIG. 2a or FIG. 15b), then the second pattern phase detection unit may assert the speed-up message or the speed-down message in the base timing control signal according to a current signal value (e.g., x2[i] in FIG. 2b, or one of x2e[i] and x2o[i] in FIG. 15d) of the second edge signal; if the data signal does not match the second pattern, the second pattern phase detection unit may not assert the speed-up message and the speed-down message in the base timing control signal.

In an embodiment (e.g., FIG. 2a to FIG. 2f, or FIG. 15a to FIG. 15d), if three consecutive signal values (e.g., sd1[i−1] to sd1[i+1] in FIG. 2b, sd1[2i−1] to sd1[2i+1] in FIG. 15d, or sd1[2i−2] to sd1[2i] also in FIG. 15d) of the data signal equal the first definition value, the second definition value and the first definition value respectively, then the data signal matches the second pattern. When the data signal matches the second pattern and the second pattern phase detection unit asserts the speed-up message or the speed-down message in the base timing control signal according to the current signal value of the second edge signal, if the current signal value of the second edge signal equals the first definition value, then the second pattern phase detection unit may assert the speed-up message in the base timing control signal; otherwise, the second pattern phase detection unit may assert the speed-down message in the base timing control signal.

In an embodiment (e.g., FIG. 2a to FIG. 2f, or FIG. 15a to FIG. 15d), the base phase detection circuit may further comprise a fourth pattern phase detection unit (e.g., pd4 in FIG. 2a, or one of pd4e and pd4o in FIG. 15b). When the base phase detection circuit provides the base timing control signal according to data signal, the first edge signal and the second edge signal, if the data signal matches a fourth pattern (e.g., p4), then the fourth pattern phase detection unit may assert the speed-up message or the speed-down message in the base timing control signal according to a current signal value (e.g., x2[i] in FIG. 2b, or one of x2e[i] and x2o[i] in FIG. 15d) of the second edge signal; if the data signal does not match the fourth pattern, the fourth pattern phase detection unit may not assert the speed-up message and the speed-down message in the base timing control signal.

In an embodiment (e.g., FIG. 2a to FIG. 2f, or FIG. 15a to FIG. 15d), if three consecutive signal values (e.g., sd1[i−1] to sd1[i+1] in FIG. 2b, sd1[2i−1] to sd1[2i+1] in FIG. 15d, or sd1[2i−2] to sd1[2i] also in FIG. 15d) of the data signal equal the second definition value, the first definition value and the second definition value respectively, then the data signal matches the fourth pattern. When the data signal matches the fourth pattern and the fourth pattern phase detection unit asserts the speed-up message or the speed-down message in the base timing control signal according to the current signal value of the second edge signal, if the current signal value of the second edge signal equals the second definition value, then the fourth pattern phase detection unit may assert the speed-up message in the base timing control signal; otherwise, the fourth pattern phase detection unit may assert the speed-down message in the base timing control signal.

In an embodiment, the data threshold level and the first threshold level may be substantially equal. In an embodiment, the base offset value may cause the data clock and the first edge clock to be orthogonal; for example, the base offset value may cause the data clock to substantially be an inverted version of the first edge clock.

In an embodiment (e.g., FIG. 9a), the additional phase detection circuit (e.g., 924) may comprise a first counting circuit (e.g., 961). In response to a current signal value (e.g., x1[i]) of the first edge signal, if three associated signal values (e.g., sd1[i−1] to sd1[i+1]) of the data signal equal the first definition value, the first definition value and the second definition value respectively, then the data signal matches the first pattern (e.g., p1). When the data signal matches the first pattern and the current signal value of the first edge signal equals the second definition value, the first counting circuit may increment a first speed-up accumulation count; when the data signal matches the first pattern and the current signal value of the first edge signal equals the first definition value, the first counting circuit may increment a first speed-down accumulation count. When the data signal does not match the first pattern, the first counting circuit may cause the first speed-up accumulation count and the first speed-down accumulation count to remain unchanged. When the first speed-up accumulation count minus the first speed-down accumulation count exceeds a first preset positive value, the additional phase detection circuit may cause the additional offset value to increase, and may cause each of the first speed-up accumulation count and the first speed-down accumulation count to be reset to a reset value. When the first speed-down accumulation count minus the first speed-up accumulation count exceeds a third preset positive value, the additional phase detection circuit may cause the additional offset value to decrease, and may cause each of the first speed-up accumulation count and the first speed-down accumulation count to be reset to the reset value. When the first speed-up accumulation count minus the first speed-down accumulation count does not exceed the first preset positive value and the first speed-down accumulation count minus the first speed-up accumulation count does not exceed the third preset positive value, the additional phase detection circuit may cause the additional offset value to remain unchanged, and may cause the first speed-up accumulation count and the first speed-down accumulation count not to be reset.

In an embodiment (e.g., FIG. 7a), the additional phase detection circuit (e.g., 724) may comprise a first counting circuit (e.g., 761). In response to a current signal value (e.g., x1[i]) of the first edge signal, if three associated signal values (e.g., sd1[i−1] to sd1[i+1]) of the data signal equal the first definition value, the first definition value and the second definition value respectively, then the data signal matches the first pattern (e.g., p1). If the three associated signal values of the data signal equal the second definition value, the second definition value and the first definition value respectively, then the data signal matches the third pattern (e.g., p3). When the data signal matches the first pattern and the current signal value of the first edge signal equals the second definition value, the first counting circuit may increment a first speed-up accumulation count; when the data signal matches the first pattern and the current signal value of the first edge signal equals the first definition value, the first counting circuit may increment a first speed-down accumulation count. When the data signal matches the third pattern and a current signal value (e.g., x3[i]) of the third edge signal equals the first definition value, the first counting circuit may increment the first speed-up accumulation count; if the data signal matches the third pattern and the current signal value of the third edge signal equals the second definition value, the first counting circuit may increment the first speed-down accumulation count. When the data signal does not match the first pattern and does not match the third pattern, the first counting circuit may cause the first speed-up accumulation count and the first speed-down accumulation count to remain unchanged. When the first speed-up accumulation count minus the first speed-down accumulation count exceeds a first preset positive value, the additional phase detection circuit may cause the additional offset value to increase, and may cause each of the first speed-up accumulation count and the first speed-down accumulation count to be reset to a reset value. When the first speed-down accumulation count minus the first speed-up accumulation count exceeds a third preset positive value, the additional phase detection circuit may cause the additional offset value to decrease, and may cause each of the first speed-up accumulation count and the first speed-down accumulation count to be reset to the reset value. When the first speed-up accumulation count minus the first speed-down accumulation count does not exceed the first preset positive value and the first speed-down accumulation count minus the first speed-up accumulation count does not exceed the third preset positive value, the additional phase detection circuit may cause the additional offset value to remain unchanged, and may cause the first speed-up accumulation count and the first speed-down accumulation count not to be reset.

In an embodiment (e.g., FIG. 10a), the additional phase detection circuit (e.g., 1024) may comprise a second counting circuit (e.g., 1062). In response to a current signal value of the second edge signal (e.g., x2[i]), if three associated signal values (e.g., sd1[i−1] to sd1[i+1]) of the data signal equal the first definition value, the second definition value and the first definition value respectively, then the data signal matches the second pattern (e.g., p2). When the data signal matches the second pattern and the current signal value of the second edge signal equals the first definition value, the second counting circuit may increment a second speed-up accumulation count; when the data signal matches the second pattern and the current signal value of the second edge signal equals the second definition value, the second counting circuit may increment a second speed-down accumulation count. When the data signal does not match the second pattern, the second counting circuit may cause the second speed-up accumulation count and the second speed-down accumulation count to remain unchanged. When the second speed-up accumulation count minus the second speed-down accumulation count exceeds a second preset positive value, the additional phase detection circuit may cause the additional offset value to decrease, and may cause each of the second speed-up accumulation count and the second speed-down accumulation count to be reset to a reset value. When the second speed-down accumulation count minus the second speed-up accumulation count exceeds a fourth preset positive value, the additional phase detection circuit may cause the additional offset value to increase, and may cause each of the second speed-up accumulation count and the second speed-down accumulation count to be reset to the reset value. When the second speed-up accumulation count minus the second speed-down accumulation count does not exceed the second preset positive value and the second speed-down accumulation count minus the second speed-up accumulation count does not exceed the fourth preset positive value, the additional phase detection circuit may cause the additional offset value to remain unchanged, and may cause the second speed-up accumulation count and the second speed-down accumulation count not to be reset.

In an embodiment (e.g., FIG. 8a), the additional phase detection circuit (e.g., 824) may comprise a second counting circuit (e.g., 862). In response to a current signal value of the second edge signal (e.g., x2[i]), if three associated signal values (e.g., sd1[i−1] to sd1[i+1]) of the data signal equal the first definition value, the second definition value and the first definition value respectively, then the data signal matches the second pattern (e.g., p2). If the three associated signal values of the data signal equal the second definition value, the first definition value and the second definition value respectively, then the data signal matches the fourth pattern (p4). When the data signal matches the second pattern and the current signal value of the second edge signal equals the first definition value, the second counting circuit may increment a second speed-up accumulation count; when the data signal matches the second pattern and the current signal value of the second edge signal equals the second definition value, the second counting circuit may increment a second speed-down accumulation count. When the data signal matches the fourth pattern and the current signal value of the second edge signal equals the second definition value, the second counting circuit may increment the second speed-up accumulation count; when the data signal matches the fourth pattern and the current signal value of the second edge signal equals the first definition value, the second counting circuit may increment the second speed-down accumulation count. When the data signal does not match the second pattern and does not match the fourth pattern, the second counting circuit may cause the second speed-up accumulation count and the second speed-down accumulation count to remain unchanged. When the second speed-up accumulation count minus the second speed-down accumulation count exceeds a second preset positive value, the additional phase detection circuit may cause the additional offset value to decrease, and may cause each of the second speed-up accumulation count and the second speed-down accumulation count to be reset to a reset value. When the second speed-down accumulation count minus the second speed-up accumulation count exceeds a fourth preset positive value, the additional phase detection circuit may cause the additional offset value to increase, and may cause each of the second speed-up accumulation count and the second speed-down accumulation count to be reset to the reset value. When the second speed-up accumulation count minus the second speed-down accumulation count does not exceed the second preset positive value and the second speed-down accumulation count minus the second speed-up accumulation count does not exceed the fourth preset positive value, the additional phase detection circuit may cause the additional offset value to remain unchanged, and may cause the second speed-up accumulation count and the second speed-down accumulation count not to be reset.

In an embodiment (e.g., FIG. 3a), the additional phase detection circuit (e.g., 324) may comprise a first counting circuit (e.g., 361) and a second counting circuit (e.g., 362). In response to a current signal value (e.g., x1[i]) of the first edge signal, if three associated signal values (e.g., sd1[i−1], sd1[i], sd1[i+1]) of the data signal equal the first definition value, the first definition value and the second definition value respectively, then the data signal matches the first pattern (e.g., p1). When the data signal matches the first pattern and the current signal value of the first edge signal equals the second definition value, the first counting circuit may increment a first speed-up accumulation count; when the data signal matches the first pattern and the current signal value of the first edge signal equals the first definition value, the first counting circuit may increment a first speed-down accumulation count. When the data signal does not match the first pattern, the first counting circuit may cause the first speed-up accumulation count and the first speed-down accumulation count to remain unchanged. In response to a current signal value (e.g., x2[i]) of the second edge signal, if the three associated signal values (e.g., sd1[i−1] to sd1[i+1]) of the data signal equal a third definition value (e.g., H), a fourth definition value (e.g., L) and the third definition value respectively, then the data signal matches the second pattern (e.g., p2). When the data signal matches the second pattern and the current signal value of the second edge signal equals the third definition value, the second counting circuit may increment a second speed-up accumulation count; when the data signal matches the second pattern and the current signal value of the second edge signal equals the fourth definition value, the second counting circuit may increment a second speed-down accumulation count. When the data signal does not match the second pattern, the second counting circuit may cause the second speed-up accumulation count and the second speed-down accumulation count to remain unchanged. When the first speed-up accumulation count minus the first speed-down accumulation count exceeds a first preset positive value and the second speed-down accumulation count minus the second speed-up accumulation count exceeds a fourth preset positive value, the additional phase detection circuit may cause the additional offset value to increase, and may cause each of the first speed-up accumulation count, the first speed-down accumulation count, the second speed-up accumulation count and the second speed-down accumulation count to be reset to a reset value. When the first speed-down accumulation count minus the first speed-up accumulation count exceeds a third preset positive value and the second speed-up accumulation count minus the second-down accumulation count exceeds a second preset positive value, the additional phase detection circuit may cause the additional offset value to decrease, and may cause each of the first speed-up accumulation count, the first speed-down accumulation count, the second speed-up accumulation count and the second speed-down accumulation count to be reset to the reset value. When an occasion other than above two happens, the additional phase detection circuit may cause the additional offset value to remain unchanged, and may cause the first speed-up accumulation count, the first speed-down accumulation count, the second speed-up accumulation count and the second speed-down accumulation count not to be reset. That is, when the first speed-down accumulation count minus the first speed-up accumulation count does not exceed the third preset positive value, or when the first speed-up accumulation count minus the first speed-down accumulation count does not exceed the first preset positive value, or when the second speed-up accumulation count minus the second speed-down accumulation count does not exceed the second preset positive value, or when the second speed-down accumulation count minus the second speed-up accumulation count does not exceed the fourth preset positive value, the additional phase detection circuit may cause the additional offset value to remain unchanged, and may cause the first speed-up accumulation count, the first speed-down accumulation count, the second speed-up accumulation count and the second speed-down accumulation count not to be reset.

In an embodiment (e.g., FIG. 2a), the additional phase detection circuit (e.g., 224) may comprise a first counting circuit (e.g., 261) and a second counting circuit (e.g., 262). In response to a current signal value (e.g., x1[i]) of the first edge signal, if three associated signal values (e.g., sd1[i−1], sd1[i], sd1[i+1]) of the data signal equal the first definition value, the first definition value and the second definition value respectively, then the data signal matches the first pattern (e.g., p1); if the three associated signal values of the data signal equal the second definition value, the second definition value and the first definition value respectively, then the data signal matches the third pattern (e.g., p3). When the data signal matches the first pattern and the current signal value of the first edge signal equals the second definition value, the first counting circuit may increment a first speed-up accumulation count; when the data signal matches the first pattern and the current signal value of the first edge signal equals the first definition value, the first counting circuit may increment a first speed-down accumulation count. When the data signal matches the third pattern and a current signal value (e.g., x3[i]) of the third edge signal equals the first definition value, the first counting circuit may increment the first speed-up accumulation count; when the data signal matches the third pattern and the current signal value of the third edge signal equals the second definition value, the first counting circuit may increment the first speed-down accumulation count. When the data signal does not match the first pattern and does not match the third pattern, the first counting circuit may cause the first speed-up accumulation count and the first speed-down accumulation count to remain unchanged. Moreover, in response to a current signal value (e.g., x2[i]) of the second edge signal, if three associated signal values (e.g., sd1[i−1], sd1[i], sd1[i+1]) of the data signal equal the first definition value, the second definition value and the first definition value respectively, then the data signal matches the second pattern (e.g., p2); if the three associated signal values of the data signal equal the second definition value, the first definition value and the second definition value respectively, then the data signal matches the fourth pattern (e.g., p4). When the data signal matches the second pattern and the current signal value of the second edge signal equals the first definition value, the second counting circuit may increment a second speed-up accumulation count; when the data signal matches the second pattern and the current signal value of the second edge signal equals the second definition value, the second counting circuit may increment a second speed-down accumulation count. When the data signal matches the fourth pattern and the current signal value of the second edge signal equals the second definition value, the second counting circuit may increment the second speed-up accumulation count; when the data signal matches the fourth pattern and the current signal value of the second edge signal equals the first definition value, the second counting circuit may increment the second speed-down accumulation count. When the data signal does not match the second pattern and does not match the fourth pattern, the second counting circuit may cause the second speed-up accumulation count and the second speed-down accumulation count to remain unchanged. When the first speed-up accumulation count minus the first speed-down accumulation count exceeds a first preset positive value and the second speed-down accumulation count minus the second speed-up accumulation count exceeds a fourth preset positive value, the additional phase detection circuit may cause the additional offset value to increase, and may cause each of the first speed-up accumulation count, the first speed-down accumulation count, the second speed-up accumulation count and the second speed-down accumulation count to be reset to a reset value. When the first speed-down accumulation count minus the first speed-up accumulation count exceeds a third preset positive value and the second speed-up accumulation count minus the second speed-down accumulation count exceeds a second preset positive value, the additional phase detection circuit may cause the additional offset value to decrease, and may cause each of the first speed-up accumulation count, the first speed-down accumulation count, the second speed-up accumulation count and the second speed-down accumulation count to be reset to the reset value. When an occasion other than above two happens, the additional phase detection circuit may cause the additional offset value to remain unchanged, and may cause the first speed-up accumulation count, the first speed-down accumulation count, the second speed-up accumulation count and the second speed-down accumulation count not to be reset. That is, when the first speed-down accumulation count minus the first speed-up accumulation count does not exceed the third preset positive value, or when the first speed-up accumulation count minus the first speed-down accumulation count does not exceed the first preset positive value, or when the second speed-up accumulation count minus the second speed-down accumulation count does not exceed the second preset positive value, or when the second speed-down accumulation count minus the second speed-up accumulation count does not exceed the fourth preset positive value, the additional phase detection circuit may cause the additional offset value to remain unchanged, and may cause the first speed-up accumulation count, the first speed-down accumulation count, the second speed-up accumulation count and the second speed-down accumulation count not to be reset.

An objective of the present disclosure is providing a method applied to an wireline receiver for improving timing and related margins; the method may comprise following operations: a data sampling, at least one of a first edge sampling and a third edge sampling, a second edge sampling, at least one of a first pattern phase detection to a fourth pattern phase detection, a base phase detection, an additional phase detection, a base timing adjustment and an additional timing adjustment. The data sampling may comprise: when triggered by one or more data clocks (e.g., ck0 in FIG. 2a, or, ck0e and ck0o in FIG. 15a), sampling and comparing one or more receiver signals (e.g., sr1 in FIG. 2a, or, sr1e and sr1o in FIG. 15a) to determine whether the one or more receiver signals exceed one or more data threshold levels (e.g., L0 in FIG. 2a, or, +h_1 and −h_1 in FIG. 15a) respectively, and accordingly provide a data signal (e.g., sd1). The first edge sampling may comprise: when triggered by one or more first edge clocks (e.g., cke1 in FIG. 2a, or, cke1e and cke1o in FIG. 15a), sampling and comparing the one or more receiver signals to determine whether the one or more receiver signals exceed a first threshold level (e.g., L1), and accordingly providing one or more first edge signals (e.g., x1 in FIG. 2a, or, x1e and x1o FIG. 15a) respectively. The second edge sampling may comprise: when triggered by one or more second edge clocks (e.g., cke2 in FIG. 2a, or, cke2e and cke2o in FIG. 15a), sampling and comparing the one or more receiver signals to determine whether the one or more receiver signals exceed a second threshold level (e.g., L2), and accordingly providing one or more second edge signals (e.g., x2 in FIG. 2a, or, x2e and x2o in FIG. 15a) respectively. The third edge sampling may comprise: when triggered by the one or more first edge clocks, sampling and comparing the one or more receiver signals to determine whether the one or more receiver signals exceed a third threshold level (e.g., L3), and accordingly providing one or more third edge signals (e.g., x3 in FIG. 2a, or, x3e and x3o in FIG. 15a) respectively. The first threshold level, the second threshold level and the third threshold level may not be equal.

The one or more first edge signals (e.g., x1 in FIG. 2a, or, x1e and x1o in FIG. 15a) may be associated with one or more first pattern phase detection signals (e.g., ud1 in FIG. 2a, or, ud1e and ud1o in FIG. 15a) respectively, and the first pattern phase detection may comprise: in response to a current signal value (e.g., x1[i], x1e[i] or x1o[i]) of a certain first edge signal (e.g., x1, x1e or x1o) of the one or more first edge signals, if a plurality of associated signal values (e.g., sd1[i−1] to sd1[i+1], sd1[2i−1] to sd1[2i+1], or, sd1[2i−2] to sd1[2i]) of the data signal match a plurality of first component values (e.g., three definition values H, H, L) which a first pattern comprises, then asserting a speed-up message or a speed-down message in the first pattern phase detection signal associated with the certain first edge signal according to whether the current signal value of the certain first edge signal equals a last one of the plurality of first component values; if the plurality of associated signal values of the data signal do not match the plurality of first component values, then not asserting anyone of the speed-up message and the speed-down message in the first pattern phase detection signal associated with the certain first edge signal.

The one or more second edge signals (e.g., x2 in FIG. 2a, or, x2e and x2o in FIG. 15a) may be associated with one or more second pattern phase detection signals (e.g., ud2 in FIG. 2a, or, ud2e and ud2o in FIG. 15a) respectively, and may also be associated with one or more fourth pattern phase detection signals (e.g., ud4 in FIG. 2a, or, ud4e and ud4o in FIG. 15a) respectively. The second pattern phase detection may comprise: in response to a current signal value (e.g., x2[i], x2e[i] or x2o[i]) of a certain second edge signal (e.g., x2, x2e or x2o) of the one or more second edge signals, if a plurality of associated signal values (e.g., sd1[i−1] to sd1[i+1], sd1[2i−1] to sd1[2i+1], or, sd1[2i−2] to sd1[2i]) of the data signal match a plurality of second component values (e.g., three definition values H, L, H) which a second pattern comprises, then asserting the speed-up message or the speed-down message in the second pattern phase detection signal associated with the certain second edge signal according to whether the current signal value of the certain second edge signal equals a last one of the plurality of second component values; if the plurality of associated signal values of the data signal do not match the plurality of the second component values, then not asserting anyone of the speed-up message and the speed-down message in the second pattern phase detection signal associated with the certain second edge signal. The fourth pattern phase detection may comprise: in response to the current signal value of the certain second edge signal, if the plurality of associated signal values of the data signal match a plurality of fourth component values (e.g., three definition values L, H, L) which a fourth pattern comprises, then asserting the speed-up message or the speed-down message in the fourth pattern phase detection signal associated with the certain second edge signal according to whether the current signal value of the certain second edge signal equals a last one of the plurality of fourth component values; if the plurality of associated signal values of the data signal do not match the plurality of fourth component values, then not asserting anyone of the speed-up message and the speed-down message in the fourth pattern phase detection signal associated with the certain second edge signal.

The one or more third edge signals (e.g., x3 in FIG. 2a, or, x3e and x3o in FIG. 15a) may be associated with one or more third pattern phase detection signals (e.g., ud3 in FIG. 2a, or, ud3e and ud3o in FIG. 15a) respectively, and the third pattern phase detection may comprise: in response to a current signal value (e.g., x3[i], x3e[i] or x3o[i]) of a certain third edge signal (e.g., x3, x3e or x3o) of the one or more third edge signals, if a plurality of associated signal values (e.g., sd1[i−1] to sd1[i+1], sd1[2i−1] to sd1[2i+1], or, sd1[2i−2 to sd1[2i]) of the data signal match a plurality of third component values (e.g., three definition values L, L, H) which a third pattern comprises, then asserting the speed-up message or speed-down message in the third pattern phase detection signal associated with the certain third edge signal according to whether the current signal value of the certain third edge signal equals a last one of the plurality of third component values; if the plurality of associated signal values of the data signal do not match the plurality of third component values, then not asserting anyone of the speed-up message and the speed-down message in the third pattern phase detection signal associated with the certain third edge signal.

The base phase detection may be associated with a base signal subset; the base signal subset may comprise at least one of the one or more first pattern phase detection signals and the one or more third pattern phase detection signals, and may further comprise at least one of the one or more second pattern phase detection signals and the one or more fourth pattern phase detection signals. The base phase detection may comprise: if anyone of the base signal subset has a said speed-up message being asserted, then asserting a corresponding speed-up message in a base timing control signal (e.g., scr1); if anyone of the base signal subset has a said speed-down message being asserted, then asserting a corresponding speed-down message in the base timing control signal. The one or more data clocks may be associated with the one or more first edge clocks, respectively. The base timing adjustment may comprise: providing the one or more data clocks and the one or more first edge clocks according to the base timing control signal, such that the one or more data clocks and the one or more first edge clocks may substantially be of a same frequency controlled by the base timing control signal, and a phase difference between each data clock and its associated first edge clock may substantially equal a predetermined base offset value (e.g., d_p0).

The one or more second edge clocks may be associated with the one or more first edge clocks, respectively. The additional timing adjustment may comprise: performing phase shifting to provide the one or more second edge clocks, such that the one or more second edge clocks and the one or more first edge clocks may substantially be of a same frequency, and a phase difference between each said second edge clock and its associated first edge clock may substantially equal an additional offset value (e.g., d_phi).

The additional phase detection may comprise one or both of a first counting operation and a second counting operation, and may further comprise an additional internal operation. The first counting operation may be associated with a first signal subset, and the first signal subset may comprise at least one of the one or more first pattern phase detection signals and the one or more third pattern phase detection signals. The first counting operation may comprise: if anyone of the first signal subset has a said speed-up message being asserted, then incrementing a first count (e.g., cnt1) by a step value (e.g., d1); if anyone of the first signal subset has a said speed-down message being asserted, then decrementing the first count by the step value; if each of the first signal subset does not have a said speed-up message being asserted and does not have a said speed-down message being asserted, then causing the first count to remain unchanged. The second counting operation may be associated with a second signal subset, and the second signal subset may comprise at least one of the one or more second pattern phase detection signals and the one or more fourth pattern phase detection signals. The second counting operation may comprise: if anyone of the second signal subset has a said speed-up message being asserted, then incrementing a second count (e.g., cnt2) by the step value; if anyone of the second signal subset has a said speed-down message being asserted, then decrementing the second count by the step value; if each of the second signal subset does not have a said speed-up message being asserted and does not have a said speed-down message being asserted, then causing the second count to remain unchanged.

In an embodiment (e.g., FIG. 7a, FIG. 9a or FIG. 11a), the additional internal operation (e.g., FIG. 7c) may comprise: when the first count is greater than an upper bound value (e.g., c_U in FIG. 2f), increasing the additional offset value, and resetting the first count to an initial value (e.g., c_0 in FIG. 2f); when the first count is less than a lower bound value (e.g., c_D in FIG. 2f), decreasing the additional offset value, and resetting the first count to the initial value; and, when the first count is not greater than the upper bound value and is not less than the lower bound value, keeping the additional offset value unchanged, and not resetting the first count. In another embodiment (e.g., FIG. 8a, FIG. 10a or FIG. 12a), the additional internal operation (e.g., FIG. 8c) may comprise: when the second count is less than the lower bound value, increasing the additional offset value, and resetting the second count to the initial value; when the second count is greater than the upper bound value, decreasing the additional offset value, and resetting the second count to the initial value; and, when the second count is not greater than the upper bound value and is not less than the lower bound value, keeping the additional offset value unchanged, and not resetting the second count.

In still another embodiment (e.g., FIG. 2a, FIG. 3a, FIG. 4a, FIG. 5a or FIG. 6a), the additional internal operation (e.g., FIG. 2e) may comprise: when the first count is greater than the upper bound value and the second count is less than the lower bound value, increasing the additional offset value, and resetting the first count and the second count to the initial value; when the first count is less than lower bound value and the second count is greater than the upper bound value, decreasing the additional offset value, and resetting the first count and the second count to the initial value; when an occasion other than the above two happens, keeping the additional offset value unchanged, and not resetting the first count and the second count. The upper bound value may be greater than the initial value, and the initial value may be greater than the lower bound value; moreover, the second preset positive value mentioned earlier may equal the first preset positive value, the fourth preset positive value may equal the third preset positive value, the upper bound value may equal the initial value plus a multiplication of the step value and the first preset positive value (e.g., c_U=c_0+d1*pv1, with pv1 representing the first preset positive value), the lower bound value may equal the initial value minus a multiplication of the step value and the third preset positive value (e.g., c_D=c_0−d1*pv3, with pv3 representing the third preset positive value).

Numerous objects, features and advantages of the present disclosure will be readily apparent upon a reading of the following detailed description of embodiments of the present disclosure when taken in conjunction with the accompanying drawings. However, the drawings employed herein are for the purpose of descriptions and should not be regarded as limiting.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1a depicts a wireline receiver according to an embodiment of the present disclosure, wherein the wireline receiver may comprise a sampler block, a phase detection circuit block and a clock circuit block, etc.;

FIG. 1b depicts an eye diagram of a received signal;

FIG. 2a depicts, according to an embodiment of the present disclosure, a sampler block, a phase detection circuit block and a clock circuit block which may respectively implement the sampler block, the phase detection circuit block and the clock circuit block in the wireline receiver shown in FIG. 1a, wherein the phase detection circuit block in FIG. 2a may comprise a base phase detection circuit and an additional phase detection circuit;

FIG. 2b depicts waveform and timing embodiments of related signals and clocks shown in FIG. 2a;

FIG. 2c depicts an operation embodiment of the base phase detection circuit shown in FIG. 2a;

FIG. 2d and FIG. 2e depict an operation embodiment of the additional phase detection circuit shown in FIG. 2a;

FIG. 2f depicts an example of operations of the additional phase detection circuit shown in FIG. 2a;

FIG. 3a depicts, according to an embodiment of the present disclosure, a sampler block, a phase detection circuit block and a clock circuit block which may respectively implement corresponding blocks in the wireline receiver shown in FIG. 1a, wherein the phase detection circuit block in FIG. 3a may comprise a base phase detection circuit and an additional phase detection circuit;

FIG. 3b depicts an operation embodiment of the base phase detection circuit shown in FIG. 3a;

FIG. 3c depicts an operation embodiment of the additional phase detection circuit shown in FIG. 3a;

FIG. 4a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 4a may comprise a base phase detection circuit and an additional phase detection circuit;

FIG. 4b depicts an operation embodiment of the base phase detection circuit shown in FIG. 4a;

FIG. 4c depicts an operation embodiment of the additional phase detection circuit shown in FIG. 4a;

FIG. 5a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 5a may comprise a base phase detection circuit and an additional phase detection circuit;

FIG. 5b depicts an operation embodiment of the base phase detection circuit shown in FIG. 5a;

FIG. 5c depicts an operation embodiment of the additional phase detection circuit shown in FIG. 5a;

FIG. 6a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 6a may comprise a base phase detection circuit and an additional phase detection circuit;

FIG. 6b depicts an operation embodiment of the base phase detection circuit shown in FIG. 6a;

FIG. 6c depicts an operation embodiment of the additional phase detection circuit shown in FIG. 6a;

FIG. 7a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 7a may comprise a base phase detection circuit and an additional phase detection circuit;

FIG. 7b and FIG. 7c depict an operation embodiment of the additional phase detection circuit shown in FIG. 7a;

FIG. 8a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 8a may comprise a base phase detection circuit and an additional phase detection circuit;

FIG. 8b and FIG. 8c depict an operation embodiment of the additional phase detection circuit shown in FIG. 8a;

FIG. 9a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 9a may comprise a base phase detection circuit and an additional phase detection circuit;

FIG. 9b depicts an operation embodiment of the additional phase detection circuit shown in FIG. 9a;

FIG. 10a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 10a may comprise a base phase detection circuit and an additional phase detection circuit;

FIG. 10b depicts an operation embodiment of the additional phase detection circuit shown in FIG. 10a;

FIG. 11a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 11a may comprise a base phase detection circuit and an additional phase detection circuit;

FIG. 11b depicts an operation embodiment of the additional phase detection circuit shown in FIG. 11a;

FIG. 12a depicts, according to an embodiment of the present disclosure, a sampler block, a phase detection circuit block and a clock circuit block which may respectively implement corresponding blocks in the wireline receiver shown in FIG. 1a, wherein the phase detection circuit block shown in FIG. 12a may comprise a base phase detection circuit and an additional phase detection circuit;

FIG. 12b depicts an operation embodiment of the additional phase detection circuit shown in FIG. 12a;

FIG. 13a to FIG. 13c depict clock circuit blocks according to different embodiments of the present disclosure;

FIG. 14 depicts, according to an embodiment of the present disclosure, a circuit block which may implement related blocks in the wireline receiver shown in FIG. 1a;

FIG. 15a depicts, according to an embodiment of the present disclosure, a circuit block which may implement related blocks in the wireline receiver shown in FIG. 1a;

FIG. 15b depicts, according to an embodiment of the present disclosure, a phase detection circuit block which may implement corresponding block in the wireline receiver shown in FIG. 1a;

FIG. 15c depicts, according to an embodiment of the present disclosure, a clock circuit block which may implement corresponding block in the wireline receiver shown in FIG. 1a; and

FIG. 15d depicts waveform and timing embodiments of related signals and clocks shown in FIG. 15a.

### DETAILED DESCRIPTION OF PREFERRED EMBODIMENTS

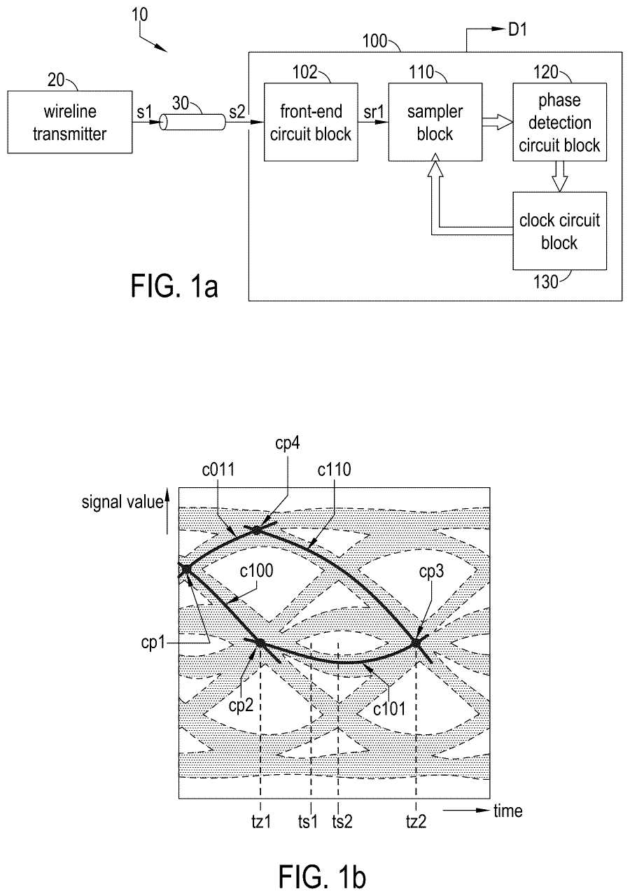

FIG. 1a illustrates a wireline transceiver system 10 according to an embodiment of the present disclosure; the wireline transceiver system 10 may comprise a wireline transmitter 20, a transmission line 30 and a wireline receiver 100. The transmission line 30 may comprise one or more physical conductive wires. When transmitting data, the wireline transmitter 20 may drive voltage changes on the transmission line 30 according to serial symbols of the data, and may therefore form an electrical signal s1; the signal s1 may be transmitted to the wireline receiver 100 via the transmission line 30 to form a signal s2. The wireline receiver 100 may receive the signal s2, may recognize (recover) symbols of the data in the received signal, and may accordingly provide a data signal D1. In an embodiment, the wireline transceiver system 10 may be a data transceiver system of embedded clock; that is, the wireline transmitter 20 may not provide any data clock regarding timing of individual symbol for the wireline receiver 100, and the wireline receiver 100 may therefore need to implement clock and data recovery for reconstructing a data clock from the received signal, and discriminating each symbol from the received signal by sampling under triggering of the data clock.

In an embodiment, the wireline transmitter 20 and the wireline receiver 100 may respectively reside in two semiconductor devices of two different packages; the two semiconductor devices may be disposed on a printed circuit board, and conductive wiring of the printed circuit board may function as the transmission line 30. In another embodiment, the wireline transmitter 20 and the wireline receiver 100 may respectively be two semiconductor circuits packaged in a same package (e.g., packaged in a same system chip).

Due to channel characteristics of the transmission line 30, the received signal of the wireline receiver 100 not only suffers noise and jitter, but also suffers interference(s), such as inter-symbol interference. For efficiency of data transmission, the wireline transmitter 20 may transmit electrical signal of high speed, but electrical signal of high speed is more sensitive to noise, jitter and interference(s). Therefore, how the wireline receiver 100 can effectively overcome noise, jitter and interference(s) which degrade high speed signal reception is important for development of modern semiconductor circuitry technology.

FIG. 1b illustrates an eye diagram of a received signal, with a horizontal axis denoting time and a vertical axis denoting signal value (in, e.g., voltage). In FIG. 1b, a shaded region represents a region which a waveform of the received signal may possibly pass through, and curves c011, c100, c101 and c110 represent various possible waveforms of the received signal. For example, if three consecutive symbols of the received signal are respectively binary 1, 1, 0, then the waveform of the received signal may look like the curve c110; if three consecutive symbols of the received signal are respectively 1, 0, 1, then the waveform of the received signal may look like the curve c101. In FIG. 1b, points cp1, cp2, cp3 and cp4 represent intersections of said four curves. From FIG. 1b, it is noted that the curves c011, c100, c101 and c110 surround an eye-shaped region at the four points cp1 to cp4; the eye-shaped region centers at a time point ts1 along the horizontal time axis, meaning that the time point ts1 is a preferred time point for data sampling. That is, when the wireline receiver 100 reconstructs the data clock from the received signal and discriminates symbols by sampling under triggering of the data clock, if timing of the data clock aligns the time point ts1, then correctness of the symbol discrimination will be effectively raised, jitter will be lowered, and margin(s) related to timing and margin(s) related to signal value (e.g., margin(s) along the vertical axis of the eye diagram) will also be expanded. However, it is difficult for currently known prior arts to align timing of the data clock with the time point ts1 when reconstructing the data clock. For example, as shown in FIG. 1b, when a typical prior art reconstructs the data clock, the resultant data clock may trigger sampling at a time point ts2, i.e., a center of two time points tz1 and tz2, with the time points tz1 and tz2 respectively being locations of the points cp2 and cp3 along the time axis. As shown in FIG. 1b, the time point ts2 deviates from the preferred sampling time point ts1, so the typical prior art suffers larger jitter and narrower margins related to timing and signal value.

As shown in FIG. 1a, to implement the present disclosure, the wireline receiver 100 may comprise a front-end circuit block 102, a sampler block 110, a phase detection circuit block 120 and a clock circuit block 130. The front-end circuit block 102 may perform preliminary signal process on the signal s2 (e.g., filtering and amplifying, etc.), and may accordingly provide a signal sr1; for example, the front-end circuit block 102 may comprise linear equalizer(s) (e.g., continuous-time linear equalizer(s)) and/or variable gain amplifier(s). Structures and operations of the sampler block 110, the phase detection circuit block 120 and the clock circuit block 130 will be described by following embodiments.

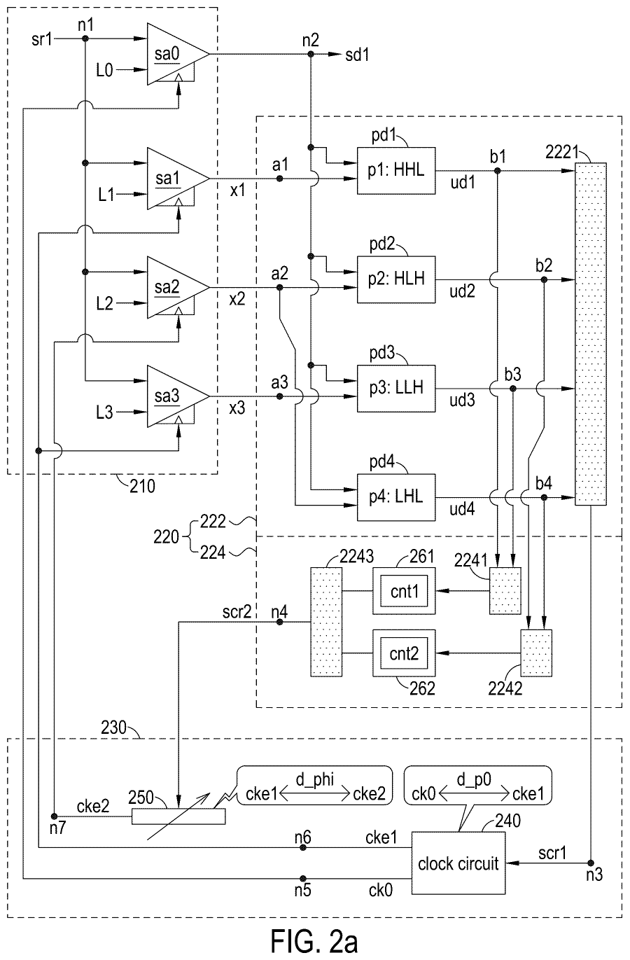

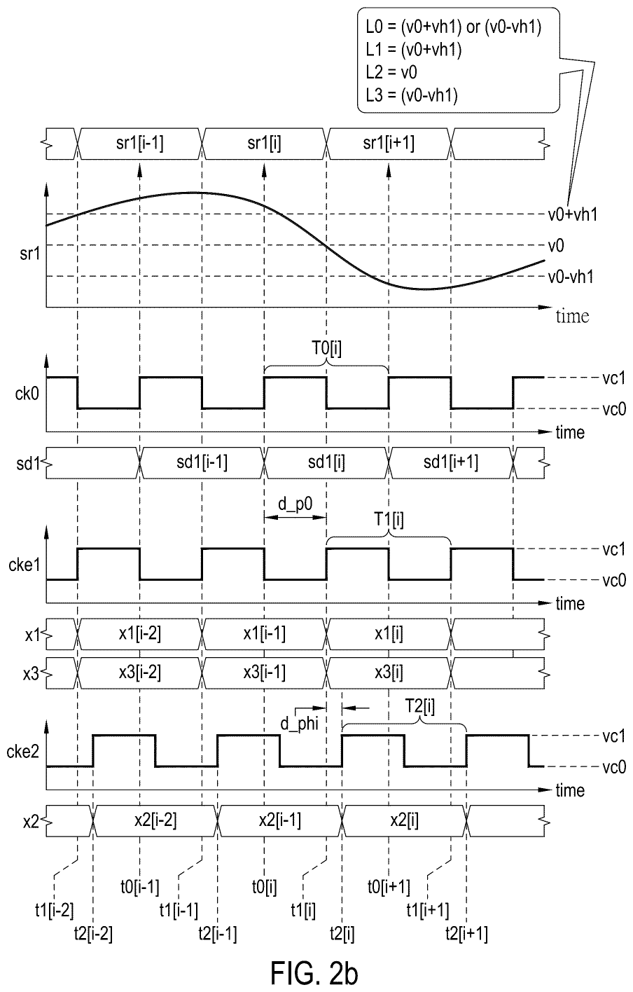

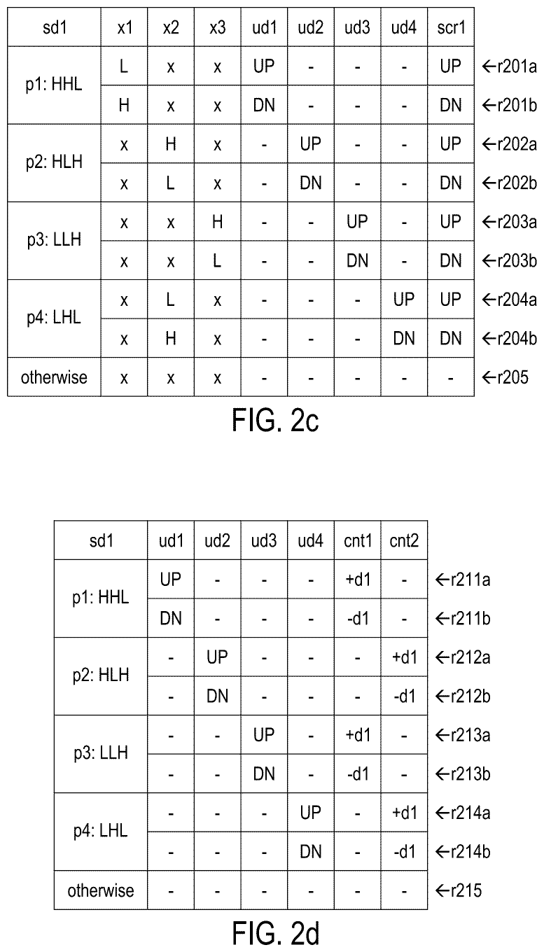

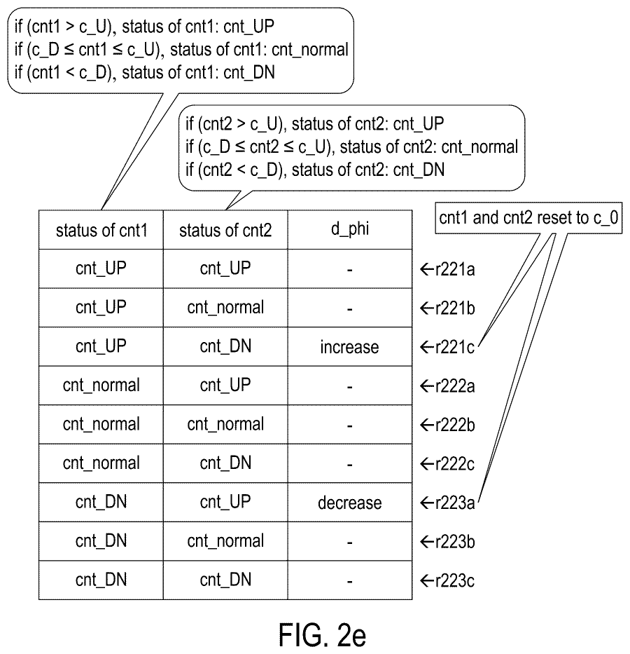

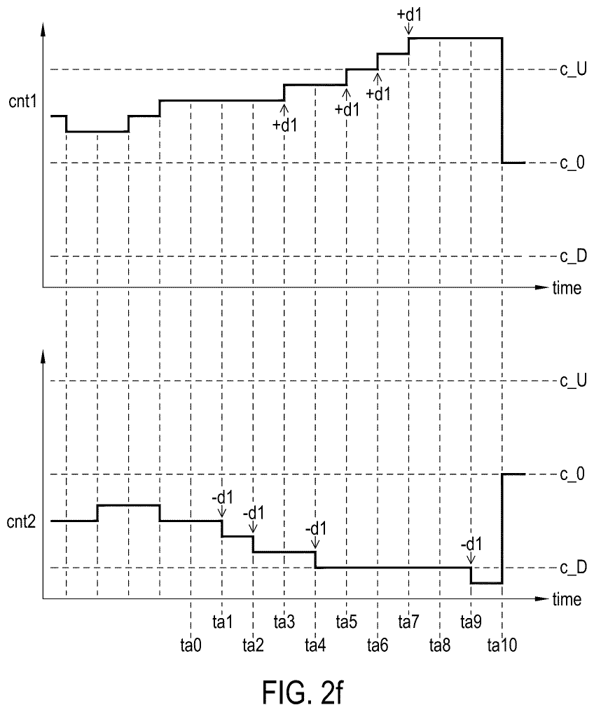

FIG. 2a illustrates a sampler block 210, a phase detection circuit block 220 and a clock circuit block 230 according to an embodiment of the present disclosure; the sampler block 210, the phase detection circuit block 220 and the clock circuit block 230 may implement the sampler block 110, the phase detection circuit block 120 and the clock circuit block 130 shown in FIG. 1a, respectively. As shown in FIG. 2a, the sampler block 210 may comprise four samplers sa0 to sa3. The sampler sa0 may comprise a signal input terminal, a clock input terminal, a threshold level input terminal and an output terminal respectively coupled to two nodes n1 and n5, a threshold level L0 and another node n2. The sampler sa1 may comprise a signal input terminal, a clock input terminal, a threshold level input terminal and an output terminal respectively coupled to the node n1, a node n6, a threshold level L1 and another node a1. The sampler sa2 may comprise a signal input terminal, a clock input terminal, a threshold level input terminal and an output terminal respectively coupled to the node n1, a node n7, a threshold level L2 and another node a2. The sampler sa3 may comprise a signal input terminal, a clock input terminal, a threshold level input terminal and an output terminal, respectively coupled to the node n1, the node n6, a threshold level L3 and another node a3. The node n1 may be further coupled to the signal sr1 (also shown in FIG. 1a).

As shown in FIG. 2a, the phase detection circuit block 220 may comprise two phase detection circuits 222 and 224. The phase detection circuit 222 may comprise four pattern phase detection units pd1 to pd4 and an internal circuit 2221. The pattern phase detection unit pd1 may comprise a data input terminal, a signal input terminal and an output terminal respectively coupled to the node n2, the node a1 and another node b1. The pattern phase detection unit pd2 may comprise a data input terminal, a signal input terminal and an output terminal respectively coupled to the node n2, the node a2 and another node b2. The pattern phase detection unit pd3 may comprise a data input terminal, a signal input terminal and an output terminal respectively coupled to the node n2, the node a3 and another node b3. The pattern phase detection unit pd4 may comprise a data input terminal, a signal input terminal and an output terminal respectively coupled to the node n2, the node a2 and another node b4. The internal circuit 2221 may comprise four input terminals and an output terminal respectively coupled to the nodes b1 to b4 and another node n3. The phase detection circuit 224 may comprise two counting circuits 261, 262 and three internal circuits 2241, 2242 and 2243. The internal circuit 2241 may comprise two input terminals and an output terminal respectively coupled to the node b1, the node b3 and the counting circuit 261. The internal circuit 2242 may comprise two input terminals and an output terminal respectively coupled to the node b2, the node b4 and the counting circuit 262.

The internal circuit 2243 may be coupled to the counting circuit 261, the counting circuit 262 and a node n4.

As shown in FIG. 2a, the clock circuit block 230 may comprise a clock circuit 240 and a phase shifting circuit 250. The clock circuit 240 may comprise a control input terminal and two clock output terminals respectively coupled to the nodes n3, n5 and n6. The phase shifting circuit 250 may comprise a control input terminal and a clock output terminal respectively coupled to the nodes n4 and n7. The clock circuit 240 may be controlled by a signal scr1 at the node n3, and may provide two clocks ck0 and cke1 respectively at the nodes n5 and n6 according to the signal scr1. When the clock circuit 240 provides the clocks ck0 and cke1, the clock circuit 240 may cause frequencies of the clocks ck0 and cke1 to be equal, and may cause a phase difference between the clocks ck0 and cke1 to equal a predetermined offset value d_p0. In an embodiment, the clock circuit 240 may control frequency (and/or phase) of the clock cke1 according to signal value of the signal scr1, and may shift phase of the clock cke1 to form the clock ck0; for example, the clock circuit 240 may invert the clock cke1 to form the clock ck0, such that the clocks ck0 and cke1 may be of inverted phases. In an embodiment, the clock circuit 240 may control frequency (and/or phase) of the clock ck0 according to signal value of the signal scr1, and may shift phase of the clock ck0 to form the clock cke1; for example, the clock circuit 240 may invert the clock ck0 to form the clock cke1. The phase shifting circuit 250 may be controlled by a signal scr2 at the node n4, and may provide the clock cke2 by phase shifting. When the phase shifting circuit 250 provides the clock cke2, the phase shifting circuit 250 may cause frequencies of the clocks cke1 and cke2 to be equal, and may cause a phase difference between the clocks cke2 and cke1 to equal an offset value d_phi, wherein the offset value d_phi may be controlled by the signal scr2.

Following FIG. 2a, FIG. 2b illustrates timing and waveform examples of related signals and clocks shown in FIG. 2a. As shown in FIG. 2b, each of the clocks ck0, cke1 and cke2 resulting from the clock circuit block 230 may periodically alternate between two levels vc0 and vc1, wherein time points t0[i−1], to [i] and to [i+1] may respectively represent three time points when three consecutive significant edges (e.g., edges changing from the levels vc0 to vc1) of the clock ck0 happen, and an interval between the two consecutive significant edge time points to [i] and to [i+1] may be a period T0[i] of the clock ck0. Moreover, time points t1[i−2], t1[i−1], t1[i] and t1[i+1] may represent consecutive four significant edges of the clock cke1, and an interval between the two consecutive significant edge time points t1[i] and t1[i+1] may be a period T1[i] of the clock cke1. Furthermore, time points t2[i−1], t2[i] and t2[i+1] may represent three consecutive significant edges of the clock cke2, and an interval between the consecutive two significant edge time points t2[i] and t2[i+1] may be a period T2[i] of the clock cke2. As mentioned above, in an embodiment, the clock circuit 240 may cause periods of the clocks ck0 and cke1 to be equal (e.g., may cause time spans of the periods T0[i] and T1[i] to be equal), and may cause the phase difference between the two clocks to equal the offset value d_p0, e.g., 180 degrees. Also, periods of the clocks cke2 and cke1 may be equal, e.g., time spans of the periods T2[i] and T1[i] may be equal.

Back to FIG. 2a; in the sampler block 210, the sampler sa0 may, when triggered by the clock ck0, sample and compare the signal sr1 to determine whether the signal sr1 exceeds the threshold level L0, and may accordingly provide a signal sd1 at the node n2. In an embodiment, the sampler sa0 may sample and compare whether the signal sr1 is higher than the threshold level L0 at each significant edge of the clock ck0 (e.g., at each of the time points to [i−1], to [i], to [i+1] shown in FIG. 2b), and may accordingly determine a corresponding signal value of the signal sd1 (e.g., each of signal values sd1[i−1], sd1[i], sd1[i+1] shown in FIG. 2b). For example, at the significant edge time point to [i] of the clock ck0, if the sampler sa0 samples that the signal sr1 is higher (greater) than the threshold level L0, the sampler sa0 may cause the corresponding signal value sd1[i] of the signal sd1 to equal a definition value H (e.g., logic 1); if the sampler sa0 samples that the signal sr1 is lower (less) than the threshold level L0, the sampler sa0 may cause the signal value sd1[i] of the signal sd1 to equal another definition value L (e.g., logic 0). In an embodiment, when performing the sampling and comparing, the sampler sa0 may first sample the signal sr1, and then compare whether the sampled result exceeds the threshold level L0; in another embodiment, when performing the sampling and comparing, the sampler sa0 may continuously compare whether the signal sr1 exceeds threshold level L0 to generate a continuous time comparison result, and may sample the comparison result.

As shown in FIG. 2b, a swing range of the signal sr1 may extend upward (to be positive) and downward (to be negative) from a center level v0 (e.g., zero volts) along the vertical axis, e.g., the signal sr1 may result from subtraction of a pair of differential signals. In an embodiment, the threshold level L0 may equal a level (v0+vh1) or a level (v0−vh1), wherein the level vh1 may be a constant level. At the significant edge time point to [i−1] of the clock ck0, the sampler sa0 may sample and compare whether the signal sr1 exceeds the threshold level L0; in the example shown in FIG. 2b, the signal sr1 is higher than the threshold level L0 at the time point to [i−1], so the sampler sa0 may cause the corresponding signal value sd1[i−1] of the signal sd1 to equal the definition value H. At the next significant edge time point to [i] of the clock ck0, the sampler sa0 may sample and compare whether the signal sr1 exceeds the threshold level L0 again; in the example shown in FIG. 2b, the signal sr1 is still higher than the threshold level L0 at the time point to [i], so the sampler sa0 may cause the corresponding signal value sd1[i] of the signal sd1 to equal the definition value H. Afterward, at the subsequent significant edge time point to [i+1] of the clock ck0, the sampler sa0 may once again sample and compare whether the signal sr1 exceeds the threshold level L0; in the example shown in FIG. 2b, the signal sr1 is lower than the threshold level L0 at the time point to [i+1], so the sampler sa0 may cause the corresponding signal value sd1[i+1] of the signal sd1 to change to the definition value L. The signal values of the signal sd1 may represent symbols discriminated from the signal sr1 by the wireline receiver 100 (FIG. 1a); i.e., the wireline receiver 100 shown in FIG. 1a may provide the data signal D1 (FIG. 1a) according to the signal sd1.

In the sampler block 210 shown in FIG. 2a, the sampler sa1 may, when triggered by the clock cke1, sample and compare the signal sr1 to determine whether the signal sr1 exceeds the threshold level L1, and may accordingly provide a signal x1 at the node a1. In an embodiment, the sampler sa1 may sample and compare whether the signal sr1 is higher than the threshold level L1 at each significant edge of the clock cke1 (e.g., at each of the time points t1[i−2], t1[i−1], t1[i] shown in FIG. 2b), and may according determine a corresponding signal value of the signal x1 (e.g., each of signal values x1[i−2], x1[i−1], x1[i] shown in FIG. 2b). For example, at the significant edge time point t1[i] of the clock cke1, if the sampler sa1 samples that the signal sr1 is higher than the threshold level L1, the sampler sa1 may cause the corresponding signal value x1[i] of the signal x1 to equal the definition value H; if the sampler sa1 samples that the signal sr1 is lower than the threshold level L1, the sampler sa1 may cause the signal value x1[i] of the signal x1 to equal the definition value L.

In the sampler block 210, the sampler sa2 may, when triggered by the clock cke2, sample and compare the signal sr1 to determine whether the signal sr1 exceeds the threshold level L2, and may accordingly provide a signal x2 at the node a2. In an embodiment, the sampler sa2 may sample and compare whether the signal sr1 is higher than the threshold level L2 at each significant edge of the clock cke2 (e.g., at each of the time points t2[i−2], t2[i−1], t2[i] shown in FIG. 2b), and may accordingly determine a corresponding signal value of the signal x2 (e.g., each of signal values x2[i−2], x2[i−1], x2[i] shown in FIG. 2b). For example, at the significant edge time point t2[i] of the cke2, if the sampler sa2 samples that the signal sr1 is higher than the threshold level L2, the sampler sa2 may cause the corresponding signal value x2[i] of the signal x2 to equal the definition value H; if the sampler sa2 samples that the signal sr1 is lower than threshold level L2, the sampler sa2 may cause the signal value x2[i] of the signal x2 to equal the definition value L.

In the sampler block 210, the sampler sa3 may, when triggered by the clock cke1, sample and compare the signal sr1 to determine whether the signal sr1 exceeds the threshold level L3, and may accordingly provide a signal x3 at the node a3. In an embodiment, the sampler sa3 may sample and compare whether the signal sr1 is higher than the threshold level L3 at each significant edge of the clock cke1 (e.g., at each of the time points t1[i−2], t1[i−1], t1[i] shown in FIG. 2b), and may accordingly determine a corresponding signal value of the signal x3 (e.g., each of signal values x3[i−2], x3[i−1], x3[i] shown in FIG. 2b). For example, at the significant edge time point t1[i] of the clock cke1, if the sampler sa3 samples that the signal sr1 is higher than the threshold level L3, the sampler sa3 may cause the corresponding signal value x3[i] of the signal x3 to equal the definition value H; if the sampler sa3 samples that the signal sr1 is lower than the threshold level L3, the sampler sa3 may cause the signal value x3[i] of the signal x3 to equal the definition value L.

In an embodiment, the threshold levels L1, L2 and L3 of the sampler sa1, sa2 and sa3 may be different; in an embodiment, the threshold level L1 may be higher than the threshold level L2, and the threshold level L2 may be higher than the threshold level L3. In an embodiment, the threshold level L2 may equal an average of the threshold levels L1 and L3 (i.e., L2=(L1+L3)/2). In an embodiment, the threshold level L0 of the sampler sa0 may equal the threshold level L1 or L3. As shown in FIG. 2b, in an embodiment, the threshold levels L1, L2 and L3 may respectively equal the levels (v0+vh1), v0 and (v0−vh1).

In the phase detection circuit block 220 shown in FIG. 2a, the phase detection circuit 222 may provide the signal scr1 at the node n3 according to the signal sd1 and the signals x1 to x3, and the phase detection circuit 224 may provide the signal scr2 at the node n4 according to the signal sd1 and the signals x1 to x3. Following FIG. 2a, FIG. 2c illustrates an operation embodiment of the phase detection circuit 222 by lists. In the phase detection circuit 222, the pattern phase detection unit pd1 may compare whether the signal sd1 matches a pattern p1, and may provide a signal ud1 at the node b1 according to the pattern comparison result and signal value of the signal x1. The pattern p1 may comprise three component values respectively equal to the definition values H, H and L. In response to the current signal value x1[i] of the signal x1, if three associated signal values sd1[i−1], sd1[i] and sd1[i+1] of the signal sd1 respectively equal the three definition values H, H and L of the pattern p1, then the pattern phase detection unit pd1 may determine that the signal sd1 matches the pattern p1, and may assert a speed-up message UP or a speed-down message DN (FIG. 2c) in the signal ud1 according to whether the current signal value x1[i] equals the definition values L or H; on the other hand, if the three associated signal values sd1[i−1], sd1[i] and sd1[i+1] of the signal sd1 do not equal the three definition values H, H and L of the pattern p1, then the pattern phase detection unit pd1 may determine that the signal sd1 does not match the pattern p1, and may not assert anyone of the speed-up message UP and the speed-down message DN in the signal ud1, regardless of what the signal value x1[i] equals.

In the phase detection circuit 222, the pattern phase detection unit pd2 may compare whether the signal sd1 matches a pattern p2, and may provide a signal ud2 at the node b2 according to the pattern comparison result and signal value of the signal x2. In an embodiment, the pattern p2 may comprise three component values respectively equal to the definition values H, L and H. In response to the current signal value x2[i] of the signal x2, if three associated signal values sd1[i−1], sd1[i] and sd1[i+1] of the signal sd1 respectively equal the three definition values H, L and H of the pattern p2, then the pattern phase detection unit pd2 may determine that the signal sd1 matches the pattern p2, and may assert a said speed-up message UP or a said speed-down message DN in the signal ud2 according to whether the current signal value x2[i] equals the definition value H or L; on the other hand, if the three associated signal values sd1[i−1], sd1[i] and sd1[i+1] of the signal sd1 do not equal the three definition values H, L and H of the pattern p2, then the pattern phase detection unit pd2 may determine that the signal sd1 does not match the pattern p2, and may not assert anyone of the speed-up message UP and the speed-down message DN in the signal ud2, regardless of what the current signal value x2[i] equals.

In the phase detection circuit 222, the pattern phase detection unit pd3 may compare whether the signal sd1 matches a pattern p3, and may provide a signal ud3 at the node b3 according to the pattern comparison result and signal value of the signal x3. In an embodiment, the pattern p3 may comprise three component values respectively equal to the definition values L, L and H. In response to the current signal value x3[i] of the signal x3, if three associated signal values sd1[i−1], sd1[i] and sd1[i+1] of the signal sd1 respectively equal the three definition values L, L and H of the pattern p3, then the pattern phase detection unit pd3 may determine that the signal sd1 matches the pattern p3, and may assert a said speed-up message UP or a said speed-down message DN in the signal ud3 according to whether the current signal value x3[i] equals the definition value H or L; on the other hand, if the three associated signal values sd1[i−1], sd1[i] and sd1[i+1] of the signal sd1 do not equal the three definition values L, L and H of the pattern p3, then the pattern phase detection unit pd3 may determine that the signal sd1 does not match the pattern p3, and may not assert anyone of the speed-up message UP and the speed-down message DN in the signal ud3, regardless of what the current signal value x3[i] equals.

In the phase detection circuit 222, the pattern phase detection unit pd4 may compare whether the signal sd1 matches a pattern p4, and may provide a signal ud4 at the node b4 according to the pattern comparison result and signal value of the signal x2. In an embodiment, the pattern p4 may comprise three component values respectively equal to the definition values L, H and L. In response to the current signal value x2[i] of the signal x2, if three associated signal values sd1[i−1], sd1[i] and sd1[i+1] of the signal sd1 respectively equal the three definition values L, H and L of the pattern p4, then the pattern phase detection unit pd4 may determine that the signal sd1 matches the pattern p4, and may assert a said speed-up message UP or a said speed-down message DN in the signal ud4 according to whether the current signal value x2[i] equals the definition value L or H; on the other hand, if the three associated signal values sd1[i−1], sd1[i] and sd1[i+1] of the signal sd1 do not equal the three definition values L, H and L of the pattern p4, then the pattern phase detection unit pd4 may determine that the signal sd1 does not match the pattern p4, and may not assert anyone of the speed-up message UP and the speed-down message DN in the signal ud4, regardless of what the signal value x2[i] equals.

In the phase detection circuit 222, the internal circuit 2221 may control the signal scr1 according to the signals ud1 to ud4. When anyone of the signals ud1 to ud4 has a said speed-up message UP being asserted, the internal circuit 2221 may responsively assert a said speed-up message UP in the signal scr1; when anyone of the signals ud1 to ud4 has a said speed-down message DN being asserted, the internal circuit 2221 may responsively assert a said speed-down message DN in the signal scr1. In other words, the internal circuit 2221 may aggregate the signals ud1 to ud4 to the signal scr1; by the internal circuit 2221, the pattern phase detection unit pd1 may assert a said speed-up message UP or a said speed-down message DN in the signal scr1 according to what the signal value of the signal x1 equals when the signal sd1 matches the pattern p1, the pattern phase detection unit pd2 may assert a said speed-up message UP or a said speed-down message DN in the signal scr1 according to what the signal value of the signal x2 equals when the signal sd1 matches the pattern p2, the pattern phase detection unit pd3 may assert a said speed-up message UP or a said speed-down message DN in the signal scr1 according to what the signal value of the signal x3 equals when the signal sd1 matches the pattern p3, and the pattern phase detection unit pd4 may assert a said speed-up message UP or a said speed-down message DN in the signal scr1 according to what the signal value of the signal x2 equals when the signal sd1 matches the pattern p4; on the other hand, if the signal sd1 does not match anyone of the patterns p1 to p4, all the pattern phase detection units pd1 to pd4 may not assert anyone of the speed-up message UP and the speed-down message DN in the signal scr1.

As shown by rows (horizontal lists) r201a and r201b of FIG. 2c, when the signal sd1 matches the pattern p1, the pattern phase detection unit pd1 in the phase detection circuit 222 may assert the speed-up message UP or the speed-down message DN in the signal ud1 according to whether the current signal value of the signal x1 equals the definition value L or H, and may therefore cause the internal circuit 2221 to assert the speed-up message UP or the speed-down message DN in the signal scr1; on the other hand, since the signal sd1 does not match the patterns p2 to p4, the pattern phase detection units pd2 to pd4 may not assert anyone of the speed-up message UP and the speed-down message DN respectively in the signals ud2 to ud4 (with “−” denoting “do not assert” in FIG. 2c), regardless of what the signal values of the signals x2 and x3 equal (with “x” denoting “do not care” in FIG. 2c).

Similarly, as shown by rows r202a and r202b of FIG. 2c, when the signal sd1 matches the pattern p2, the pattern phase detection unit pd2 in the phase detection circuit 222 may assert the speed-up message UP or the speed-down message DN in the signal ud2 according to whether the current signal value of the signal x2 equals the definition value H or L, and may therefore cause the internal circuit 2221 to assert the speed-up message UP or the speed-down message DN in the signal scr1; on the other hand, since the signal sd1 does not match the patterns p1, p3 and p4, the pattern phase detection units pd1, pd3 and pd4 may not assert anyone of the speed-up message UP and the speed-down message DN respectively in the signals ud1, ud3 and ud4, regardless of what the signal values of the signals x1, x2 and x3 equal.

As shown by rows r203a and r203b of FIG. 2c, when the signal sd1 matches the pattern p3, the pattern phase detection unit pd3 in the phase detection circuit 222 may assert the speed-up message UP or the speed-down message DN in the signal ud3 according to whether the current signal value of the signal x3 equals the definition value H or L, and may therefore cause the internal circuit 2221 to assert the speed-up message UP or the speed-down message DN in the signal scr1; on the other hand, since the signal sd1 does not match the patterns p1, p2 and p4, the pattern phase detection units pd1, pd2 and pd4 may not assert anyone of the speed-up message UP and the speed-down message DN respectively in the signals ud1, ud2 and ud4, regardless of what the signal values of the signals x1 and x2 equal.

As shown by rows r204a and r204b of FIG. 2c, when signal sd1 matches the pattern p4, the pattern phase detection unit pd4 in the phase detection circuit 222 may assert the speed-up message UP or the speed-down message DN in the signal ud4 according to whether the current signal value of the signal x2 equals the definition value L or H, and may therefore cause the internal circuit 2221 to assert the speed-up message UP or the speed-down message DN in the signal scr1; on the other hand, since the signal sd1 does not match the patterns p1 to p3, the pattern phase detection units pd1 to pd3 may not assert anyone of the speed-up message UP and the speed-down message DN respectively in the signals ud1 to ud3, regardless of what the signal values of the signals x1, x2 and x3 equal.

As shown by a row r205 of FIG. 2c, when the signal sd1 does not match anyone of the patterns p1 to p4, the pattern phase detection units pd1 to pd4 may not assert any one of the speed-up message UP and the speed-down message DN respectively in the signals ud1 to ud4 regardless of what the signal values of the signals x1 to x3 equal, and may therefore cause the internal circuit 2221 not to assert anyone of the speed-up message UP and the speed-down message DN in the signal scr1.

In the phase detection circuit 224, the internal circuit 2241 may control the counting circuit 261 according to the signals ud1 and ud3, so as to accumulate a total number of times the speed up message UP is asserted in the signals ud1 and ud3 (referred to as a first speed-up accumulation count hereinafter), and a total number of times the speed-down message DN is asserted in the signals ud1 and ud3 (referred to as a first speed-down accumulation count). When the signal ud1 has a said speed-up message UP being asserted, the internal circuit 2241 may cause the counting circuit 261 to increment the first speed-up accumulation count by one; when the signal ud1 has a said speed-down message DN being asserted, the internal circuit 2241 may cause the counting circuit 261 to increment the first speed-down accumulation count by one. Moreover, when the signal ud3 has a said speed-up message UP being asserted, the internal circuit 2241 may cause the counting circuit 261 to increment the first speed-up accumulation count by one; when the signal ud3 has a said speed-down message DN being asserted, the internal circuit 2241 may cause the counting circuit 261 to increment the first speed-down accumulation count by one. In other words, whenever a said speed-up message UP is asserted in anyone of the signals ud1 and ud3, the counting circuit 261 may increment the first speed-up accumulation count by one; whenever a said speed-down message DN is asserted in anyone of the signals ud1 and ud3, the counting circuit 261 may increment the first speed-down accumulation count by one. On the other hand, when none of the speed-up message UP and the speed-down DN is asserted in anyone of the signals ud1 and ud3, the counting circuit 261 may cause the first speed-up accumulation count and the first speed-down accumulation count to remain unchanged.

In the phase detection circuit 224, the internal circuit 2242 may control the counting circuit 262 according to the signals ud2 and ud4, so as to accumulate a total number of times the speed-up message UP is asserted in the signals ud2 and ud4 (referred to as a second speed-up accumulation count hereinafter), and a total number of times the speed-down message DN is asserted in the signals ud2 and ud4 (referred to as a second speed-down accumulation count hereinafter). When the signal ud2 has a said speed-up message UP being asserted, the internal circuit 2242 may cause the counting circuit 262 to increment the second speed-up accumulation count by one; when the signal ud2 has a said speed-down message DN being asserted, the internal circuit 2242 may cause the counting circuit 262 to increment the second speed-down accumulation count by one. Moreover, when the signal ud4 has a said speed-up message UP being asserted, the internal circuit 2242 may cause the counting circuit 262 to increment the second speed-up accumulation count by one; when the signal ud4 has a said speed-down message DN being asserted, the internal circuit 2242 may cause the counting circuit 262 to increment the second speed-down accumulation count by one. In other words, whenever a said speed-up message UP is asserted in anyone of the signals ud2 and ud4, the counting circuit 262 may increment the second speed-up accumulation count by one; whenever a said speed-down message DN is asserted in anyone of the signals ud2 and ud4, the counting circuit 262 may increment the second speed-down accumulation count by one. On the other hand, when none of the speed-up message UP and the speed-down message DN is asserted in anyone of the signals ud2 and ud4, the counting circuit 262 may cause the second speed-up accumulation count and the second speed-down accumulation count to remain unchanged.

In the phase detection circuit 224, the internal circuit 2243 may control the offset value d_phi of the phase shifting circuit 250 according to accumulation results of the counting circuits 261 and 262. If the first speed-up accumulation count (i.e., total number of times the speed-up message UP is asserted in the signals ud1 and ud3) of the counting circuit 261 minus the first speed-down accumulation count (i.e., total number of times the speed-down message DN is asserted in the signals ud1 and ud3) of the counting circuit 261 exceeds a first preset positive value, and the second speed-down accumulation count (i.e., total number of times the speed-down message DN is asserted in the signals ud2 and ud4) of the counting circuit 262 minus the second speed-up accumulation count (i.e., total number of times the speed-up message UP is asserted in the signals ud2 and ud4) of the counting circuit 262 exceeds a fourth preset positive value, then the internal circuit 2243 may cause the offset value d_phi to increase (increment), and may reset each of the first speed-up accumulation count, the first speed-down accumulation count, the second speed-up accumulation count and the second speed-down accumulation count of the counting circuits 261 and 262 to a reset value (e.g., zero). Moreover, if the first speed-down accumulation count of the counting circuit 261 minus the first speed-up accumulation count of the counting circuit 261 exceeds a third preset positive value, and the second speed-up accumulation count of the counting circuit 262 minus the second speed-down accumulation count of the counting circuit 262 exceeds a second preset positive value, then the internal circuit 2243 may cause the offset value d_phi to decrease (decrement), and may reset each of the first speed-up accumulation count, the first speed-down accumulation count, the second speed-up accumulation count and the second speed-down accumulation count of the counting circuits 261 and 262 to the reset value. On the other hand, if the first speed-up accumulation count minus the first speed-down accumulation count does not exceed the first preset positive value, or the first speed-down accumulation count minus the first speed-up accumulation count does not exceed the third preset positive value, then the internal circuit 2243 may cause the offset value d_phi to remain unchanged, regardless of what the second speed-up accumulation count and the second speed-down accumulation count equal; and, the internal circuit 2243 may not reset the first speed-up accumulation count, the first speed-down accumulation count, the second speed-up accumulation count and the second speed-down accumulation count. Similarly, if the second speed-down accumulation count minus the second speed-up accumulation count does not exceed the fourth preset positive value, or the second speed-up accumulation count minus the second speed-down accumulation count does not exceed the second preset positive value, then the internal circuit 2243 may cause the offset value d_phi to remain unchanged, regardless of what the first speed-up accumulation count and the first speed-down accumulation count equal; and, the internal circuit 2243 may not reset the first speed-up accumulation count, the first speed-down accumulation count, the second speed-up accumulation count and the second speed-down accumulation count.

Following FIG. 2a to FIG. 2c, FIG. 2d illustrates an operation embodiment of the counting circuits 261 and 262 by lists. As shown by rows r211a and r213a of FIG. 2d, in an embodiment of the present disclosure, whenever a said speed-up message UP is asserted in either one of the signals ud1 and ud3, the internal circuit 2241 may cause the counting circuit 261 to increment a count cnt1 by a predetermined step value d1 (which may be a positive value, e.g., +1); and, as shown by rows r211b and r213b of FIG. 2d, whenever a said speed-down message DN is asserted in either one of the signals ud1 and ud3, the internal circuit 2241 may cause the counting circuit 261 to decrement the count cnt1 by the step value d1. Moreover, as shown by rows r212a, r212b, r214a, r214b and r215 of FIG. 2d, when none of the speed-up message UP and the speed-down message DN is asserted in the signals ud1 and ud3, the counting circuit 261 may cause the count cnt1 to remain unchanged (denoted by “−” in FIG. 2d). Therefore, the count cnt1 may reflect the total number of times the speed-up message UP is asserted in the signals ud1 and ud3 minus the total number of times the speed-down message DN is asserted in the signals ud1 and ud3, i.e., the first speed-up accumulation count minus the first speed-down accumulation count.

Similarly, as shown by the rows r212a and r214a of FIG. 2d, in an embodiment of the present disclosure, whenever a said speed-up message UP is asserted in either one of the signals ud2 and ud4, the internal circuit 2242 may cause the counting circuit 262 to increment a count cnt2 by the step value d1; as shown by the rows r212b and r214b of FIG. 2d, whenever a said speed-down message DN is asserted in either one of the signals ud2 and ud4, the internal circuit 2242 may cause the counting circuit 262 to decrement the count cnt2 by the step value d1. Moreover, as shown by the rows r211a, r211b, r213a, r213b and r215 of FIG. 2d, when none of the speed-up message UP and the speed-down message DN is asserted in the signals ud2 and ud4, the counting circuit 262 may cause the count cnt2 to remain unchanged. Therefore, the count cnt2 may reflect the total number of times the speed-up message UP is asserted in the signals ud2 and ud4 minus the total number of times the speed-down message DN is asserted in the signals ud2 and ud4, i.e., the second speed-up accumulation count minus the second speed-down accumulation count.

Following FIG. 2a to FIG. 2d, FIG. 2e illustrates an operation embodiment of the internal circuit 2243 in the phase detection circuit 224. As shown in FIG. 2e, the internal circuit 2243 may further determine a status of the count cnt1 according to value of the count cnt1; when the count cnt1 is greater than a predetermined upper bound value c_U, the internal circuit 2243 may cause the status of the count cnt1 to equal a status cnt_UP; when the count cnt1 is less than a predetermined lower bound value c_D, the internal circuit 2243 may cause the status of the count cnt1 to equal another status cnt_DN; and, when the count cnt1 is between the upper bound value c_U and the lower bound value c_D, the internal circuit 2243 may cause the status of the count cnt1 to equal still another status cnt_normal. Similarly, the internal circuit 2243 may further determine a status of the count cnt2 according to value of the count cnt2; when the count cnt2 is greater than the upper bound value c_U, the internal circuit 2243 may cause the status of the count cnt2 to equal the status cnt_UP; when the count cnt2 is less than the lower bound value c_D, the internal circuit 2243 may cause the status of the count cnt2 to equal the status cnt_DN; when the count cnt2 is between the upper bound value c_U and the lower bound value c_D, the internal circuit 2243 may cause the status of the count cnt2 to equal the status cnt_normal. The upper bound value c_U may be greater than the lower bound value c_D.

As shown in FIG. 2e, in an embodiment, the internal circuit 2243 in the phase detection circuit 224 may further adjust the offset value d_phi of the phase shifting circuit 250 according to the statuses of the counts cnt1 and cnt2. As shown by a row r221c of FIG. 2e, when the statuses of the counts cnt1 and cnt2 respectively equal the statuses cnt_UP and cnt_DN, the internal circuit 2243 may, via the signal scr2, cause the offset value d_phi of the phase shifting circuit 250 to increase, and may reset each of the counts cnt1 and cnt2 to a predetermined initial value c_0. The initial value c_0 may be greater than the lower bound value c_D, and may be less than the upper bound value c_U; therefore, when the counts cnt1 and cnt2 are reset to the initial value c_0, the statuses of the counts cnt1 and cnt2 may return to equal the status cnt_normal.

On the other hand, as shown by rows r221a and r221b of FIG. 2e, when the status of the count cnt1 equals the status cnt_UP, if the status of the count cnt2 equals the status cnt_UP or cnt_normal, the internal circuit 2243 may cause the offset value d_phi of the phase shifting circuit 250 to remain unchanged (denoted by “−” in FIG. 2e) via the signal scr2, and may not reset the counts cnt1 and cnt2. Moreover, as shown by a row r223a of FIG. 2e, when the statuses of the counts cnt1 and cnt2 respectively equal the statuses cnt_DN and cnt_UP, the internal circuit 2243 may, via the signal scr2, cause the offset value d_phi of the phase shifting circuit 250 to decrease, and may reset the counts cnt1 and cnt2 to the initial value c_0, such that the statuses of the counts cnt1 and cnt2 may return to the status cnt_normal. On the other hand, as shown by rows r223b and r223c of FIG. 2e, when the status of the count cnt1 equals the status cnt_DN, if the status of the count cnt2 equals the status cnt_DN or cnt_normal, the internal circuit 2243 may cause the offset value d_phi to remain unchanged, and may not reset the counts cnt1 and cnt2. As shown by the row r221b, rows r222a to r222c and the row r223b of FIG. 2e, when the status of anyone of the counts cnt1 and cnt2 equals the status cnt_normal, the internal circuit 2243 may cause the offset value d_phi to remain unchanged, and may not reset the counts cnt1 and cnt2.

Following FIG. 2a to FIG. 2e, FIG. 2f illustrates value change of the counts cnt1 and cnt2 by an example. In the example shown in FIG. 2f, between two time points ta0 and ta1, a said speed-down message DN is asserted in the signal ud2 or ud4; hence, at the time point ta1, the count cnt2 may decrement by the step value d1, and the count cnt1 may remain unchanged; at this time, the counts cnt1 and cnt2 may both be between the upper bound value c_U and the lower bound value c_D, so the statuses of the counts cnt1 and cnt2 may both equal the status cnt_normal, and the internal circuit 2243 may keep the offset value d_phi unchanged. Between the time point ta1 and a subsequent time point ta2, a said speed-down message DN is asserted again in the signal ud2 or ud4; hence, at the time point ta2, the count cnt2 may decrement by the step value d1 again, the count cnt1 may remain unchanged, and the statuses of the counts cnt1 and cnt2 may stay equal to the status cnt_normal. Then, between the time point ta2 and a later time point ta3, a said speed-up message UP is asserted in the signal ud1 or ud3; therefore, at the time point ta3, the count cnt1 may increment by the step value d1, the count cnt2 may remain unchanged, and the statuses of the counts cnt1 and cnt2 may stay equal to the status cnt_normal. Between the time point ta3 and a later time point ta4, a said speed-down message DN is asserted in the signal ud2 or ud4; therefore, at the time point ta4, the count cnt2 may decrement to equal the lower bound value c_D, the count cnt1 may remain unchanged, and the statuses of the counts cnt1 and cnt2 may stay equal to the status cnt_normal. Between the time point ta4 and a later time point ta5, a said speed-up message UP is asserted in the signal ud1 or ud3; therefore, at the time point ta5, the count cnt1 may increment to equal the upper bound value c_U, and the count cnt2 may remain unchanged.

Between the time point ta5 and a later time point ta6, a said speed-up message UP is asserted again in the signal ud1 or ud3; therefore, at the time point ta6, the count cnt1 may increment to be higher the upper bound value c_U, the count cnt2 may remain unchanged; at this time, the status of the count cnt1 may change to the status cnt_UP, while the status of the count cnt2 may still equal the status cnt_normal, so the internal circuit 2243 may not change the offset value d_phi. Between the time point ta6 and a later time point ta7, a said speed-up message UP is asserted again in the signal ud1 or ud3; therefore, at the time point ta7, the count cnt1 may increment by the step value d1 again, the count cnt2 may remain unchanged; at this time, the statuses of the counts cnt1 and cnt2 may respectively equal the statuses cnt_UP and cnt_normal. Between the time point ta7 and a later time point ta8, none of the speed-up message UP and the speed-down message DN is asserted in either one of the signals ud1 to ud4; therefore, at the time point ta8, the counts cnt1 and cnt2 may stay unchanged. Between the time point ta8 and a later time point ta9, a said speed-down message DN is asserted in the signal ud2 or ud4; therefore, at the time point ta9, the count cnt2 may decrement to be lower than the lower bound value c_D; because the count cnt2 is below the lower bound value c_D, the status of the count cnt2 may change to the status cnt_DN. At the time point ta9, because the statuses of the counts cnt1 and cnt2 respectively equal the statuses cnt_UP and cnt_DN, the internal circuit 2243 may operate according to the row r221c of FIG. 2e to increase the offset value d_phi of the phase shifting circuit 250 via the signal scr2, and may reset the counts cnt1 and cnt2 to the initial value c_0 at a later time point ta10, so the statuses of the counts cnt1 and cnt2 may return to the status cnt_normal. After the time point ta10, the count cnt1 may increment or decrement again because a said speed-up message UP or a said speed-down message DN is asserted in either one of the signals ud1 and ud3, and the count cnt2 may increment or decrement again because a said speed-up message UP or speed-down message DN is asserted in either one of the signals ud2 and ud4. Among the time points ta0 to ta10 shown in FIG. 2f, a time span between every two consecutive time points (e.g., between the time points ta0 and ta1, between the time points ta1 and ta2, etc.) may equal the period of the clock cke1.

Back to FIG. 2a, when the clock circuit 240 provides the clocks cke1 and ck0 according to the signal scr1 of the phase detection circuit 222, the clock circuit 240 may adjust frequencies (and/or phases) of the clocks cke1 and ck0 according to a count of times the speed-up message UP is asserted in the signal scr1 and a count of times the speed-down message DN is asserted in the signal scr1. For example, in the signal scr1, if the count of times the speed-up message UP is asserted is greater than the count of times the speed-down message DN is asserted by a difference exceeding a predetermined first tolerance value, then the clock circuit 240 may accelerate timing of the clocks cke1 and ck0, e.g., may increase (increment) the frequencies of the clocks cke1 and ck0; furthermore, the clock circuit 240 may reset the count of times the speed-up message UP is asserted in the signal scr1 to an origin value, and may reset the count of times the speed-down message DN is asserted in the signal scr1 to the origin value; on the other hand, in the signal scr1, if the count of times the speed-down message DN is asserted is greater than the count of times the speed-up message UP is asserted by a difference exceeding a predetermined second tolerance value, then the clock circuit 240 may decelerate timing of the clocks cke1 and ck0, e.g., may decrease (decrement) the frequencies of the clocks cke1 and ck0; furthermore, the clock circuit 240 may reset the count of times the speed-up message UP is asserted in the signal scr1 to the origin value, and may reset the count of times the speed-down message DN is asserted in the signal scr1 to the origin value. As shown in FIG. 2c, whenever a said speed-up message UP is asserted in either one of the signals ud1 to ud4, the internal circuit 2221 in the phase detection circuit 222 may assert a said speed-up message UP in the signal scr1, therefore, the count of times the speed-up message UP is asserted in the signal scr1 may equal a total number of times the speed-up message UP is asserted in the signals ud1 to ud4. Moreover, whenever a said speed-down message DN is asserted in either one of the signals ud1 to ud4, the internal circuit 2221 in the phase detection circuit 222 may assert a said speed-down message DN in the signal scr1, so the count of times the speed-down message DN is asserted in the signal scr1 may equal a total number of times the speed-down message DN is asserted in the signals ud1 to ud4. Briefly speaking, an operation principle of the clock circuit 240 may be: by adjusting timing of the clocks cke1 and ck0, balancing the count of times the speed-up message UP is asserted in the signal scr1 and the count of times the speed-down message DN is asserted in the signal scr1.

In circuitry shown in FIG. 2a, while the clock circuit 240 may adjust timing of the clocks cke1 and ck0 according to the signal scr1 resulting from the phase detection circuit 222, the phase shifting circuit 250 may adjust the offset value d_phi according to the signal scr2 resulting from the phase detection circuit 224, and may therefore adjust timing of the clock cke2. The timing adjustment of the clock circuit 240 and the timing adjustment of the phase shifting circuit 250 may be based on different principles. For example, as described earlier, during the time points ta0 to ta10 shown in FIG. 2f, the phase shifting circuit 250 may adjust (increase) the offset value d_phi because the statuses of the count cnt1 (related to the signals ud1 and ud3 of the pattern phase detection units pd1 and pd3) and the count cnt2 (related to the signals ud2 and ud4 of the pattern phase detection units pd2 and pd4) change from the status cnt_normal to the statuses cnt_UP and cnt_DN, respectively. On the other hand, during the time points ta0 to ta10 shown in FIG. 2f, the clock circuit 240 may not adjust timing of the clocks cke1 and ck0, because the count of times the speed-up message UP is asserted in the signal scr1 equals the count of times the speed-down message DN is asserted in the signal scr1; in the signal scr1, although the count of times the speed-up message UP is asserted is provided by the signals ud1 and ud3 of the pattern phase detection units pd1 and pd3 while the count of times the speed-down message DN is asserted is provided by the signals ud2 and ud4 of the other two pattern phase detection units pd2 and pd4, the phase detection circuit 222 which provides the signal scr1 may not care which one of the pattern phase detection units pd1 to pd4 causes asserting of each said speed-up message UP and each said speed-down message DN; therefore, the timing adjustment performed on the clocks ck0 and cke1 by the clock circuit 240 may be indistinguishable to what the speed-up message UP and the speed-down message DN result from.

In FIG. 2a, the signal sr1 may be referred to as a receiver signal; when the circuitry shown in FIG. 2a operates to discriminate each symbol in the signal sr1 (e.g., symbols sr1[i−1], sr1[i] and sr1[i+1] shown in FIG. 2b), the significant edges of the clocks cke1 and cke2 may track (and/or reflect) edges of the symbols, so the clocks cke1 and cke2 may be respectively referred to as a first edge clock and a second edge clock; besides, the significant edges of the clock ck0 may track (and/or reflect) time axis centers of the symbols, so the clock ck0 may be referred to as a data clock, the sampler sa0 trigger by the clock ck0 may be referred to as a data sampler, the threshold level L0 utilized by the sampler sa0 may be referred to as a data threshold level, and the signal sd1 provided by the sampler sa0 may be referred to as a data signal. Moreover, the samplers sa1, sa2 and sa3 may be respectively referred to as a first edge sampler, a second edge sampler and a third edge sampler, and the threshold levels L1, L2 and L3 may be respectively referred to as a first threshold level, a second threshold level and a third threshold level.

In FIG. 2a, the signal x1 provided by the sampler sa1 may be referred to as a first edge signal; when the signal sd1 matches the pattern p1 (equal to the definition values H, H, L), the signal value of the signal x1 may reflect whether a corresponding significant edge of the clock cke1 is earlier or later than an associated edge of the signal sd1 changing from the definition values H to L (i.e., when the signal sd1 intersects the threshold level L1). When the signal sd1 matches the pattern p1, an occasion that the signal value of the signal x1 equals the definition value H may represent that the corresponding significant edge of the clock cke1 is earlier than the associated edge of the signal sd1 changing from the definition values H to L, so the pattern phase detection unit pd1 may assert the speed-down message DN in the signal ud1, as shown by the row r201b of FIG. 2c. On the other hand, when the signal sd1 matches the pattern p1, an occasion that the signal value of the signal x1 equals the definition value L may represent that the corresponding significant edge of the clock cke1 is later than the associated edge of the signal sd1 changing from the definition values H to L, so the pattern phase detection unit pd1 may assert the speed-up message UP in the signal ud1, as shown by the row r201a of FIG. 2c.

In FIG. 2a, the signal x2 provided by the sampler sa2 may be referred to as a second edge signal; when the signal sd1 matches the pattern p2 (equal to the definition values H, L, H), the signal value of the signal x2 may reflect whether a corresponding significant edge of the clock cke2 is earlier or later than an associated edge of the signal sd1 changing from the definition values L to H (i.e., when the signal sd1 intersects the threshold level L2). When the signal sd1 matches the pattern p2, an occasion that the signal value of the signal x2 equals the definition value L may represent that the corresponding significant edge clock cke2 is earlier than the associated edge of the signal sd1 changing from the definition values L to H, so the pattern phase detection unit pd2 may assert the speed-down message DN in the signal ud2, as shown by the row r202b of FIG. 2c. On the other hand, when the signal sd1 matches the pattern p2, an occasion that the signal value of the signal x2 equals the definition value H may represent that the corresponding significant edge of the clock cke2 is later than the associated edge of the signal sd1 changing from the definition values L to H, so the pattern phase detection unit pd2 may assert the speed-up message UP in the signal ud2, as shown by the row r202a of FIG. 2c.

In FIG. 2a, the signal x3 provided by the sampler sa3 may be referred to as a third edge signal; when the signal sd1 matches the pattern p3 (equal to the definition values L, L, H), the signal value of the signal x3 may reflect whether a corresponding significant edge of the clock cke1 is earlier or later than an associated edge of the signal sd1 changing from the definition values L to H (i.e., when the signal sd1 intersects the threshold level L3). When the signal sd1 matches the pattern p3, an occasion that the signal value of the signal x3 equals the definition value L may represent that the corresponding significant edge of the clock cke1 is earlier than the associated edge of the signal sd1 changing from the definition values L to H, so the pattern phase detection unit pd3 may assert the speed-down message DN in the signal ud3, as shown by the row r203b of FIG. 2c. On the other hand, when the signal sd1 matches the pattern p3, an occasion that the signal value of the signal x3 equals the definition value H may represent that the corresponding significant edge of the clock cke1 is later than the associated edge of the signal sd1 changing from the definition values L to H, so the pattern phase detection unit pd3 may assert the speed-up message UP in the signal ud3, as shown by the row r203a of FIG. 2c.

Besides, when the signal sd1 matches the pattern p4 (equal to the definition values L, H, L), the signal value of the signal x2 may also reflect whether the corresponding significant edge of the clock cke2 is earlier or later than an associated edge of the signal sd1 changing from the definition values H to L (i.e., when the signal sd1 intersects the threshold level L2). When the signal sd1 matches the pattern p4, an occasion that the signal value of the signal x2 equals the definition value H may represent that the corresponding significant edge of the clock cke2 is earlier than the associated edge of the signal sd1 changing from the definition values H to L, so the pattern phase detection unit pd4 may assert the speed-down message DN in the signal ud4, as shown by the row r204b of FIG. 2c. On the other hand, when the signal sd1 matches the pattern p4, an occasion that the signal value of the signal x2 equals the definition value L may represent that the corresponding significant edge of the clock cke2 is later than the associated edge of the signal sd1 changing from the definition values H to L, so the pattern phase detection unit pd4 may assert the speed-up message UP in the signal ud4, as shown by the row r204a of FIG. 2c.

In FIG. 2a, the patterns p1 to p4 may be respectively referred to as a first pattern to a fourth pattern. In the three component values of the patterns p1 (equal to the definition values H, H, L) and p3 (equal to the definition values L, L, H), because the first component value and the second component value may be equal, the patterns p1 and p3 may also be referred to as low frequency patterns. In the three component values of the pattern p2 (equal to the definition values H, L, H) and p4 (equal to the definition values L, H, L), because the first component value may differ from the second component value and the second component value may differ from the third component value, the patterns p2 and p4 may also be referred to as high frequency patterns. In FIG. 2a, the phase detection circuits 222 and 224 may be respectively referred to as a base phase detection circuit and an additional phase detection circuit, the signals scr1 and scr2 may be respectively referred to as a base timing control signal and an additional timing control signal, the offset values d_p0 and d_phi may be respectively referred to as a base offset value and an additional offset value.

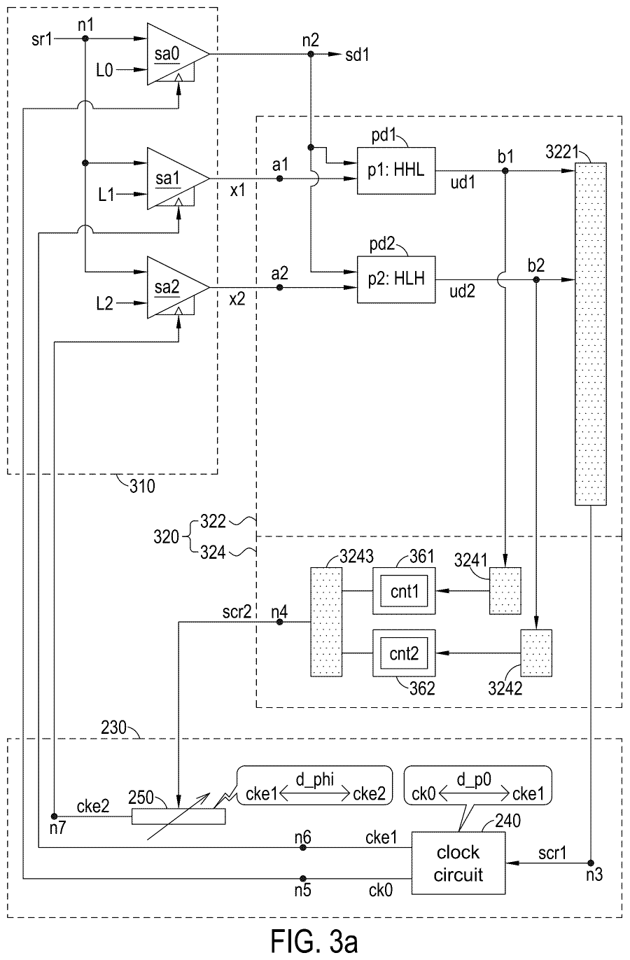

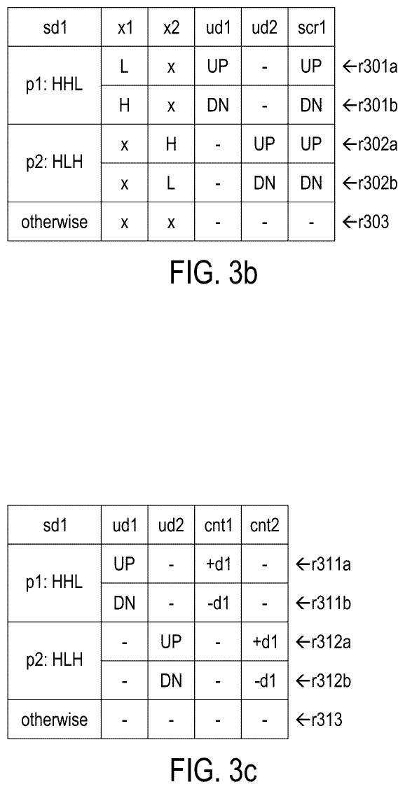

Following FIG. 1a and FIG. 2a, FIG. 3a illustrates a sampler block 310 and a phase detection circuit block 320 according to an embodiment of the present disclosure; the sampler block 310 and the phase detection circuit block 320 may cooperate with the clock circuit block 230 shown in FIG. 2a (also reproduced in FIG. 3a) to implement the sampler block 110, the phase detection circuit block 120 and the clock circuit block 130 shown in FIG. 1a, respectively. As shown in FIG. 3a, the sampler block 310 may comprise the samplers sa0 to sa2 (already described when referring to FIG. 2a), the phase detection circuit block 320 may comprise two phase detection circuits 322 and 324. The phase detection circuit 322 may be a base phase detection circuit, and may comprise the pattern phase detection units pd1 and pd2 (already described when referring to FIG. 2a), as well as an internal circuit 3221. The phase detection circuit 324 may be an additional phase detection circuit, and may comprise three internal circuits 3241, 3242 and 3243, and two counting circuits 361 and 362.

In the phase detection circuit 322, the internal circuit 3221 may comprise two input terminals and an output terminal respectively coupled to the nodes b1, b2 and n3. In the phase detection circuit 324, the internal circuit 3241 may comprise an input terminal and an output terminal respectively coupled to the node b1 and the counting circuit 361, and the internal circuit 3242 may comprise an input terminal and an output terminal respectively coupled to the node b2 and the counting circuit 362. The internal circuit 3243 may be coupled to the counting circuits 361, 362 and the node n4.

In FIG. 3a, the phase detection circuit 322 may provide the signal scr1 at the node n3 according to the signals sd1, x1 and x2, and the phase detection circuit 324 may provide the signal scr2 at the node n4 also according to the signals sd1, x1 and x2. When a said speed-up message UP is asserted in either one of the signals ud1 and ud2, the internal circuit 3221 may responsively assert a said speed-up message UP in the signal scr1; when a said speed-down message DN is asserted in either one of the signals ud1 and ud2, the internal circuit 3221 may responsively assert a said speed-down message DN in the signal scr1.

Following FIG. 3a, FIG. 3b illustrates an operation embodiment of the phase detection circuit 322 by lists. As shown by rows r301a and r301b of FIG. 3b, when the signal sd1 matches the pattern p1 and therefore the pattern phase detection unit pd1 asserts the speed-up message UP or the speed-down message DN in the signal ud1 according to the signal value of the signal x1, the internal circuit 3221 in the phase detection circuit 322 may follow to assert the speed-up message UP or the speed-down message DN in the signal scr1. As shown by rows r302a and r302b of FIG. 3b, when the signal sd1 matches the pattern p2 and therefore the pattern phase detection unit pd2 asserts the speed-up message UP or the speed-down message DN in the signal ud2 according to the signal value of the signal x2, the internal circuit 3221 in the phase detection circuit 322 may follow to assert the speed-up message UP or the speed-down message DN in the signal scr1. As shown by a row r303 of FIG. 3b, when the signal sd1 does not match anyone of the patterns p1 and p2 and therefore the pattern phase detection units pd1 and pd2 do not assert any speed-up message UP and do not assert any speed-down message DN, the internal circuit 3221 in the phase detection circuit 322 may not assert anyone of the speed-up message UP and the speed-down message DN in the signal scr1.

Following FIG. 3a and FIG. 3b, FIG. 3c illustrates an operation embodiment of the counting circuits 361 and 362 by lists. As shown by a row r311a of FIG. 3c, whenever a said speed-up message UP is asserted in the signal ud1, the internal circuit 3241 may cause the counting circuit 361 to increment a count cnt1 by the step value d1; as shown by a row r311b of FIG. 3c, whenever a said speed-down message DN is asserted in the signal ud1, the internal circuit 3241 may cause the counting circuit 361 to decrement the count cnt1 by the step value d1. Moreover, as shown by rows r312a, r312b and r313, when none of the speed-up message UP and the speed-down message DN is asserted in the signal ud1, the counting circuit 361 may cause the count cnt1 to remain unchanged. Hence, the count cnt1 may reflect a number of times the speed-up message UP is asserted in the signal ud1 minus a number of times the speed-down message DN is asserted in the signal ud1.

Similarly, as shown by the row r312a of FIG. 3c, whenever a said speed-up message UP is asserted in the signal ud2, the internal circuit 3242 may cause the counting circuit 362 to increment a count cnt2 by the step value d1; as shown by the row r312b of FIG. 3c, whenever a said speed-down message DN is asserted in the signal ud2, the internal circuit 3242 may cause the counting circuit 362 to decrement the count cnt2 by the step value d1. Moreover, as shown by the rows r311a, r311b and r313, when none of the speed-up message UP and the speed-down message DN is asserted in the signal ud2, the counting circuit 362 may cause the count cnt2 to remain unchanged. Hence, the count cnt2 may reflect a number of times the speed-up message UP is asserted in the signal ud2 minus a number of times the speed-down message DN is asserted in the signal ud2.

In the phase detection circuit 324 shown in FIG. 3a, operations of the internal circuit 3243 and operations of the internal circuit 2243 shown in FIG. 2a may be same, as shown in FIG. 2e. In an embodiment, the internal circuit 3243 may determine statuses of the counts cnt1 and cnt2 respectively according to values of the counts cnt1 and cnt2, and may dynamically adjust the offset value d_phi of the phase shifting circuit 250 according to the statuses of the two counts. When the count cnt1 is above the upper bound value c_U (FIG. 2e), the internal circuit 3243 may cause the status of the count cnt1 to equal the status cnt_UP; when the count cnt1 is below the lower bound value c_D, the internal circuit 3243 may cause the status of the count cnt1 to equal the status cnt_DN; when the count cnt1 is between the upper bound value c_U and the lower bound value c_D, the internal circuit 3243 may cause the status of the count cnt1 to equal the status cnt_normal. Similarly, when the count cnt2 is above the upper bound value c_U, the internal circuit 3243 may cause the status of the count cnt2 to equal the status cnt_UP; when the count cnt2 is below the lower bound value c_D, the internal circuit 3243 may cause the status of the count cnt2 to equal the status cnt_DN; when the count cnt2 is between the upper bound value c_U and the lower bound value c_D, the internal circuit 3243 may cause the status of the count cnt2 to equal the status cnt_normal.

When the statuses of the counts cnt1 and cnt2 respectively equal the statuses cnt_UP and cnt_DN, the internal circuit 3243 in the phase detection circuit 324 may cause the offset value d_phi to increase, and may reset the counts cnt1 and cnt2 to the initial value c_0, such that the statuses of the counts cnt1 and cnt2 may return to the status cnt_normal; when the statuses of the counts cnt1 and cnt2 respectively equal the statuses cnt_DN and cnt_UP, the internal circuit 3243 may cause the offset value d_phi to decrease, and may reset the counts cnt1 and cnt2 to the initial value c_0, such that the statuses of the counts cnt1 and cnt2 may return to the status cnt_normal; on occasions other than above two, the internal circuit 3243 may cause the offset value d_phi to remain unchanged, and may not reset the counts cnt1 and cnt2.

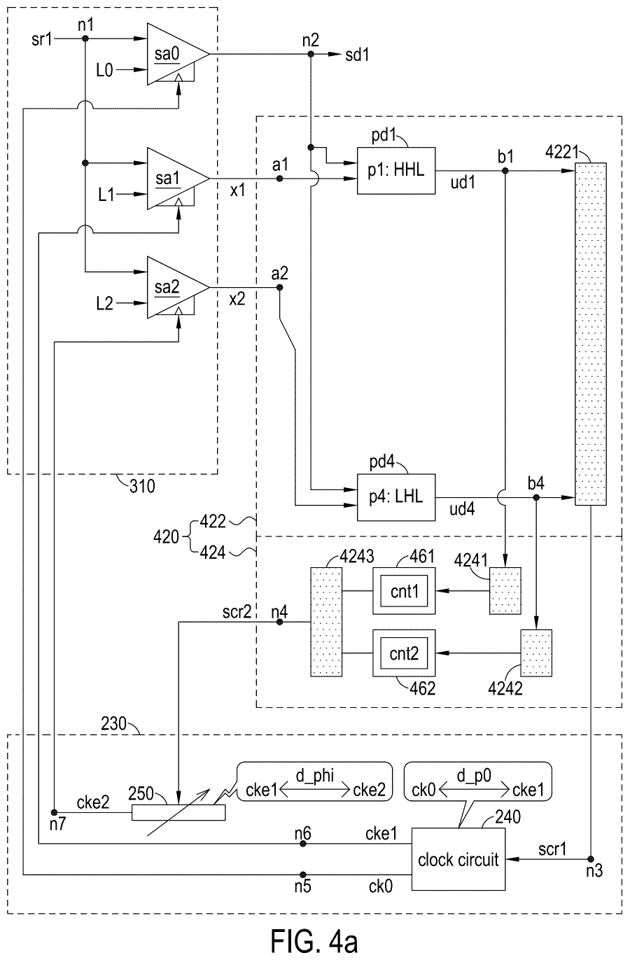

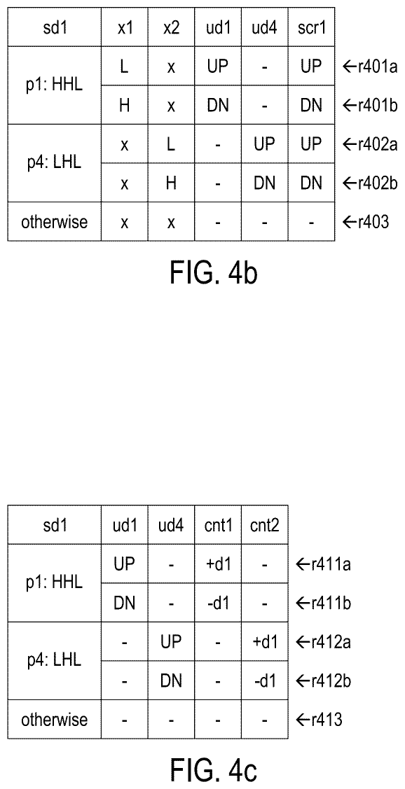

Following FIG. 1a, FIG. 2a and FIG. 3a, FIG. 4a illustrates a phase detection circuit block 420 according to an embodiment of the present disclosure; the phase detection circuit block 420 may cooperate with the clock circuit block 230 shown in FIG. 2a (also reproduced in FIG. 4a) and the sampler block 310 shown in FIG. 3a (also reproduced in FIG. 4a) to implement the phase detection circuit block 120, the clock circuit block 130 and the sampler block 110 shown in FIG. 1a, respectively. As shown in FIG. 4a, the phase detection circuit block 420 may comprise two phase detection circuits 422 and 424. The phase detection circuit 422 may be a base phase detection circuit, and may comprise the pattern phase detection units pd1 and pd4 (already described when referring to FIG. 2a), as well as an internal circuit 4221. The phase detection circuit 424 may be an additional phase detection circuit, and may comprise three internal circuits 4241, 4242 and 4243, and two counting circuits 461 and 462.

In the phase detection circuit 422, the internal circuit 4221 may comprise two input terminals and an output terminal respectively coupled to the nodes b1, b4 and n3. In the phase detection circuit 424, the internal circuit 4241 may comprise an input terminal and an output terminal respectively coupled to the node b1 and the counting circuit 461, and the internal circuit 4242 may comprise an input terminal and an output terminal respectively coupled to the node b4 and the counting circuit 462. The internal circuit 4243 may be coupled to the counting circuits 461, 462 and the node n4.

In FIG. 4a, the phase detection circuit 422 may provide the signal scr1 at the node n3 according to the signals sd1, x1 and x2, and the phase detection circuit 424 may provide the signal scr2 at the node n4 also according to the signals sd1, x1 and x2. When a said speed-up message UP is asserted in either one of the signals ud1 and ud4, the internal circuit 4221 may responsively assert a said speed-up message UP in the signal scr1; when a said speed-down message DN is asserted in either one of the signals ud1 and ud4, the internal circuit 4221 may responsively assert a said speed-down message DN in the signal scr1.

Following FIG. 4a, FIG. 4b illustrates an operation embodiment of the phase detection circuit 422 by lists. As shown by rows r401a and r401b of FIG. 4b, when the signal sd1 matches the pattern p1 so the pattern phase detection unit pd1 asserts the speed-up message UP or the speed-down message DN in the signal ud1 according to the signal value of the signal x1, the internal circuit 4221 in the phase detection circuit 422 may follow to assert the speed-up message UP or the speed-down message DN in the signal scr1. As shown by rows r402a and r402b of FIG. 4b, when the signal sd1 matches the pattern p4 so the pattern phase detection unit pd4 asserts the speed-up message UP or the speed-down message DN in the signal ud4 according to the signal value of the signal x2, the internal circuit 4221 in the phase detection circuit 422 may follow to assert the speed-up message UP or the speed-down message DN in the signal scr1. As shown by a row r403 of FIG. 4b, when the signal sd1 does not match anyone of the patterns p1 and p4 so the pattern phase detection units pd1 and pd4 do not assert any speed-up message UP and do not assert any speed-down message DN, the internal circuit 4221 in the phase detection circuit 422 may not assert anyone of the speed-up message UP and the speed-down message DN in the signal scr1.

Following FIG. 4a and FIG. 4b, FIG. 4c illustrates an operation embodiment of the counting circuits 461 and 462 by lists. As shown by a row r411a of FIG. 4c, whenever a said speed-up message UP is asserted in the signal ud1, the internal circuit 4241 in the phase detection circuit 424 may cause the counting circuit 461 to increment a count cnt1 by the step value d1; as shown by a row r411b of FIG. 4c, whenever a said speed-down message DN is asserted in the signal ud1, the internal circuit 4241 may cause the counting circuit 461 to decrement the count cnt1 by the step value d1. Moreover, as shown by rows r412a, r412b and r413, when none of the speed-up message UP and the speed-down message DN is asserted in the signal ud1, the counting circuit 461 may cause the count cnt1 to remain unchanged. Hence, the count cnt1 may reflect a number of times the speed-up message UP is asserted in the signal ud1 minus a number of times the speed-down message DN is asserted in the signal ud1.

Similarly, as shown by the row r412a of FIG. 4c, whenever a said speed-up message UP is asserted in the signal ud4, the internal circuit 4242 may cause the counting circuit 462 to increment a count cnt2 by the step value d1; as shown by the row r412b of FIG. 4c, whenever a said speed-down message DN is asserted in the signal ud4, the internal circuit 4242 may cause the counting circuit 462 to decrement the count cnt2 by the step value d1. Moreover, as shown by the rows r411a, r411b and r413, when none of the speed-up message UP and the speed-down message DN is asserted in the signal ud4, the counting circuit 462 may cause the count cnt2 to remain unchanged. Hence, the count cnt2 may reflect a number of times the speed-up message UP is asserted in the signal ud4 minus a number of times the speed-down message DN is asserted in the signal ud4.

In the phase detection circuit 424 shown in FIG. 4a, operations of the internal circuit 4243 and operations of the internal circuit 2243 shown in FIG. 2a may be same, as shown in FIG. 2e. In an embodiment, the internal circuit 4243 may determine statuses of the counts cnt1 and cnt2 respectively according to values of the counts cnt1 and cnt2, and may dynamically adjust the offset value d_phi of the phase shifting circuit 250 according to the statuses of the two counts. When the count cnt1 is greater than the upper bound value c_U (FIG. 2e), the internal circuit 4243 may cause the status of the count cnt1 to equal the status cnt_UP; when the count cnt1 is less than the lower bound value c_D, the internal circuit 4243 may cause the status of the count cnt1 to equal the status cnt_DN; when the count cnt1 is between the upper bound value c_U and the lower bound value c_D, the internal circuit 4243 may cause the status of the count cnt1 to equal the status cnt_normal. Similarly, when the count cnt2 is greater than the upper bound value c_U, the internal circuit 4243 may cause the status of the count cnt2 to equal the status cnt_UP; when the count cnt2 is less than the lower bound value c_D, the internal circuit 4243 may cause the status of the count cnt2 to equal the status cnt_DN; when the count cnt2 is between the upper bound value c_U and the lower bound value c_D, the internal circuit 4243 may cause the status of the count cnt2 to equal the status cnt_normal.

When the statuses of the counts cnt1 and cnt2 respectively equal the statuses cnt_UP and cnt_DN, the internal circuit 4243 in the phase detection circuit 424 may cause the offset value d_phi of the phase shifting circuit 250 to increase (increment) via the signal scr2, and may reset the counts cnt1 and cnt2 to the initial value c_0, such that the statuses of the counts cnt1 and cnt2 may return to the status cnt_normal; when the statuses of the counts cnt1 and cnt2 respectively equal the statuses cnt_DN and cnt_UP, the internal circuit 4243 may cause the offset value d_phi to decrease (decrement), and may reset the counts cnt1 and cnt2 to the initial value c_0, such that the statuses of the counts cnt1 and cnt2 may return to the status cnt_normal; on occasions other than above two, the internal circuit 4243 may cause the offset value d_phi to remain unchanged, and may not reset the counts cnt1 and cnt2.

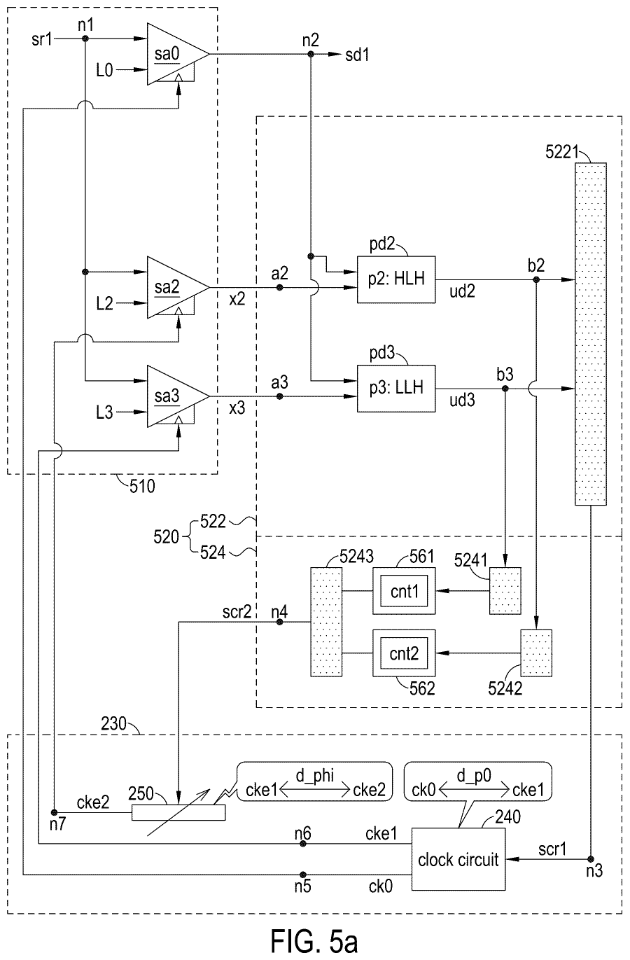

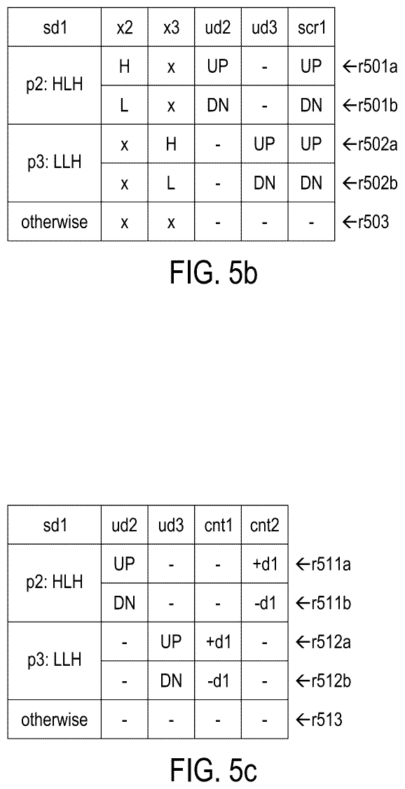

Following FIG. 1a and FIG. 2a, FIG. 5a illustrates a sampler block 510 and a phase detection circuit block 520 according to an embodiment of the present disclosure; the sampler block 510 and the phase detection circuit block 520 may cooperate with the clock circuit block 230 shown in FIG. 2a (also reproduced in FIG. 5a) to implement the sampler block 110, the phase detection circuit block 120 and the clock circuit block 130 shown in FIG. 1a, respectively. As shown in FIG. 5a, the sampler block 510 may comprise the samplers sa0, sa2 and sa3 (already described when referring to FIG. 2a), and the phase detection circuit block 520 may comprise two phase detection circuits 522 and 524. The phase detection circuit 522 may be a base phase detection circuit, and may comprise the pattern phase detection units pd2 and pd3 (already described when referring to FIG. 2a), along with an internal circuit 5221. The phase detection circuit 524 may be an additional phase detection circuit, and may comprise internal circuits 5241, 5242 and 5243, as well as two counting circuits 561 and 562.

In the phase detection circuit 522, the internal circuit 5221 may comprise two input terminals and an output terminal respectively coupled to the nodes b2, b3 and n3. In the phase detection circuit 524, the internal circuit 5241 may comprise an input terminal and an output terminal respectively coupled to the node b3 and the counting circuit 561, and the internal circuit 5242 may comprise an input terminal and an output terminal respectively coupled to the node b2 and the counting circuit 562. The internal circuit 5243 may be coupled to the counting circuits 561, 562 and the node n4.

In FIG. 5a, the phase detection circuit 522 may provide the signal scr1 at the node n3 according to the signals sd1, x2 and x3, and the phase detection circuit 524 may provide the signal scr2 at the node n4 also according to the signals sd1, x2 and x3. When a said speed-up message UP is asserted in either one of the signals ud2 and ud3, the internal circuit 5221 may responsively assert a said speed-up message UP in the signal scr1; when a said speed-down message DN is asserted in either one of the signals ud2 and ud3, the internal circuit 5221 may responsively assert a said speed-down message DN in the signal scr1.

Following FIG. 5a, FIG. 5b illustrates an operation embodiment of the phase detection circuit 522 by lists. As shown by rows r501a and r501b of FIG. 5b, when the signal sd1 matches the pattern p2 and therefore the pattern phase detection unit pd2 asserts the speed-up message UP or the speed-down message DN in the signal ud2 according to the signal value of the signal x2, the internal circuit 5221 in the phase detection circuit 522 may follow to assert the speed-up message UP or the speed-down message DN in the signal scr1. As shown by rows r502a and r502b of FIG. 5b, when the signal sd1 matches the pattern p3 and therefore the pattern phase detection unit pd3 asserts the speed-up message UP or the speed-down message DN in the signal ud3 according to the signal value of the signal x3, the internal circuit 5221 in the phase detection circuit 522 may follow to assert the speed-up message UP or the speed-down message DN in the signal scr1. As shown by a row r503 of FIG. 5b, when the signal sd1 does not match anyone of the patterns p2 and p3 and therefore the pattern phase detection units pd2 and pd3 do not assert any speed-up message UP and do not assert any speed-down message DN, the internal circuit 5221 in the phase detection circuit 522 may not assert anyone of the speed-up message UP and the speed-down message DN in the signal scr1.

Following FIG. 5a and FIG. 5b, FIG. 5c illustrates an operation embodiment of the counting circuit 561 and 562 by lists. As shown by a row r512a of FIG. 5c, whenever a said speed-up message UP is asserted in the signal ud3, the internal circuit 5241 may cause the counting circuit 561 to increment a count cnt1 by the step value d1; as shown by a row r512b of FIG. 5c, whenever a said speed-down message DN is asserted in the signal ud3, the internal circuit 5241 may cause the counting circuit 561 to decrement the count cnt1 by the step value d1. Moreover, as shown by rows r511a, r511b and r513, when none of the speed-up message UP and the speed-down message DN is asserted in the signal ud3, the counting circuit 561 may cause the count cnt1 to remain unchanged. Hence, the count cnt1 may reflect a number of times the speed-up message UP is asserted in the signal ud3 minus a number of times the speed-down message DN is asserted in the signal ud3.

Similarly, as shown by the row r511a of FIG. 5c, whenever a said speed-up message UP is asserted in the signal ud2, the internal circuit 5242 may cause the counting circuit 562 to increment a count cnt2 by the step value d1; as shown by the row r511b of FIG. 5c, whenever a said speed-down message DN is asserted in the signal ud2, the internal circuit 5242 may cause the counting circuit 562 to decrement the count cnt2 by the step value d1. Moreover, as shown by the rows r512a, r512b and r513, when none of the speed-up message UP and the speed-down message DN is asserted in the signal ud2, the counting circuit 562 may cause the count cnt2 to remain unchanged. Hence, the count cnt2 may reflect a number of times the speed-up message UP is asserted in the signal ud2 minus a number of times the speed-down message DN is asserted in the signal ud2.

In the phase detection circuit 524 shown in FIG. 5a, operations of the internal circuit 5243 and operations of the internal circuit 2243 shown in FIG. 2a may be same, as shown in FIG. 2e. In an embodiment, the internal circuit 5243 may determine statuses of the counts cnt1 and cnt2 respectively according to values of the counts cnt1 and cnt2, and may dynamically adjust the offset value d_phi of the phase shifting circuit 250 according to the statuses of the two counts. When the count cnt1 is greater than the upper bound value c_U (FIG. 2e), the internal circuit 5243 may cause the status of the count cnt1 to equal the status cnt_UP; when the count cnt1 is less than the lower bound value c_D, the internal circuit 5243 may cause the status of the count cnt1 to equal the status cnt_DN; when the count cnt1 is between the upper bound value c_U and the lower bound value c_D, the internal circuit 5243 may cause the status of the count cnt1 to equal the status cnt_normal. Similarly, when the count cnt2 is greater than the upper bound value c_U, the internal circuit 5243 may cause the status of the count cnt2 to equal the status cnt_UP; when the count cnt2 is less than the lower bound value c_D, the internal circuit 5243 may cause the status of the count cnt2 to equal the status cnt_DN; when the count cnt2 is between the upper bound value c_U and the lower bound value c_D, the internal circuit 5243 may cause the status of the count cnt2 to equal the status cnt_normal.

When the statuses of the counts cnt1 and cnt2 respectively equal the statuses cnt_UP and cnt_DN, the internal circuit 5243 in the phase detection circuit 524 may cause the offset value d_phi of the phase shifting circuit 250 to increase (increment) via the signal scr2, and may reset the counts cnt1 and cnt2 to the initial value c_0, such that the statuses of the counts cnt1 and cnt2 may return to the status cnt_normal; when the statuses of the counts cnt1 and cnt2 respectively equal the statuses cnt_DN and cnt_UP, the internal circuit 5243 may cause the offset value d_phi to decrease (decrement), and may reset the counts cnt1 and cnt2 to the initial value c_0, such that the statuses of the counts cnt1 and cnt2 may return to the status cnt_normal; on occasions other than above two, the internal circuit 5243 may cause the offset value d_phi to remain unchanged, and may not reset the counts cnt1 and cnt2.

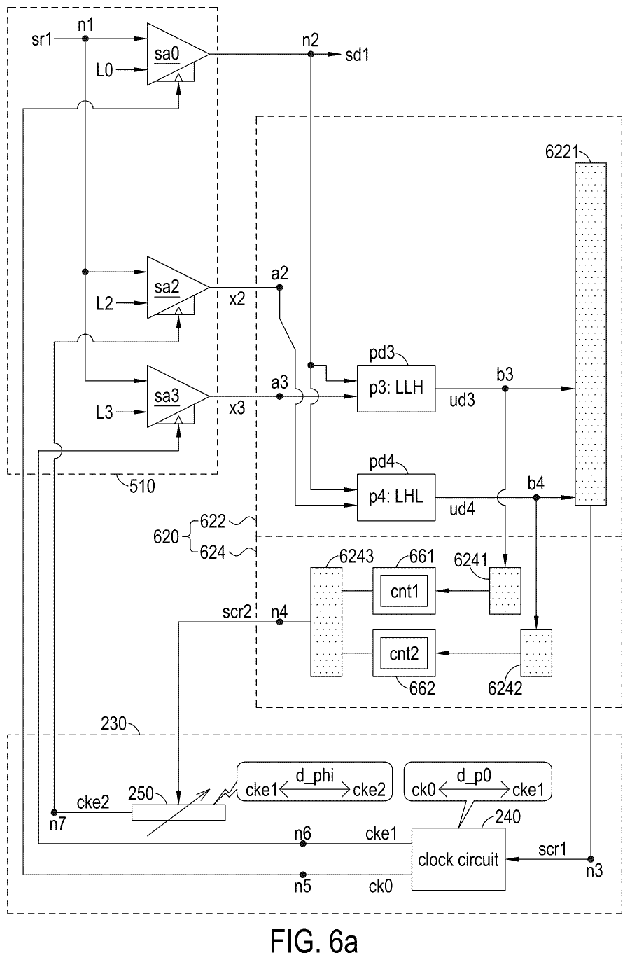

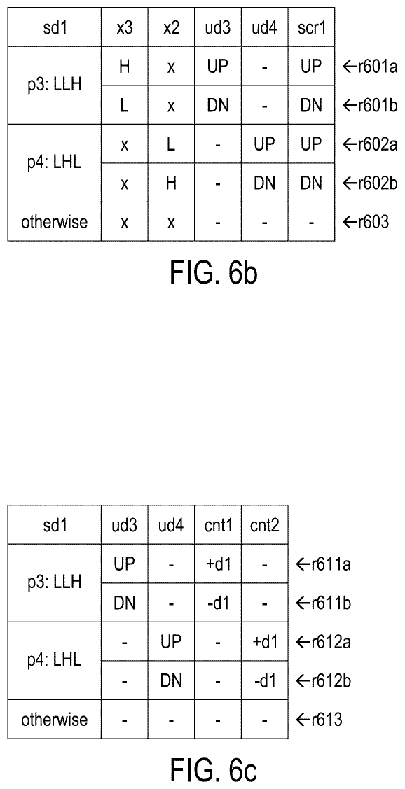

Following FIG. 1a, FIG. 2a and FIG. 5a, FIG. 6a illustrates a phase detection circuit block 620 according to an embodiment of the present disclosure; the phase detection circuit block 620 may cooperate with the clock circuit block 230 shown in FIG. 2a (also reproduced in FIG. 6a) and the sampler block 510 shown in FIG. 5a (also reproduced in FIG. 6a) to implement the phase detection circuit block 120, the clock circuit block 130 and the sampler block 110 shown in FIG. 1a, respectively. As shown in FIG. 6a, the phase detection circuit block 620 may comprise two phase detection circuits 622 and 624. The phase detection circuit 622 may be a base phase detection circuit, and may comprise the pattern phase detection units pd3 and pd4 (already described when referring to FIG. 2a), along with an internal circuit 6221. The phase detection circuit 624 may be an additional phase detection circuit, and may comprise three internal circuits 6241, 6242 and 6243, as well as two counting circuits 661 and 662.

In the phase detection circuit 622, the internal circuit 6221 may comprise two input terminals and an output terminal respectively coupled to the nodes b3, b4 and n3. In the phase detection circuit 624, the internal circuit 6241 may comprise an input terminal and an output terminal respectively coupled to the node b3 and the counting circuit 661, and the internal circuit 6242 may comprise an input terminal and an output terminal respectively coupled to the node b4 and the counting circuit 662. The internal circuit 6243 may be coupled to the counting circuits 661, 662 and the node n4.

In FIG. 6a, the phase detection circuit 622 may provide the signal scr1 at the node n3 according to the signals sd1, x2 and x3, and the phase detection circuit 624 may provide the signal scr2 at the node n4 also according to the signals sd1, x2 and x3. When a said speed-up message UP is asserted in either one of the signals ud3 and ud4, the internal circuit 6221 may responsively assert a said speed-up message UP in the signal scr1; when a said speed-down message DN is asserted in either one of the signals ud3 and ud4, the internal circuit 6221 may responsively assert a said speed-down message DN in the signal scr1.

Following FIG. 6a, FIG. 6b illustrates an operation embodiment of the phase detection circuit 622 by lists. As shown by rows r601a and r601b of FIG. 6b, when the signal sd1 matches the pattern p3 and therefore the pattern phase detection unit pd3 asserts the speed-up message UP or the speed-down message DN in the signal ud3 according to the signal value of the signal x3, the internal circuit 6221 in the phase detection circuit 622 may correspondingly assert the speed-up message UP or the speed-down message DN in the signal scr1. As shown by rows r602a and r602b of FIG. 6b, when the signal sd1 matches the pattern p4 and therefore the pattern phase detection unit pd4 asserts the speed-up message UP or the speed-down message DN in the signal ud4 according to the signal value of the signal x2, the internal circuit 6221 in the phase detection circuit 622 may correspondingly assert the speed-up message UP or the speed-down message DN in the signal scr1. As shown by a row r603 of FIG. 6b, when the signal sd1 does not match anyone of the patterns p3 and p4 and therefore the pattern phase detection units pd3 and pd4 do not assert any speed-up message UP and do not assert any speed-down message DN, the internal circuit 6221 in the phase detection circuit 622 may not assert anyone of the speed-up message UP and the speed-down message DN in the signal scr1.

Following FIG. 6a and FIG. 6b, FIG. 6c illustrates an operation embodiment of the counting circuits 661 and 662 by lists. As shown by a row r611a of FIG. 6c, whenever a said speed-up message UP is asserted in the signal ud3, the internal circuit 6241 may cause the counting circuit 661 to increment a count cnt1 by the step value d1; as shown by a row r611b of FIG. 6c, whenever a said speed-down message DN is asserted in the signal ud3, the internal circuit 6241 may cause the counting circuit 661 to decrement the count cnt1 by the step value d1. Moreover, as shown by rows r612a, r612b and r613, when none of the speed-up message UP and the speed-down message DN is asserted in the signal ud3, the counting circuit 661 may cause the count cnt1 to remain unchanged. Hence, the count cnt1 may reflect a number of times the speed-up message UP is asserted in the signal ud3 minus a number of times the speed-down message DN is asserted in the signal ud3.

Similarly, as shown by the row r612a of FIG. 6c, whenever a said speed-up message UP is asserted in the signal ud4, the internal circuit 6242 may cause the counting circuit 662 to increment a count cnt2 by the step value d1; as shown by the row r612b of FIG. 6c, whenever a said speed-down message DN is asserted in the signal ud4, the internal circuit 6242 may cause the counting circuit 662 to decrement the count cnt2 by the step value d1. Moreover, as shown by the rows r611a, r611b and r613, when none of the speed-up message UP and the speed-down message DN is asserted in the signal ud4, the counting circuit 662 may cause the count cnt2 to remain unchanged. Hence, the count cnt2 may reflect a number of times the speed-up message UP is asserted in the signal ud4 minus a number of times the speed-down message DN is asserted in the signal ud4.

In the phase detection circuit 624 shown in FIG. 6a, operations of the internal circuit 6243 and operations of the internal circuit 2243 shown in FIG. 2a may be same, as shown in FIG. 2e. In an embodiment, the internal circuit 6243 may determine statuses of the counts cnt1 and cnt2 respectively according to values of the counts cnt1 and cnt2, and may dynamically adjust the offset value d_phi of the phase shifting circuit 250 according to the statuses of the two counts. When the count cnt1 is greater than the upper bound value c_U (FIG. 2e), the internal circuit 6243 may cause the status of the count cnt1 to equal the status cnt_UP; when the count cnt1 is less than the lower bound value c_D, the internal circuit 6243 may cause the status of the count cnt1 to equal the status cnt_DN; when the count cnt1 is between the upper bound value c_U and the lower bound value c_D, the internal circuit 6243 may cause the status of the count cnt1 to equal the status cnt_normal. Similarly, when the count cnt2 is greater than the upper bound value c_U, the internal circuit 6243 may cause the status of the count cnt2 to equal the status cnt_UP; when the count cnt2 is less than the lower bound value c_D, the internal circuit 6243 may cause the status of the count cnt2 to equal the status cnt_DN; when the count cnt2 is between the upper bound value c_U and the lower bound value c_D, the internal circuit 6243 may cause the status of the count cnt2 to equal the status cnt_normal.

When the statuses of the counts cnt1 and cnt2 respectively equal the statuses cnt_UP and cnt_DN, the internal circuit 6243 in the phase detection circuit 624 may cause the offset value d_phi of the phase shifting circuit 250 to increase (increment) via the signal scr2, may reset the counts cnt1 and cnt2 to the initial value c_0, and may therefore cause the statuses of the counts cnt1 and cnt2 to return to the status cnt_normal; when the statuses of the counts cnt1 and cnt2 respectively equal the statuses cnt_DN and cnt_UP, the internal circuit 6243 may cause the offset value d_phi to decrease (decrement), may reset the counts cnt1 and cnt2 to the initial value c_0, and may therefore cause the statuses of the counts cnt1 and cnt2 to return to the status cnt_normal; on occasions other than above two, the internal circuit 6243 may cause the offset value d_phi to remain unchanged, and may not reset the counts cnt1 and cnt2.

Though not depicted, any one of the phase detection circuits 324, 424, 524 and 624 (respectively shown in FIG. 3a, FIG. 4a, FIG. 5a and FIG. 6a) may replace the phase detection circuit 224 shown in FIG. 2a to form other embodiments of the present disclosure. That is, though the base phase detection circuit 222 shown in FIG. 2a may provide all the four signals ud1 to ud4, an accompanying additional phase detection circuit may adjust the offset value d_phi according to only one of the signals ud1 and ud3 and only one of the signals ud2 and ud4, like the phase detection circuits 324, 424, 524 and 624 respectively shown in FIG. 3a to FIG. 6a.

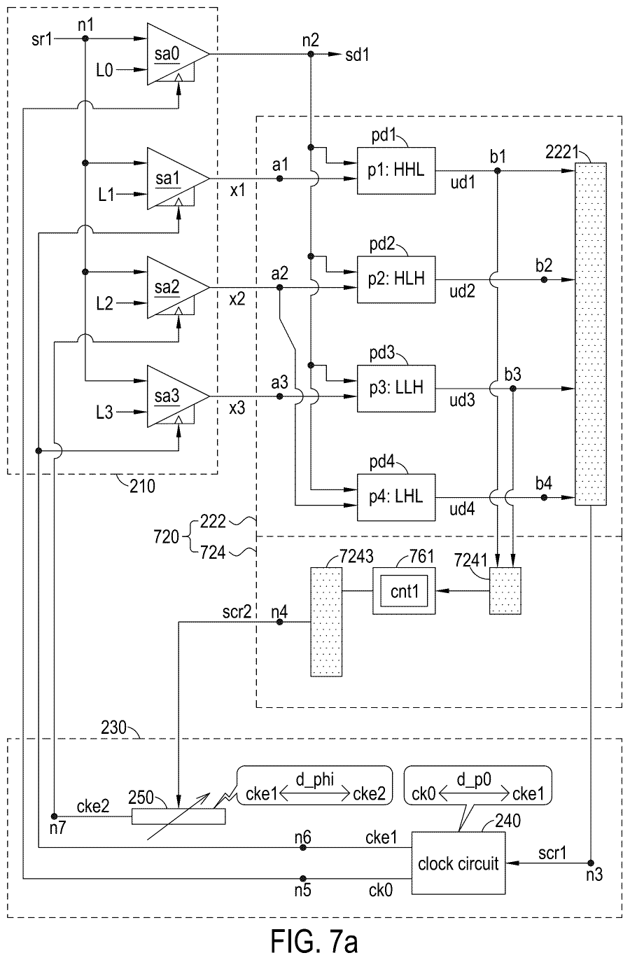

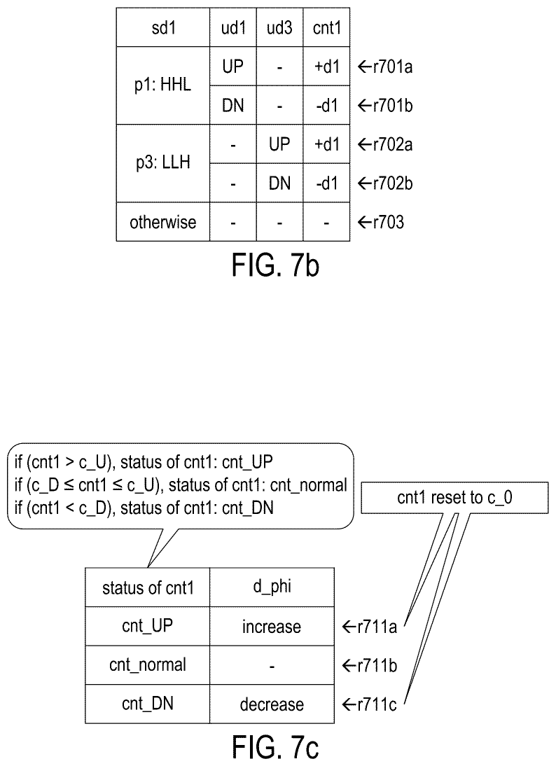

Following FIG. 1a and FIG. 2a, FIG. 7a illustrates a phase detection circuit block 720 according to an embodiment of the present disclosure; the phase detection circuit block 720 may cooperate with the sampler block 210 and the clock circuit block 230 shown in FIG. 2a (also reproduced in FIG. 7a) to implement the phase detection circuit block 120, the sampler block 110 and the clock circuit block 130 shown in FIG. 1a, respectively. The phase detection circuit block 720 may comprise the phase detection circuit 222 (already described when referring to FIG. 2a) and another phase detection circuit 724. The phase detection circuit 724 may be an additional phase detection circuit, may provide the signal scr2 at the node n4 according to the signals sd1, x1 and x3, and may comprise two internal circuits 7241 and 7243, as well as a counting circuit 761. The internal circuit 7241 may comprise two input terminals and an output terminal respectively coupled to the node b1, b3 and the counting circuit 761. The internal circuit 7243 may be coupled to the counting circuit 761 and the node n4.

Following FIG. 7a, FIG. 7b illustrates an operation embodiment of the counting circuit 761 by lists. As shown by rows r701a and r702a of FIG. 7b, whenever a said speed-up message UP is asserted in the signal ud1 or ud3, the internal circuit 7241 may cause the counting circuit 761 to increment a count cnt1 by the step value d1; as shown by rows r701b and r702b of FIG. 7b, whenever a said speed-down message DN is asserted in the signal ud1 or ud3, the internal circuit 7241 may cause the counting circuit 761 to decrement the count cnt1 by the step value d1. Moreover, as shown by a row r703, when none of the speed-up message UP and the speed-down message DN is asserted in the signals ud1 and ud3, the counting circuit 761 may cause the count cnt1 to remain unchanged. Therefore, the count cnt1 may reflect a total number of times the speed-up message UP is asserted in the signals ud1 and ud3 minus a total number of times the speed-down message DN is asserted in the signals ud1 and ud3.

In the phase detection circuit 724, the internal circuit 7243 may determine a status of the count cnt1 according to value of the count cnt1, and may dynamically adjust the offset value d_phi of the phase shifting circuit 250 according to the status of the count cnt1. Following FIG. 7a and FIG. 7b, FIG. 7c illustrates an operation embodiment of the internal circuit 7243 by lists. As shown in FIG. 7c, when the count cnt1 is greater than the upper bound value c_U, the internal circuit 7243 may cause the status of the count cnt1 to equal the status cnt_UP; when the count cnt1 is less than the lower bound value c_D, the internal circuit 7243 may cause the status of the count cnt1 to equal the status cnt_DN; when the count cnt1 is between the upper bound value c_U and the lower bound value c_D, the internal circuit 7243 may cause the status of the count cnt1 to equal the status cnt_normal. As shown by a row r711a, when the status of the count cnt1 equals the status cnt_UP, the internal circuit 7243 in the phase detection circuit 724 may cause the offset value d_phi of the phase shifting circuit 250 to increase (increment) via the signal scr2, may reset the count cnt1 to the initial value c_0, and may therefore cause the status of the count cnt1 to return to the status cnt_normal; as shown by a row r711c, when the status of the count cnt1 equals the status cnt_DN, the internal circuit 7243 may cause the offset value d_phi to decrease (decrement), may reset the count cnt1 to the initial value c_0, and may therefore cause the status of the count cnt1 to return to the status cnt_normal; as shown by a row r711b, when the status of the count cnt1 equals the status cnt_normal, the internal circuit 7243 may cause the offset value d_phi to remain unchanged, and may not reset the count cnt1.

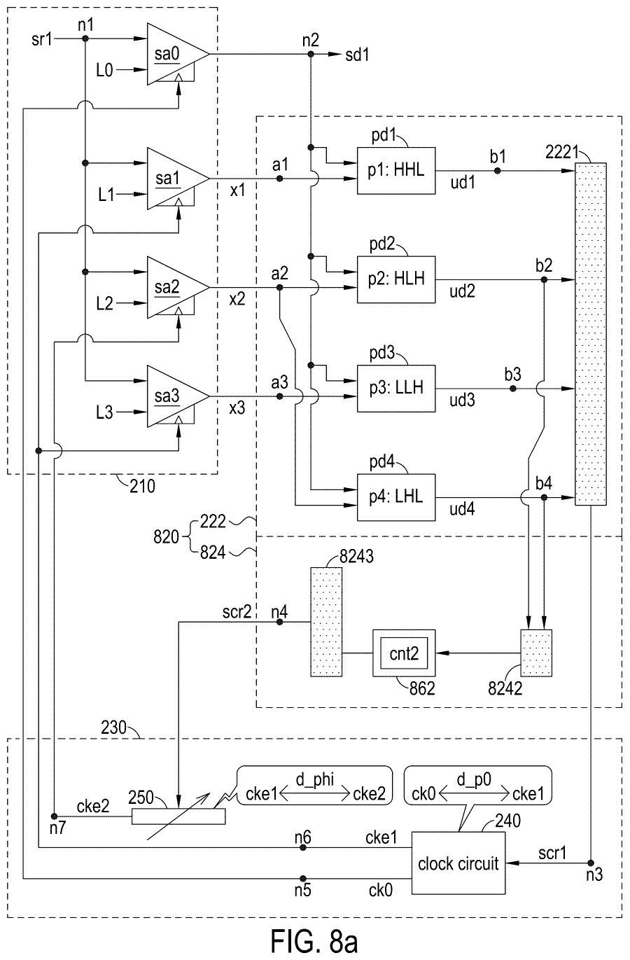

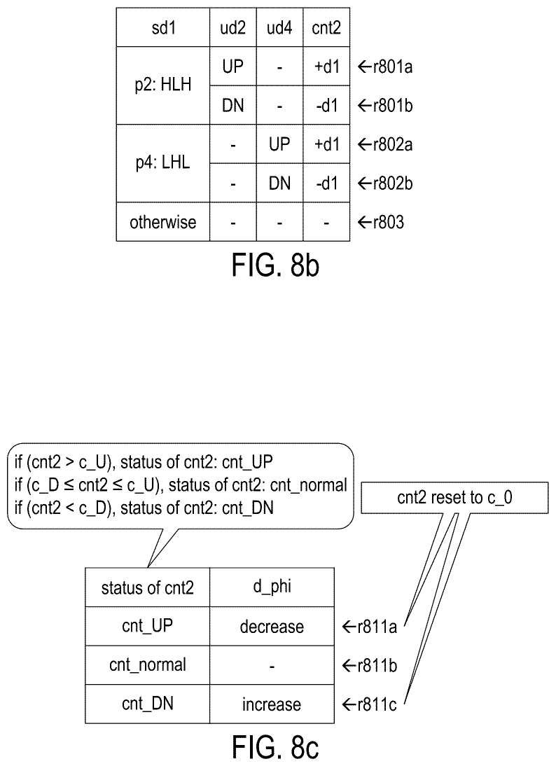

Following FIG. 1a and FIG. 2a, FIG. 8a illustrates a phase detection circuit block 820 according to an embodiment of the present disclosure; the phase detection circuit block 820 may cooperate with the sampler block 210 and the clock circuit block 230 shown in FIG. 2a (also reproduced in FIG. 8a) to implement the phase detection circuit block 120, the sampler block 110 and the clock circuit block 130 shown in FIG. 1a, respectively. The phase detection circuit block 820 may comprise the phase detection circuit 222 (already described when referring to FIG. 2a) and another phase detection circuit 824. The phase detection circuit 824 may be an additional phase detection circuit, may provide the signal scr2 at the node n4 according to the signals sd1 and x2, and may comprise two internal circuits 8242 and 8243, as well as a counting circuit 862. The internal circuit 8242 may comprise two input terminals and an output terminal respectively coupled to the nodes b2, b4 and the counting circuit 862. The internal circuit 8243 may be coupled to the counting circuit 862 and the node n4.

Following FIG. 8a, FIG. 8b illustrates an operation embodiment of the counting circuit 862 by lists. As shown by rows r801a and r802a of FIG. 8b, whenever a said speed-up message UP is asserted in the signal ud2 or ud4, the internal circuit 8242 may cause the counting circuit 862 to increment a count cnt2 by the step value d1; as shown by rows r801b and r802b of FIG. 8b, whenever a said speed-down message DN is asserted in the signal ud2 or ud4, the internal circuit 8242 may cause the counting circuit 862 to decrement the count cnt2 by the step value d1. Moreover, as shown by a row r803, when none of the speed-up message UP and the speed-down message DN is asserted in the signals ud2 and ud4, the counting circuit 862 may cause the count cnt2 to remain unchanged. Hence, the count cnt2 may reflect a total number of times the speed-up message UP is asserted in the signals ud2 and ud4 minus a total number of times the speed-down message DN is asserted in the signals ud2 and ud4.

In the phase detection circuit 824, the internal circuit 8243 may determine a status of the count cnt2 according to value of the count cnt2, and may dynamically adjust the offset value d_phi of the phase shifting circuit 250 according to the status of the count cnt2. Following FIG. 8a and FIG. 8b, FIG. 8c illustrates an operation embodiment of the internal circuit 8243 by lists. As shown in FIG. 8c, when the count cnt2 is greater than the upper bound value c_U, the internal circuit 8243 may cause the status of the count cnt2 to equal the status cnt_UP; when the count cnt2 is less than the lower bound value c_D, the internal circuit 8243 may cause the status of the count cnt2 to equal the status cnt_DN; when the count cnt2 is between the upper bound value c_U and the lower bound value c_D, the internal circuit 8243 may cause the status of the count cnt2 to equal the status cnt_normal. As shown by a row r811a, when the status of the count cnt2 equals the status cnt_UP, the internal circuit 8243 in the phase detection circuit 824 may, via the signal scr2, cause the offset value d_phi of the phase shifting circuit 250 to decrease, may reset the count cnt2 to the initial value c_0, and may therefore cause the status of the count cnt2 to return to the status cnt_normal; as shown by a row r811c, when the status of the count cnt2 equals the status cnt_DN, the internal circuit 8243 may cause the offset value d_phi to increase, may reset the count cnt2 to the initial value c_0, and may therefore cause the status of the count cnt2 to return to the status cnt_normal; as shown by a row r811b, when the status of the count cnt2 equals the status cnt_normal, the internal circuit 8243 may cause the offset value d_phi to remain unchanged, and may not reset the count cnt2.

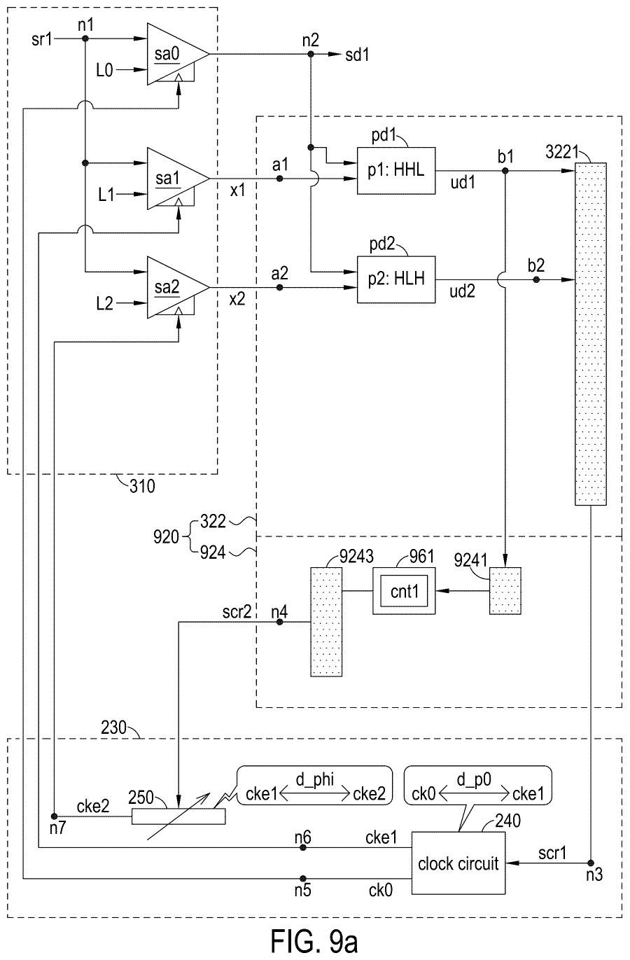

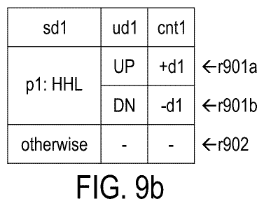

Following FIG. 1a, FIG. 2a and FIG. 3a, FIG. 9a illustrates a phase detection circuit block 920 according to an embodiment of the present disclosure; the phase detection circuit block 920 may cooperate with the sampler block 310 shown in FIG. 3a and the clock circuit block 230 shown in FIG. 2a (also reproduced in FIG. 9a) to implement the phase detection circuit block 120, the sampler block 110 and the clock circuit block 130 shown in FIG. 1a, respectively. The phase detection circuit block 920 may comprise the phase detection circuit 322 (already described when referring to FIG. 3a) and another phase detection circuit 924. The phase detection circuit 924 may be an additional phase detection circuit, may provide the signal scr2 at the node n4 according to the signals sd1 and x1, and may comprise two internal circuits 9241 and 9243, as well as a counting circuit 961. The internal circuit 9241 may comprise an input terminal and an output terminal respectively coupled to the node b1 and the counting circuit 961. The internal circuit 9243 may be coupled to the counting circuit 961 and the node n4.

Following FIG. 9a, FIG. 9b illustrates an operation embodiment of the counting circuit 961 by lists. As shown by a row r901a of FIG. 9b, whenever a said speed-up message UP is asserted in the signal ud1, the internal circuit 9241 may cause the counting circuit 961 to increment a count cnt1 by the step value d1; as shown by a row r901b of FIG. 9b, whenever a said speed-down message DN is asserted in the signal ud1, the internal circuit 9241 may cause the counting circuit 961 to decrement the count cnt1 by the step value d1. Moreover, as shown by a row r902, when none of the speed-up message UP and the speed-down message DN is asserted in the signal ud1, the counting circuit 961 may cause the count cnt1 to remain unchanged.

In the phase detection circuit 924, the internal circuit 9243 may determine a status of the count cnt1 according to value of the count cnt1, and may dynamically adjust the offset value d_phi of the phase shifting circuit 250 according to the status of the count cnt1. In an embodiment, operations of the internal circuit 9243 shown in FIG. 9a and operations of the internal circuit 7243 shown in FIG. 7a may be same, as shown in FIG. 7c. When the count cnt1 is greater than the upper bound value c_U, the internal circuit 9243 may cause the status of the count cnt1 to equal the status cnt_UP; when the count cnt1 is less than the lower bound value c_D, the internal circuit 9243 may cause the status of the count cnt1 to equal the status cnt_DN; when the count cnt1 is between the upper bound value c_U and the lower bound value c_D, the internal circuit 9243 may cause the status of the count cnt1 to equal the status cnt_normal. When the status of the count cnt1 equals the status cnt_UP, the internal circuit 9243 in the phase detection circuit 924 may, via the signal scr2, cause the offset value d_phi of the phase shifting circuit 250 to increase (increment), may reset the count cnt1 to the initial value c_0, and may therefore cause the status of the count cnt1 to return to the status cnt_normal; when the status of the count cnt1 equals the status cnt_DN, the internal circuit 9243 may cause the offset value d_phi to decrease (decrement), may reset the count cnt1 to the initial value c_0, and may therefore cause the status of the count cnt1 to return to the status cnt_normal; when the status of the count cnt1 equals the status cnt_normal, the internal circuit 9243 may cause the offset value d_phi to remain unchanged, and may not reset the count cnt1.

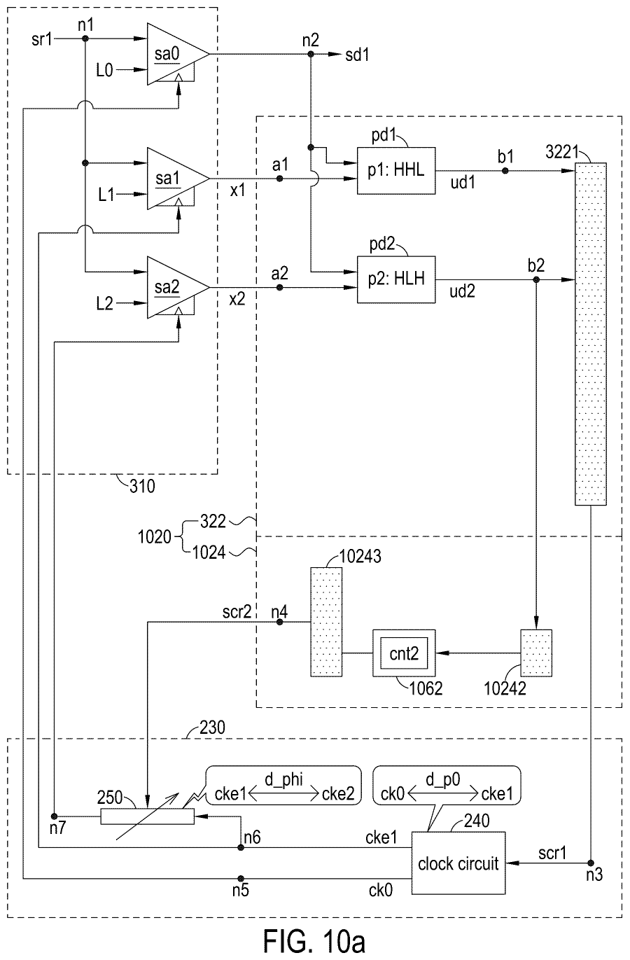

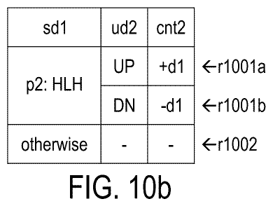

Following FIG. 1a, FIG. 2a and FIG. 3a, FIG. 10a illustrates a phase detection circuit block 1020 according to an embodiment of the present disclosure; the phase detection circuit block 1020 may cooperate with the sampler block 310 shown in FIG. 3a and the clock circuit block 230 shown in FIG. 2a (also reproduced in FIG. 10a) to implement the phase detection circuit block 120, the sampler block 110 and the clock circuit block 130 shown in FIG. 1a, respectively. The phase detection circuit block 1020 may comprise the phase detection circuit 322 (already described when referring to FIG. 3a) and another phase detection circuit 1024. The phase detection circuit 1024 may be an additional phase detection circuit, may provide the signal scr2 at the node n4 according to the signals sd1 and x2, and may comprise two internal circuits 10242 and 10243, as well as a counting circuit 1062. The internal circuit 10242 may comprise an input terminal and an output terminal respectively coupled to the node b2 and the counting circuit 1062. The internal circuit 10243 may be coupled to the counting circuit 1062 and the node n4.

Following FIG. 10a, FIG. 10b illustrates an operation embodiment of the counting circuit 1062 by lists. As shown by a row r1001a of FIG. 10b, whenever a said speed-up message UP is asserted in the signal ud2, the internal circuit 10242 may cause the counting circuit 1062 to increment a count cnt2 by the step value d1; as shown by a row r1001b of FIG. 10b, whenever a said speed-down message DN is asserted in the signal ud2, the internal circuit 10242 may cause the counting circuit 1062 to decrement the count cnt2 by the step value d1. Moreover, as shown by a row r1002, when none of the speed-up message UP and the speed-down message DN is asserted in the signal ud2, the counting circuit 1062 may cause the count cnt2 to remain unchanged. Hence, the count cnt2 may reflect a number of times the speed-up message UP is asserted in the signal ud2 minus a number of times the speed-down message DN is asserted in the signal ud2.

In the phase detection circuit 1024, the internal circuit 10243 may determine a status of the count cnt2 according to value of the count cnt2, and may dynamically tune the offset value d_phi of the phase shifting circuit 250 according to the status of the count cnt2. In an embodiment, operations of the internal circuit 10243 shown in FIG. 10a and operations of the internal circuit 8243 shown in FIG. 8a may be same, as shown in FIG. 8c. When the count cnt2 is greater than the upper bound value c_U, the internal circuit 10243 may cause the status of the count cnt2 to equal the status cnt_UP; when the count cnt2 is less than the lower bound value c_D, the internal circuit 10243 may cause the status of the count cnt2 to equal the status cnt_DN; when the count cnt2 is between the upper bound value c_U and the lower bound value c_D, the internal circuit 10243 may cause the status of the count cnt2 to equal the status cnt_normal. When the status of the count cnt2 equals the status cnt_UP, the internal circuit 10243 in the phase detection circuit 1024 may, via the signal scr2, cause the offset value d_phi of the phase shifting circuit 250 to decrease, may reset the count cnt2 to the initial value c_0, and may therefore cause the status of the count cnt2 to return to the status cnt_normal; when the status of the count cnt2 equals the status cnt_DN, the internal circuit 10243 may cause the offset value d_phi to increase, may reset the count cnt2 to the initial value c_0, and may therefore cause the status of the count cnt2 to return to the status cnt_normal; when the status of the count cnt2 equals the status cnt_normal, the internal circuit 10243 may cause the offset value d_phi to remain unchanged, and may not reset the count cnt2.

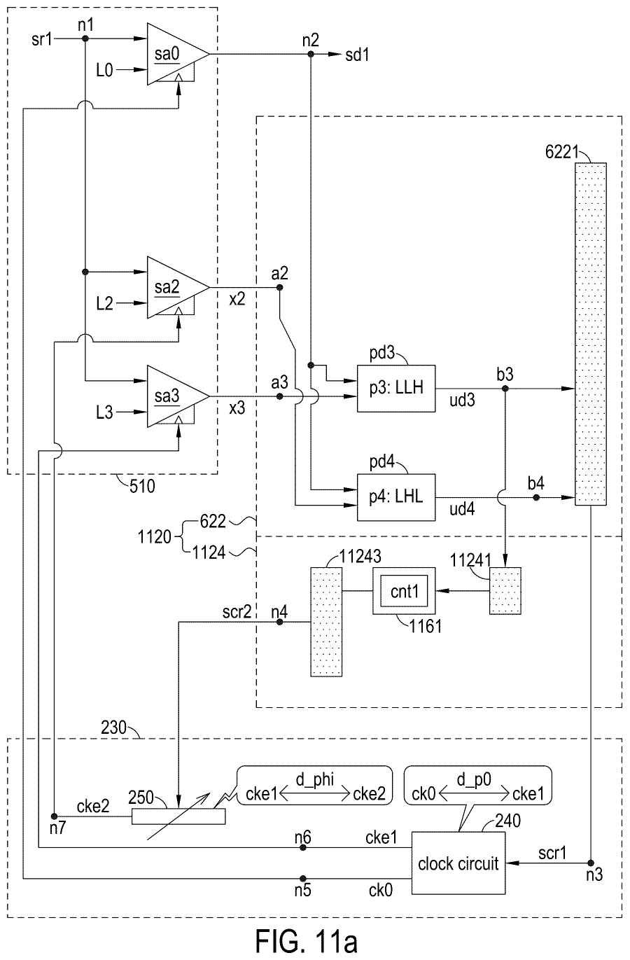

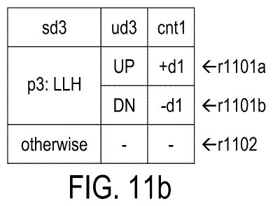

Following FIG. 1a, FIG. 2a, FIG. 5a and FIG. 6a, FIG. 11a illustrates a phase detection circuit block 1120 according to an embodiment of the present disclosure; the phase detection circuit block 1120 may cooperate with the sampler block 510 shown in FIG. 5a and the clock circuit block 230 shown in FIG. 2a (also reproduced in FIG. 11a) to implement the phase detection circuit block 120, the sampler block 110 and the clock circuit block 130 shown in FIG. 1a, respectively. The phase detection circuit block 1120 may comprise the phase detection circuit 622 (already described when referring to FIG. 6a) and another phase detection circuit 1124. The phase detection circuit 1124 may be an additional phase detection circuit, may provide the signal scr2 at the node n4 according to the signals sd1 and x3, and may comprise two internal circuits 11241 and 11243, and a counting circuit 1161. The internal circuit 11241 may comprise an input terminal and an output terminal respectively coupled to the node b3 and the counting circuit 1161. The internal circuit 11243 may be coupled to the counting circuit 1161 and the node n4.

Following FIG. 11a, FIG. 11b illustrates an operation embodiment of the counting circuit 1161 by lists. As shown by a row r1101a of FIG. 11b, whenever a said speed-up message UP is asserted in the signal ud3, the internal circuit 11241 may cause the counting circuit 1161 to increment a count cnt1 by the step value d1; as shown by a row r1101b of FIG. 11b, whenever a said speed-down message DN is asserted in the signal ud3, the internal circuit 11241 may cause the counting circuit 1161 to decrement the count cnt1 by the step value d1. Moreover, as shown by a row r1102, when none of the speed-up message UP and the speed-down message DN is asserted in the signal ud3, the counting circuit 1161 may cause the count cnt1 to remain unchanged. Hence, the count cnt1 may reflect a number of times the speed-up message UP is asserted in the signal ud3 minus a number of times the speed-down message DN is asserted in the signal ud3.

In the phase detection circuit 1124, the internal circuit 11243 may determine a status of the count cnt1 according to value of the count cnt1, and may dynamically tune the offset value d_phi of the phase shifting circuit 250 according to the status of the count cnt1. In an embodiment, operations of the internal circuit 11243 shown in FIG. 11a, operations of the internal circuit 7243 shown in FIG. 7a, and operations of the internal circuit 9243 shown in FIG. 9a may be same, as shown in FIG. 7c. When the count cnt1 is above the upper bound value c_U, the internal circuit 11243 may cause the status of the count cnt1 to equal the status cnt_UP; when the count cnt1 is below the lower bound value c_D, the internal circuit 11243 may cause the status of the count cnt1 to equal the status cnt_DN; when the count cnt1 is between the upper bound value c_U and the lower bound value c_D, the internal circuit 11243 may cause the status of the count cnt1 to equal the status cnt_normal. When the status of the count cnt1 is the status cnt_UP, the internal circuit 11243 in the phase detection circuit 1124 may, via the signal scr2, cause the offset value d_phi of the phase shifting circuit 250 to increase, and may reset the count cnt1 to the initial value c_0, such that the status of the count cnt1 may return back to the status cnt_normal; when the status of the count cnt1 is the status cnt_DN, the internal circuit 11243 may cause the offset value d_phi to decrease, and may reset the count cnt1 to the initial value c_0, such that the status of the count cnt1 may return back to the status cnt_normal; when the status of the count cnt1 is the status cnt_normal, the internal circuit 11243 may cause the offset value d_phi to remain unchanged, and may not reset the count cnt1.

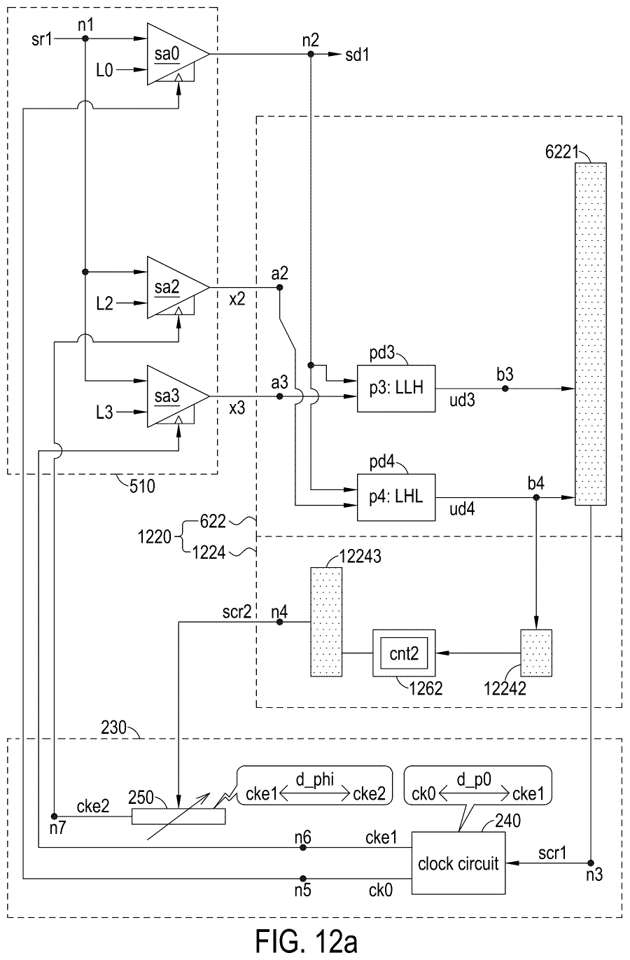

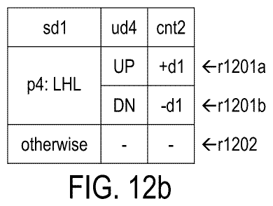

Following FIG. 1a, FIG. 2a, FIG. 5a and FIG. 6a, FIG. 12a illustrates a phase detection circuit block 1220 according to an embodiment of the present disclosure; the phase detection circuit block 1220 may cooperate with the sampler block 510 shown in FIG. 5a and the clock circuit block 230 shown in FIG. 2a (also reproduced in FIG. 12a) to implement the phase detection circuit block 120, the sampler block 110 and the clock circuit block 130 shown in FIG. 1a, respectively. The phase detection circuit block 1220 may comprise the phase detection circuit 622 (already described when referring to FIG. 6a) and another phase detection circuit 1224. The phase detection circuit 1224 may be an additional phase detection circuit, may provide the signal scr2 at the node n4 according to the signals sd1 and x2, and may comprise two internal circuits 12242 and 12243, and a counting circuit 1262. The internal circuit 12242 may comprise an input terminal and an output terminal respectively coupled to the node b4 and the counting circuit 1262. The internal circuit 12243 may be coupled to the counting circuit 1262 and the node n4.

Following FIG. 12a, FIG. 12b illustrates an operation embodiment of the counting circuit 1262 by lists. As shown by a row r1201a of FIG. 12b, whenever a said speed-up message UP is asserted in the signal ud4, the internal circuit 12242 may cause the counting circuit 1262 to increment a count cnt2 by the step value d1; as shown by a row r1201b of FIG. 12b, whenever a said speed-down message DN is asserted in the signal ud4, the internal circuit 12242 may cause the counting circuit 1262 to decrement the count cnt2 by the step value d1. Moreover, as shown by a row r1202, when none of the speed-up message UP and the speed-down message DN is asserted in the signal ud4, the counting circuit 1262 may cause the count cnt2 to remain unchanged. Hence, the count cnt2 may reflect a number of times the speed-up message UP is asserted in the signal ud4 minus a number of times the speed-down message DN is asserted in the signal ud4.

In the phase detection circuit 1224, the internal circuit 12243 may determine a status of the count cnt2 according to value of the count cnt2, and may dynamically tune the offset value d_phi of the phase shifting circuit 250 according to the status of the count cnt2. In an embodiment, operations of the internal circuit 12243 shown in FIG. 12a, operations of the internal circuit 10243 shown in FIG. 10a, and operations of internal circuit 8243 shown in FIG. 8a may be same, as shown in FIG. 8c. When the count cnt2 is above the upper bound value c_U, the internal circuit 12243 may cause the status of the count cnt2 to equal the status cnt_UP; when the count cnt2 is below the lower bound value c_D, the internal circuit 12243 may cause the status of the count cnt2 to equal the status cnt_DN; when the count cnt2 is between the upper bound value c_U and the lower bound value c_D, the internal circuit 12243 may cause the status of the count cnt2 to equal the status cnt_normal. When the status of the count cnt2 is the status cnt_UP, the internal circuit 12243 in the phase detection circuit 1224 may, via the signal scr2, cause the offset value d_phi of the phase shifting circuit 250 to decrease, and may reset the count cnt2 to the initial value c_0, such that the status of the count cnt2 may return to the status cnt_normal; when the status of the count cnt2 is the status cnt_DN, the internal circuit 12243 may cause the offset value d_phi to increase, and may reset the count cnt2 to the initial value c_0, such that the status of the count cnt2 may return to the status cnt_normal; when the status of the count cnt2 is the status cnt_normal, the internal circuit 12243 may cause the offset value d_phi to remain unchanged, and may not reset the count cnt2.

Though not depicted, the phase detection circuit 924 shown in FIG. 9a may replace the phase detection circuit 224 shown in FIG. 2a or the phase detection circuit 424 shown in FIG. 4a to form other embodiments of the present disclosure. Though not depicted, the phase detection circuit 1024 shown in FIG. 10a may replace the phase detection circuit 224 shown in FIG. 2a or the phase detection circuit 524 shown in FIG. 5a to form other embodiments of the present disclosure. Though not depicted, the phase detection circuit 1124 shown in FIG. 11a may replace the phase detection circuit 224 shown in FIG. 2a or the phase detection circuit 524 shown in FIG. 5a to form other embodiments of the present disclosure. Though not depicted, the phase detection circuit 1224 shown in FIG. 12a may replace the phase detection circuit 224 shown in FIG. 2a or the phase detection circuit 424 shown in FIG. 4a to form other embodiments of the present disclosure. In other words, though each of the base phase detection circuits 222, 322, 422, 522 and 622 respectively shown in FIG. 2a to FIG. 6a may provide at least one of the signals ud1 and ud3 as a first set of phase detection result and may provide at least one of the signals ud2 and ud4 as a second set of phase detection result, the accompanying additional phase detection circuit may adjust the offset value d_phi only according to a subset of one of the first set and the second set of phase detection result. For example, the base phase detection circuit 222 shown in FIG. 2a may provide the signals ud1 and ud3 as the first set of phase detection result, and may provide the signals ud1 and ud4 as the second set of phase detection result, the accompanying additional phase detection circuit may, however, adjust the offset value d_phi only according to the signals ud1 and ud3, like the additional phase detection circuit 724 shown in FIG. 7a, or, the accompanying additional phase detection circuit may adjust the offset value d_phi only according to one of the signals ud1 and ud3, like the additional phase detection circuit 924 or 1124 shown in FIG. 9a or FIG. 11a; similarly, the accompanying additional phase detection circuit may adjust offset value d_phi only according to the signals ud2 and ud4, like the additional phase detection circuit 824 shown in FIG. 8a; or, the accompanying additional phase detection circuit may adjust the offset value d_phi only according to one of the signals ud2 and ud4, like the additional phase detection circuit 1024 or 1224 shown in FIG. 10a or FIG. 12a.

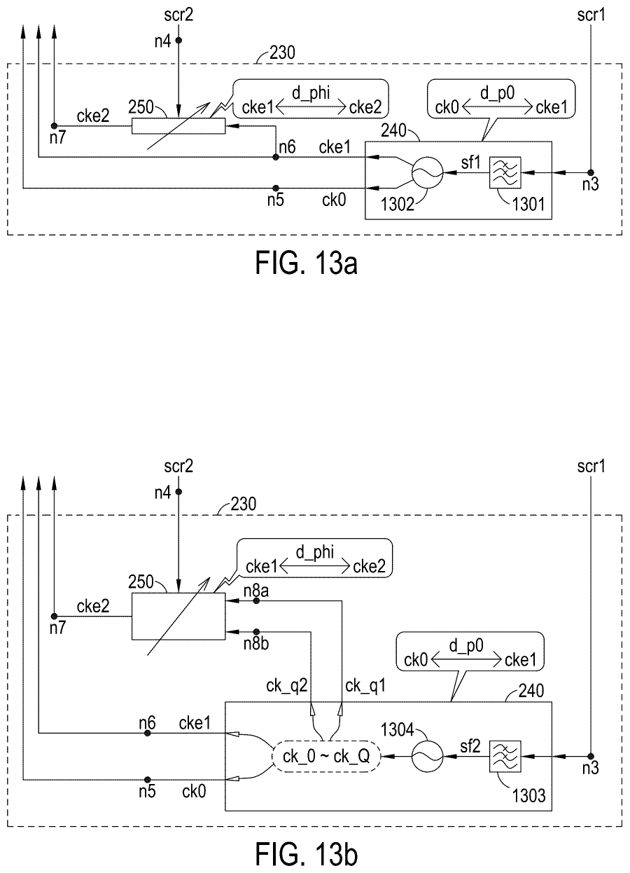

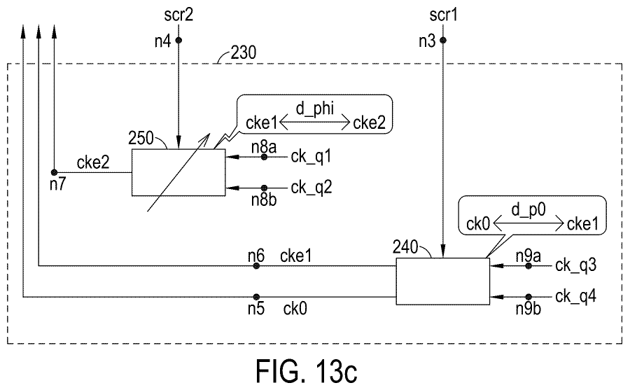

Following FIG. 2a, FIG. 13a, FIG. 13b and FIG. 13c illustrate various embodiments of the clock circuit block 230. As shown in FIG. 13a, in an embodiment of the present disclosure, the clock circuit 240 may comprise a filter 1301 and an oscillator 1302. The filter 1301 may be coupled between the node n3 and the oscillator 1302, and may filter the signal scr1 to generate a signal sf1. The oscillator 1302 may be a controlled oscillator, such as a voltage-controlled oscillator or a digitally controlled oscillator; under control of the signal sf1, the oscillator 1302 may generate the clocks cke1 and ck0 of a same frequency and different phases. The oscillator 1302 may cause timing (frequencies and/or phases) of the clocks cke1 and ck0 to be controlled by the signal scr1, and may cause the mutual phase difference between the clocks ck0 and cke1 to substantially equal the predetermined offset value d_p0. In the embodiment shown in FIG. 13a, the phase shifting circuit 250 may be a controlled variable delay line, and may further comprise a clock input terminal coupled to the clock cke1 at the node n6. The phase shifting circuit 250 shown in FIG. 13a may shift (delay) the phase of the clock cke1 by the offset value d_phi to form the clock cke2, such that the phase difference between the clocks cke2 and cke1 may substantially equal the offset value d_phi, wherein the offset value d_phi may be controlled by the signal scr2.

In the embodiment shown in FIG. 13b, the clock circuit 240 may comprise a filter 1303 and an oscillator 1304. The filter 1303 may be coupled between the node n3 and the oscillator 1304, and may filter the signal scr1 to generate a signal sf2. The oscillator 1304 may be a controlled oscillator, and may, under control of the signal sf2, generate a plurality of clocks ck_0 to ck_Q of a same frequency and constant mutual phase differences. The oscillator 1304 may cause timing (frequencies and/or phases) of the clocks ck_0 to ck_Q to be controlled by the signal sf2 (and therefore the signal scr1), and may cause the mutual phase difference between every two of the clocks ck_0 to ck_Q to equal a predetermined phase difference (e.g., a constant phase angle). The clocks cke1 and ck0 provided by the clock circuit 240 may be two of the clocks ck_0 to ck_Q, and the mutual phase difference of the two clocks may equal the predetermined offset value d_p0. In the embodiment shown in FIG. 13b, the phase shifting circuit 250 may be a controlled variable phase interpolator, and may further comprise two clock input terminals respectively coupled to two clocks ck_q1 and ck_q2 at two nodes n8a and n8b; the clocks ck_q1 and ck_q2 may be two of the clocks ck_0 to ck_Q. The phase shifting circuit 250 may perform phase interpolation between the clocks ck_q1 and ck_q2 to form the clock cke2, and may cause the phase difference between the clocks cke2 and cke1 to equal the offset value d_phi; the phase interpolation performed by the phase shifting circuit 250 may be controlled by the signal scr2, so the offset value d_phi may be controlled by the signal scr2. For example, in an embodiment, the clocks ck_0 to ck_Q provided by the oscillator 1304 may be four clocks ck_0, ck_90, ck_180 and ck_270 of mutual phase differences equal to 90 degrees; the clocks ck0 and cke1 may be the clocks ck_0 and ck_180, and the phase shifting circuit 250 may perform phase interpolation between the clocks ck_180 and ck_270 to form the clock cke2.

In the embodiment shown in FIG. 13c, the clock circuit 240 and the phase shifting circuit 250 may be two controlled variable phase interpolators. The clock circuit 240 may further comprise two clock input terminals respectively coupled to two clocks ck_q3 and ck_q4 at two nodes n9a and n9b. The phase shifting circuit 250 may further comprise two clock input terminals respectively coupled to two clocks ck_q1 and ck_q2 at two nodes n8a and n8b. The clocks ck_q1, ck_q2, ck_q3 and ck_q4 may be four clocks of a same frequency and constant mutual phase differences. Under control of the signal scr1, the clock circuit 240 may perform phase interpolation between the clocks ck_q3 and ck_q4 to generate the clocks ck0 and cke1, and may cause the mutual phase difference between the clocks ck0 and cke1 to substantially equal the offset value d_p0. Under control of the signal scr2, the phase shifting circuit 250 may perform phase interpolation between the clocks ck_q1 and ck_q2 to generate the clock cke2, and may cause the mutual phase difference between the clocks cke2 and cke1 to equal the offset value d_phi. Because the phase interpolation performed by the phase shifting circuit 250 is controlled by the signal scr2, the offset value d_phi may therefore be controlled by the signal scr2.

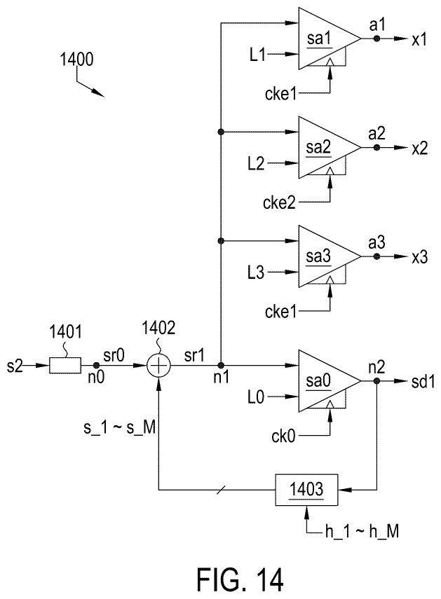

The present disclosure may be implemented within a decision feedback equalizer; following FIG. 1a and FIG. 2a, FIG. 14 illustrates a circuit block 1400 according to an embodiment of the present disclosure; the circuit block 1400 may implement the front-end circuit block 102 and the sampler block 110 shown in FIG. 1a by an architecture of a decision feedback equalizer. Similar to the sampler block 210 shown in FIG. 2a, the circuit block 1400 shown in FIG. 14 may comprise the samplers sa0 to sa3 (already described when referring to FIG. 2a), and may also comprise a front-end circuit 1401, an adder 1402 and a feedback circuit 1403. The front-end circuit 1401 may be coupled between the received signal s2 (FIG. 1a) and a node no, may comprise linear equalizer(s) and/or variable gain amplifier(s) (not depicted), and may perform signal process on the received signal s2 to accordingly provide a signal sr0 at the node n0. The adder 1402 may be coupled among the nodes no, n1 and the feedback circuit 1403, and may sum the signal sr0 and a number M of signals s_1 to s_M to accordingly provide the signal sr1 at the node n1, wherein the number M may be an integer greater than or equal to one. The feedback circuit 1403 may be coupled between the node n2 and the adder 1402, and may provide the signals s_1 to s_M as feedback signals according to the signal sd1 at the node n2 and one or more predetermined coefficients h_1 to h_M. For example, in an embodiment, the feedback circuit 1403 may form the signal s_1 by multiplying the coefficient h_1 and a result of delaying the signal sd1 by one unit duration, may form the signal s_2 by multiplying the coefficient h_2 and a result of delaying the signal sd1 by two said unit durations, and may form the signal s_M by multiplying the coefficient h_M and a result of delaying the signal sd1 by number M of said unit durations, etc.; the unit duration may equal the period of the clock ck0. In an embodiment, the coefficient h_1 may be a positive value, the threshold level L1 may equal the coefficient h_1, and the threshold level L3 may equal a negative of the coefficient h_1 (i.e., −h_1).

Though not depicted, the circuit block 1400 shown in FIG. 14 may cooperate with the phase detection circuit block 220 and the clock circuit block 230 shown in FIG. 2a to implement the wireline receiver 100 shown in FIG. 1a. Along with the clock circuit block 230, the circuit block 1400 shown in FIG. 14 may also cooperate with the phase detection circuit block 320, 420, 520, 620, 720, 820, 920, 1020, 1120 or 1220 respectively shown in FIG. 3a, FIG. 4a, FIG. 5a, FIG. 6a, FIG. 7a, FIG. 8a, FIG. 9a, FIG. 10a, FIG. 11a or FIG. 12a to implement the wireline receiver 100 shown in FIG. 1a.

Similar to FIG. 3a, FIG. 4a, FIG. 9a or FIG. 10a, the circuit block 1400 shown in FIG. 14 may omit the sampler sa3 to cooperate with the phase detection circuit block 320, 420, 920 or 1020 respectively shown in FIG. 3a, FIG. 4a, FIG. 9a or FIG. 10a to implement the wireline receiver 100 shown in FIG. 1a along with the clock circuit block 230. Besides, similar to FIG. 5a, FIG. 6a, FIG. 11a or FIG. 12a, the circuit block 1400 may also omit the sampler sa1 to cooperate with the phase detection circuit block 520, 620, 1120 or 1220 respectively shown in FIG. 5a, FIG. 6a, FIG. 11a or FIG. 12a to implement the wireline receiver 100 shown in FIG. 1a along with the clock circuit block 230.

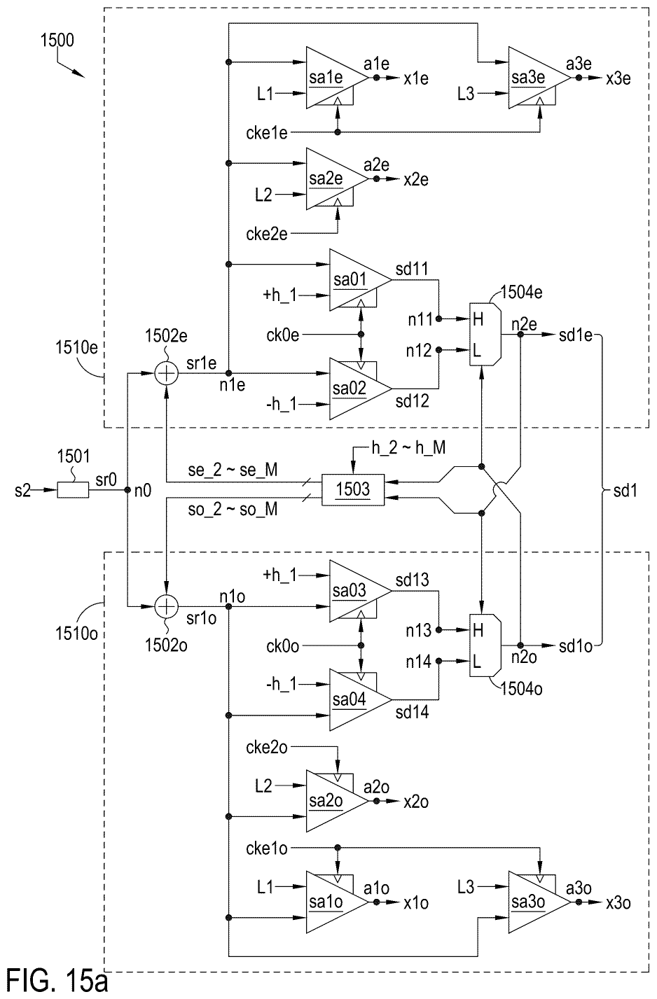

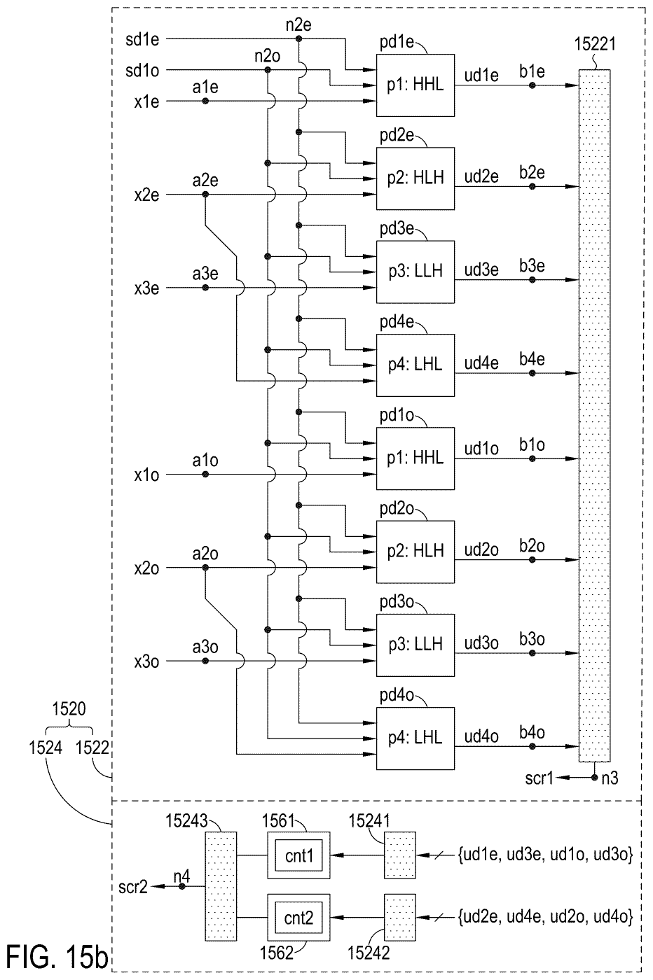

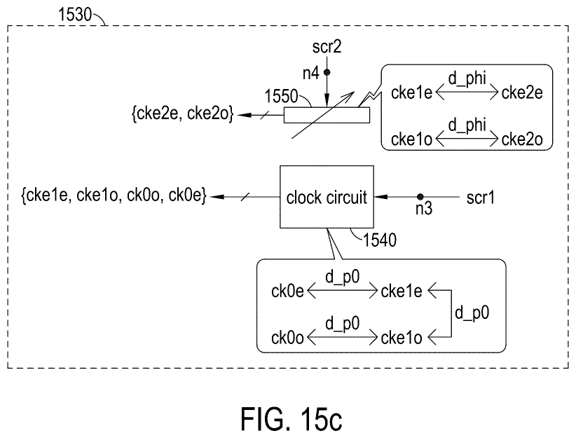

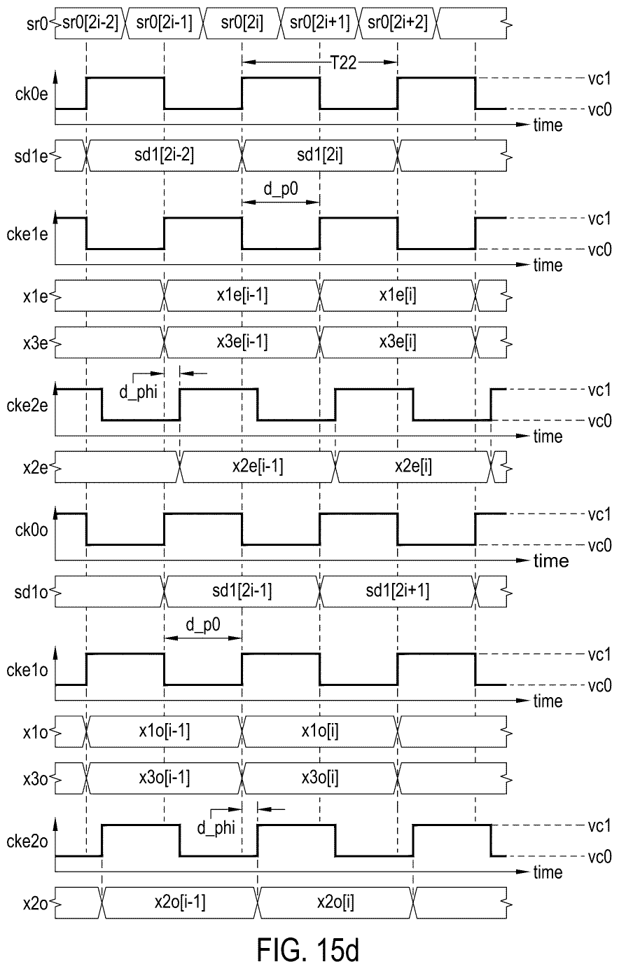

Following FIG. 1a, FIG. 2a and FIG. 14, FIG. 15a illustrates a circuit block 1500 according to an embodiment of the present disclosure, FIG. 15b illustrates a phase detection circuit block 1520 according to an embodiment of the present disclosure, FIG. 15c illustrates a clock circuit block 1530 according to an embodiment of the present disclosure, and FIG. 15d illustrates timing and waveform embodiments of related signals and clocks shown in FIG. 15a. The circuit block 1500 shown in FIG. 15a may implement the front-end circuit block 102 and the sampler block 110 shown in FIG. 1a by an architecture of a half-rate loop-unrolled decision feedback equalizer; in cooperation with the circuit block 1500, the phase detection circuit block 1520 shown in FIG. 15b and the clock circuit block 1530 shown in FIG. 15c may respectively implement the phase detection circuit block 120 and the clock circuit block 130 shown in FIG. 1a.

As shown in FIG. 15a, the circuit block 1500 may comprise a front-end circuit 1501, two adders 1502e and 1502o, a feedback circuit 1503, two multiplexers 1504e and 15040, and a plurality of samplers sa01 to sa04, sale to sa3e and sa1o to sa3o. The front-end circuit 1501 may be coupled between the received signal s2 and a node no, may comprise linear equalizer(s) and/or variable gain amplifier(s) (not depicted), and may perform signal process on the signal s2 to accordingly form a signal sr0 at the node n0. The adder 1502e may be coupled among the node n0, another node n1e and the feedback circuit 1503, may sum the signal sr0 and one or more signals se_2 to se_M, and may accordingly form a signal srle at the node n1e, wherein the number M may be an integer greater than or equal to two. The sampler sa01 may comprise a signal input terminal, a clock input terminal, a threshold level input terminal and an output terminal respectively coupled to the node n1e, a clock ck0e, a positive coefficient +h_1 and a node n11. The sampler sa02 may comprise a signal input terminal, a clock input terminal, a threshold level input terminal and an output terminal respectively coupled to the node n1e, the clock ck0e, a negative coefficient −h_1 (a negation of the positive coefficient h_1) and a node n12. The sampler sale may comprise a signal input terminal, a clock input terminal, a threshold level input terminal and an output terminal respectively coupled to the node n1e, a clock cke1e, a threshold level L1 and a node ale. The sampler sa2e may comprise a signal input terminal, a clock input terminal, a threshold level input terminal and an output terminal respectively coupled to the node nie, a clock cke2e, a threshold level L2 and a node a2e. The sampler sa3e may comprise a signal input terminal, a clock input terminal, a threshold level input terminal and an output terminal respectively coupled to the node n1e, the clock cke1e, a threshold level L3 and a node a3e. The multiplexer 1504e may comprise two signal input terminals, a control input terminal and an output terminal respectively coupled to the nodes n11, n12 and another two nodes node n2o and n2e.

In the circuit block 1500, the adder 1502o may be coupled among the node n0, another node n1o and the feedback circuit 1503, may sum the signal sr0 and one or more signals so_2 to so_M, and may accordingly form a signal sr1o at the node n1o. The sampler sa03 may comprise a signal input terminal, a clock input terminal, a threshold level input terminal and an output terminal respectively coupled to the node n1o, a clock ckOo, the positive coefficient +h_1 and a node n13. The sampler sa04 may comprise a signal input terminal, a clock input terminal, a threshold level input terminal and an output terminal respectively coupled to the node n1o, the clock ckOo, the negative coefficient −h_1 and a node n14. The sampler sa1o may comprise a signal input terminal, a clock input terminal, a threshold level input terminal and an output terminal respectively coupled to the node n1o, a clock cke1o, the threshold level L1 and a node a1o. The sampler sa2o may comprise a signal input terminal, a clock input terminal, a threshold level input terminal and an output terminal respectively coupled to the node n1o, a clock cke2o, the threshold level L2 and a node a2o. The sampler sa3o may comprise a signal input terminal, a clock input terminal, a threshold level input terminal and an output terminal respectively coupled to the node n1o, the clock cke1o, the threshold level L3 and a node a3o. The multiplexer 15040 may comprise two signal input terminals, a control input terminal and an output terminal respectively coupled to the nodes n13, n14, n2e and n2o.

In the circuit block 1500, the sample sa01 may, when triggered by the clock ck0e, sample and compare the signal sr1e to determine whether the signal sr1e exceeds the positive coefficient +h_1, and may accordingly provide a signal sd11 at the node n11. The sample sa02 may, when triggered by the clock ckle, sample and compare the signal sr1e to determine whether the signal sr1e exceeds the negative coefficient −h_1, and may accordingly provide a signal sd12 at the node n12. The sample sa03 may, when triggered by the clock ck0o, sample and compare the signal sr1o to determine whether the signal sr1o exceeds the positive coefficient +h_1, and may accordingly provide a signal sd13 at the node n13. The sample sa04 may, when triggered by the clock ck0o, sample and compare the signal sr1o to determine whether the signal sr1o exceeds the negative coefficient −h_1, and may accordingly provide a signal sd14 at the node n14.

In the circuit block 1500, the multiplexers 1504e and 15040 may respectively provide two signals sd1e and sd1o at the nodes n2e and n2o. When a signal value at the node n2o equals the definition value H, the multiplexer 1504e may conduct (electrically connect) the node n11 (instead of the node n12) to the node n2e; when the signal value at the node n2o equals the definition value L, the multiplexer 1504e may conduct the node n12 (instead of the node n11) to the node n2e. When a signal value at the node n2e equals the definition value H, the multiplexer 15040 may conduct (electrically connect) the node n13 (instead of the node n14) to the node n2o; when the signal value at the node n2e equals the definition value L, the multiplexer 15040 may conduct the node n14 (instead of the node n13) to the node n2o.

In the circuit block 1500, the adder 1502e, the samplers sa01, sa02, sa1e to sa3e and the multiplexer 1504e may constitute a circuit branch 1510e, which may discriminate even symbols (e.g., symbols sr0[2i−2] and sr0[2i] shown in FIG. 15d) of the signal sr0, and may accordingly provide the signal sd1e; signal values (e.g., consecutive signal values sd1[2i−2] and sd1[2i] shown in FIG. 15d) of the signal sd1e may therefore represent the even symbols discriminated from the signal sr0 by the circuit block 1500. On the other hand, in the circuit block 1500, the adder 1502o, the samplers sa03, sa04, sa1o to sa3o and the multiplexer 15040 may constitute another circuit branch 1510o, which may discriminate odd symbols (e.g., symbols sr0[2i−1] and sr0[2i+1] shown in FIG. 15d) of the signal sr0, and may accordingly provide the signal sd1o; signal values (e.g., consecutive signal values sd1[2i−1] and sd1[2i+1] shown in FIG. 15d) of the signal sd1o may therefore represent the odd symbols discriminated from the signal sr0 by the circuit block 1500. By integrating the signal values corresponding to the even symbols from the signal sd1e and the signal values corresponding to the odd symbols from the signals sd1o, a complete data signal sd1 may be formed, and signal values (e.g., signal values sd1[2i−2], sd1[2i−1], sd1[2i], sd1[2i+1]) of the data signal sd1 may represent the complete symbols discriminated from the signal sr0 by the circuit block 1500.

As shown in FIG. 15c, the clock circuit block 1530 may comprise a clock circuit 1540 and a phase shifting circuit 1550. The clock circuit 1540 may provide the clocks cke1e, cke1o, ck0e and ck0o according to a signal scr1; when providing the clocks cke1e, cke1o, ck0e and ck0o, the clock circuit 1540 may cause frequencies of the clocks cke1e, cke1o, ck0e and ckOo to be equal and to be controlled by the signal scr1, may cause a phase difference between the clocks ck0e and cke1e to equal a predetermined offset value d_p0, may cause a phase difference between the clocks ck0o and cke1o to equal the offset value d_p0, and may cause a phase difference between the clocks cke1e and cke1o to equal the offset value d_p0. In an embodiment, the offset value d_p0 may be 180 degrees; i.e., the clocks cke1e and ck0e may be inverted from each other, the clocks cke1o and ck0o may be inverted from each other, and the clocks cke1e and cke1o may be inverted from each other. The phase shifting circuit 1550 may provide the clocks cke2e and cke2o by performing phase shifting according to a signal scr2; when providing the clocks cke2e and cke2o, the phase shifting circuit 1550 may cause frequencies of the clocks cke1e and cke2e to be equal, and may cause a phase difference between the clocks cke2e and cke1e to equal an offset value d_phi; also, the phase shifting circuit 1550 may cause frequencies of the clocks cke1o and cke2o to be equal, and may cause a phase difference between the clocks cke2o and cke1o to equal the offset value d_phi, wherein the offset value d_phi may be controlled by the signal scr2.

As shown in FIG. 15d, each of the clocks ck0e, cke1e, cke2e, ck0o, cke1o and cke2o may be a periodic clock alternating between the two levels vc1 and vc0, and a period of these clocks may equal a period T22. Significant edges (edges changing from the levels vc0 to vc1) of the clocks cke1e and cke2e may track (reflect) edges of symbols of the signal sr1e, and significant edges of the clock ck0e may track (reflect) time-axis centers of symbols of the signal sr1e. Moreover, significant edges of the clocks cke1o and cke2o may track (reflect) edges of symbols of the signal sr1o, and significant edges of the clock ck0o may track (reflect) time axis centers of symbols of the signal sr1o.

In the circuit block 1500 shown in FIG. 15a, the feedback circuit 1503 may provide the signals se_2 to se_M and the signals so_2 to so_M according to the signals sd1e and sd1o, and one or coefficients h_2 to h_M; for example, the feedback circuit 1503 may form the signal se_2 by multiplying the coefficient h_2 and a result of delaying the signal sd1e by two unit intervals, may form the signal so_2 by multiplying the coefficient h_2 and a result of delaying the signal sd1o by two said unit intervals, may form the signal se_3 by multiplying the coefficient h_3 and a result of delaying the signal sd1o by four said unit intervals, and may form the signal so_3 by multiplying the coefficient h_3 and a result of delaying the signal sd1e by four said unit intervals, etc. A time span of two said unit intervals may equal the period T22 (FIG. 15d).

As shown in FIG. 15b, the phase detection circuit block 1520 may comprise two phase detection circuits 1522 and 1524, which may respectively be a base phase detection circuit and an additional phase detection circuit. The phase detection circuit 1522 may comprise a plurality of pattern phase detection units pd1e to pd4e and pd1o to pd4o, and an internal circuit 15221. The pattern phase detection unit pd1e may comprise two data input terminals, a signal input terminal and an output terminal respectively coupled to the nodes n2e, n2o, ale and another node b1e. The pattern phase detection unit pd2e may comprise two data input terminals, a signal input terminal and an output terminal respectively coupled to the nodes n2e, n2o, a2e and another node b2e. The pattern phase detection unit pd3e may comprise two data input terminals, a signal input terminal and an output terminal respectively coupled to the nodes n2e, n2o, a3e and another node b3e. The pattern phase detection unit pd4e may comprise two data input terminals, a signal input terminal and an output terminal respectively coupled to the nodes n2e, n2o, a2e and another node b4e. The pattern phase detection unit pd1o may comprise two data input terminals, a signal input terminal and an output terminal respectively coupled to the nodes n2e, n2o, a1o and another node b1o. The pattern phase detection unit pd2o may comprise two data input terminals, a signal input terminal and an output terminal respectively coupled to the nodes n2e, n2o, a2o and another node b2o. The pattern phase detection unit pd3o may comprise two data input terminals, a signal input terminal and an output terminal respectively coupled to the nodes n2e, n2o, a3o and another node b3o. The pattern phase detection unit pd4o may comprise two data input terminals, a signal input terminal and an output terminal respectively coupled to the nodes n2e, n2o, a2o and another node b4o. The pattern phase detection units pd1e to pd4e and pd1o to pd4o may provide signals ud1e to ud4e and ud1o to ud4o at the nodes b1e to b4e and b1o to b4o, respectively.

In response to a signal value x1e[i] (FIG. 15d) of the signal x1e, the pattern phase detection unit pd1e may compare whether three associated signal values sd1[2i−1], sd1[2i] and sd1[2i+1] of the signals sd1e and sd1o match the pattern p1, may assert a said speed-up message UP or a said speed-down message DN in the signal ud1e according to whether the signal value x1e[i] equals the definition value L or H if comparison of the pattern p1 matches, and may not assert anyone of the speed-up message UP and the speed down-down message DN in the signal ud1e if comparison of the pattern p1 does not match. In response to a signal value x2e[i] (FIG. 15d) of the signal x2e, the pattern phase detection unit pd2e may compare whether three associated signal values sd1[2i−1], sd1[2i] and sd1[2i+1] of the signals sd1e and sd1o match the pattern p2, may assert a said speed-up message UP or a said speed-down message DN in the signal ud2e according to whether the signal value x2e[i] equals the definition value H or L if comparison of the pattern p2 matches, and may not assert anyone of the speed-up message UP and the speed down-down message DN in the signal ud2e if comparison of the pattern p2 does not match. In response to a signal value x3e[i] (FIG. 15d) of the signal x3e, the pattern phase detection unit pd3e may compare whether three associated signal values sd1[2i−1], sd1[2i] and sd1[2i+1] of the signals sd1e and sd1o match the pattern p3, may assert a said speed-up message UP or a said speed-down message DN in the in the signal ud3e according to whether the signal value x3e[i] equals the definition value H or L if comparison of the pattern p3 matches, and may not assert anyone of the speed-up message UP and the speed down-down message DN in the signal ud3e if comparison of the pattern p3 does not match. In response to the signal value x2e[i] (FIG. 15d) of the signal x2e, the pattern phase detection unit pd4e may compare whether three associated signal values sd1[2i−1], sd1[2i] and sd1[2i+1] of the signals sd1e and sd1o match the pattern p4, may assert a said speed-up message UP or a said speed-down message DN in the in the signal ud4e according to whether the signal value x2e[i] equals the definition value L or H if comparison of the pattern p4 matches, and may not assert anyone of the speed-up message UP and the speed down-down message DN in the signal ud4e if comparison of the pattern p4 does not match.

In response to a signal value x1o[i] (FIG. 15d) of the signal x1o, the pattern phase detection unit pd1o may compare whether three associated signal values sd1[2i−2], sd1[2i−1] and sd1[2i] of the signals sd1e and sd1o match the pattern p1, may assert a said speed-up message UP or a said speed-down message DN in the signal ud1o according to whether the signal value x1o[i] equals the definition value L or H if comparison of the pattern p1 matches, and may not assert anyone of the speed-up message UP and the speed down-down message DN in the signal ud1o if comparison of the pattern p1 does not match. In response to a signal value x2o[i] (FIG. 15d) of the signal x2o, the pattern phase detection unit pd2o may compare whether three associated signal values sd1[2i−2], sd1[2i−1] and sd1[2i] of the signals sd1e and sd1o match the pattern p2, may assert a said speed-up message UP or a said speed-down message DN in the signal ud2o according to whether the signal value x2o[i] equals the definition value H or L if comparison of the pattern p2 matches, and may not assert anyone of the speed-up message UP and the speed down-down message DN in the signal ud2o if comparison of the pattern p2 does not match. In response to a signal value x3o[i] (FIG. 15d) of the signal x3o, the pattern phase detection unit pd3o may compare whether three associated signal values sd1[2i−2], sd1[2i−1] and sd1[2i] of the signals sd1e and sd1o match the pattern p3, may assert a said speed-up message UP or a said speed-down message DN in the signal ud3o according to whether the signal value x3o[i] equals the definition value H or L if comparison of the pattern p3 matches, and may not assert anyone of the speed-up message UP and the speed down-down message DN in the signal ud3o if comparison of the pattern p3 does not match. In response to the signal value x2o[i] (FIG. 15d) of the signal x2o, the pattern phase detection unit pd4o may compare whether three associated signal values sd1[2i−2], sd1[2i−1] and sd1[2i] of the signals sd1e and sd1o match the pattern p4, may assert a said speed-up message UP or a said speed-down message DN in the signal ud4o according to whether the signal value x2o[i] equals the definition value L or H if comparison of the pattern p4 matches, and may not assert anyone of the speed-up message UP and the speed down-down message DN in the signal ud4o if comparison of the pattern p4 does not match.

In the phase detection circuit 1522, the internal circuit 15221 may provide the signal scr1 at the node n3 according to the signals ud1e to ud4e and ud1o to ud4o. When a said speed-up message UP is asserted in either one of the signals ud1e to ud4e and ud1o to ud4o, the internal circuit 15221 may correspondingly assert a said speed-up message UP in the signal scr1; when a said speed-down message DN is asserted in either one of the signals ud1e to ud4e and ud1o to ud4o, the internal circuit 15221 may correspondingly assert a said speed-down message DN in signal scr1.

As shown in FIG. 15b, the phase detection circuit 1524 may comprise three internal circuits 15241, 15242 and 15243, as well as two counting circuits 1561 and 1562. When a said speed-up message UP is asserted in either one of the signals ud1e, ud3e, ud1o and ud3o, the internal circuit 15241 may cause the counting circuit 1561 to increment a count cnt1 by the step value d1; when a said speed-down message DN is asserted in either one of the signals ud1e, ud3e, ud1o and ud3o, the internal circuit 15241 may cause the counting circuit 1561 to decrement the count cnt1 by the step value d1. When none of the speed-up message UP and the speed-down message DN is asserted in anyone of the signals ud1e, ud3e, ud1o and ud3o, the internal circuit 15241 may cause the count cnt1 of the counting circuit 1561 to remain unchanged.

When a said speed-up message UP is asserted in either one of the signals ud2e, ud4e, ud2o and ud4o, the internal circuit 15242 may cause the counting circuit 1562 to increment another count cnt2 by the step value d1; when a said speed-down message DN is asserted in either one of the signals ud2e, ud4e, ud2o and ud4o, the internal circuit 15242 may cause the counting circuit 1562 to decrement the count cnt2 by the step value d1. When none of the speed-up message UP and the speed-down message DN is asserted in anyone of the signal ud2e, ud4e, ud2o and ud4o, the internal circuit 15242 may cause the count cnt2 of the counting circuit 1562 to remain unchanged. The internal circuit 15243 may determine statuses of the counts cnt1 and cnt2 respectively according to values of the counts cnt1 and cnt2, and may, via the signal scr2, control the offset value d_phi of the phase shifting circuit 1550 according to the statuses of the counts cnt1 and cnt2. When the count cnt1 is between the upper bound value c_U and the lower bound value c_D, its status may equal the status cnt_normal; when the count cnt1 is greater than the upper bound value c_U or less than the lower bound value c_D, its status may equal the status cnt_UP or cnt_DN. When the count cnt2 is between the upper bound value c_U and the lower bound value c_D, its status may equal the status cnt_normal; when the count cnt2 is greater than the upper bound value c_U or less than the lower bound value c_D, its status may equal the status cnt_UP or cnt_DN. As shown in FIG. 2e, when the statuses of the counts cnt1 and cnt2 respectively equal the statuses cnt_UP and cnt_DN, the internal circuit 15243 may, via the signal scr2, cause the offset value d_phi of the phase shifting circuit 1550 to increase, and may reset the counts cnt1 and cnt2 to the initial value c_0. When the statuses of the counts cnt1 and cnt2 respectively equal the statuses cnt_DN and cnt_UP, the internal circuit 15243 may, via the signal scr2, cause the offset value d_phi of the phase shifting circuit 1550 to decrease, and may reset the counts cnt1 and cnt2 to the initial value c_0. On occasions other than above two, the internal circuit 15243 may cause the offset value d_phi to remain unchanged, and may not reset the counts cnt1 and cnt2.

In an embodiment, the threshold levels L1 and L3 shown in FIG. 15a may respectively equal the positive coefficient +h_1 and the negative of the coefficient −h_1; besides, the clocks ck0e and cke1e may be inverted from each other, the clocks cke1o and cke1e may be inverted from each other, so phases of the clocks ck0e and cke1o may be same. From above two points, it is understood that operations of the samplers sa01 and sa02 and operations of the samplers sa1o and sa3o may be same, and thus the samplers sa1o and sa3o may be omitted; the signals x1o and x3o of the samplers sa1o and sa3o at the nodes a1o and a3o may be respectively replaced by the signals sd11 and sd12 of the samplers sa01 and sa02 at the nodes n11 and n12. Similarly, the sampler sale and sa3e may be omitted; the signals x1e and x3e of the samplers sale and sa3e at the nodes ale and a3e may be respectively replaced by the signals sd13 and sd14 of the samplers sa03 and sa04 at the nodes n13 and n14.

Though not depicted, the phase detection circuit 1522 shown in FIG. 15b may not include all the pattern phase detection units pd1e to pd4e and pd1o to pd4o; and/or, the phase detection circuit 1524 may not include both two of the internal circuits 15241 and 15242 and both two of the counting circuits 1561 and 1562. For example, in an embodiment not depicted, the phase detection circuit 1522 may include the pattern phase detection units pd1e to pd4e, but may not include the pattern phase detection units pd1o to pd4o; the internal circuit 15221 may not assert anyone of the speed-up message UP and the speed down-down message DN in the signal scr1 unless a said speed-up message UP or a said speed-down message DN is asserted in either one of the signals ud1e to ud4e. In cooperation with the simplified phase detection circuit 1522, the phase detection circuit 1524 may include all the internal circuits 15241 to 15243 and the counting circuits 1561 and 1562, wherein the internal circuit 15241 may not increment or decrement the count cnt1 by the step value d1 unless a said speed-up message UP or a said speed-down message DN is asserted in either one of the signals ud1e and ud3e, and the internal circuit 15242 may not increment or decrement the count cnt2 by the step value d1 unless a said speed-up message UP or a said speed-down message DN is asserted in either one of the signals ud2e and ud4e. In cooperation with the simplified phase detection circuit 1522, the phase detection circuit 1524 may also omit the internal circuit 15242 and the counting circuit 1562, similar to the phase detection circuit 724 shown in FIG. 7a. Moreover, in cooperation with the simplified phase detection circuit 1522, the phase detection circuit 1524 may omit the internal circuit 15241 and the counting circuit 1561, similar to the phase detection circuit 824 shown in FIG. 8a.

In an embodiment not depicted, the phase detection circuit 1522 may include the pattern phase detection units pd1e and pd2o, but may not include rest pattern phase detection units; the internal circuit 15221 may not assert anyone of the speed-up message UP and the speed down-down message DN in the signal scr1 unless a said speed-up message UP or a said speed-down message DN is asserted in either one of the signals ud1e and ud2o. In cooperation with such simplified phase detection circuit 1522, the phase detection circuit 1524 may include all the internal circuits 15241 to 15243 and the counting circuits 1561 and 1562, similar to the phase detection circuit 324 shown in FIG. 3a. Or the phase detection circuit 1524 may omit the internal circuit 15242 and the counting circuit 1562, similar to the phase detection circuit 924 shown in FIG. 9a. Or the phase detection circuit 1524 may omit the internal circuit 15241 and the counting circuit 1561, similar to the phase detection circuit 1024 shown in FIG. 10a.

To sum up, the wireline receiver of the present disclosure may utilize one or more first edge clocks (e.g., the clock cke1 in FIG. 2a, or the clocks cke1e and cke1o in FIG. 15a) and one or more second edge clocks (e.g., the clock cke2 in FIG. 2a, or the clock cke2e and cke2o in FIG. 15a) to track (reflect) edges between two symbols of one or more receiver signals (e.g., the signal sr1 in FIG. 2a, or the signals sr1e and sr1o resulting from the signal sr0 in FIG. 15a), and may utilize one or more reconstructed data clocks (e.g., the clock ck0 in FIG. 2a, or the clocks ck0e and ck0o in FIG. 15a) to discriminate symbols of the one or more receiver signals, so as to form a data signal (e.g., the signal sd1). Operations of the present disclosure may comprise: when triggered by a first edge clock, sampling and comparing a related receiver signal to determine whether the related receiver signal exceeds a low frequency pattern threshold level (e.g., the threshold level L1 or L3); in response to a result (e.g., the signal value x1[i] or x3[i] in FIG. 2b, or one of the signal values x1e[i], x3e[i], x1o[i] and x3o[i] in FIG. 15d) of the sampling and comparing, if a plurality of associated signal values (e.g., the signal values sd1[i−1] to sd1[i+1] in FIG. 2b, the signal values sd1[2i−1] to sd1[2i+1] in FIG. 15d, or the signal values sd1[2i−2] to sd1[2i] also in FIG. 15d) of the data signal match a plurality of component values of a low frequency pattern (e.g., the pattern p1 or p3), the present disclosure may determine whether a significant edge of the said first edge clock is earlier or later than a corresponding time when the related said receiver signal intersects the low frequency pattern threshold level, and may accordingly provide a first set of phase detection result (e.g., the first set of phase detection result may include at least one of the signals ud1 and ud3 in FIG. 2a, or at least one of the signals ud1e, ud3e, ud1o and ud3o in FIG. 15b). The first set of phase detection result may comprise speed-up message(s) and/or speed-down message(s), wherein a said speed-up message may indicate that a significant edge of a said first edge clock is later than a corresponding time when a related said receiver signal intersects the low frequency pattern threshold level, and a said speed-down message may indicate that a significant edge of a said first edge clock is earlier than a corresponding time when a related said receiver signal intersects the low frequency pattern threshold level.

Furthermore, operations of the present disclosure may also comprise: when triggered by a second edge clock, sampling and comparing a related receiver signal to determine whether the related receiver signal exceeds a high frequency pattern threshold level (e.g., the threshold level L2); in response to a result (e.g., the signal value x2[i] in FIG. 2b, or one of the signal values x2e[i] or x2o[i] in FIG. 15d) of the sampling and comparing, if a plurality of associated signal values (e.g., the signal values sd1[i−1] to sd1[i+1] in FIG. 2b, the signal values sd1[2i−1] to sd1[2i+1] in FIG. 15d, or the signal values sd1[2i−2] to sd1[2i] in FIG. 15d) of the data signal match a plurality of component values of a high frequency pattern (e.g., pattern p2 or p4), the present disclosure may determine whether a significant edge of the said second edge clock is earlier or later than a correspond time when the related said receiver signal intersects the high frequency pattern threshold level, and may accordingly provide a second set of phase detection result (e.g., the second set of phase detection result may include at least one of the signals ud2 and ud4 in FIG. 2a, or at least one of the signals ud2e, ud4e, ud2o and ud4o in FIG. 15d). The second set of phase detection result may comprise speed-up message(s) and/or speed-down message(s), wherein a said speed-up message may indicate that a significant edge of a said second edge clock is later than a corresponding time when a related said receiver signal intersects the high frequency pattern threshold level, and a said speed-down message may indicate that a significant edge of a said second edge clock is earlier than a corresponding time when a related said receiver signal intersects the high frequency pattern threshold level.

Based on aforementioned pattern phase detection, the present disclosure may adjust timing (frequency and/or phase) of the one or more first edge clocks, so significant edges of the one or more first edge clocks may correctly track edges of symbols of the low frequency pattern; also, the present disclosure may provide the one or more reconstructed data clocks according to the one or more first edge clocks, e.g., may cause a phase difference between each said data clock and its corresponding said first edge clock to equal a predetermined base offset value (e.g., the offset value d_p0). Based on aforementioned pattern phase detection, the present disclosure may also dynamically adjust an additional offset value (e.g., the offset value d_phi), and may provide the second edge clocks by phase shifting, such that a phase difference between each said second edge clock and its corresponding said first edge clock may equal the additional offset value.

When adjusting timing of the one or more first edge clocks, a principle of the timing adjustment may be: balancing between a total number of times the speed-up message occurs in both the first set of phase detection result and the second set of phase detection result, and a total number of times the speed-down message occurs in both the first set of phase detection result and the second set of phase detection result; for example, in both the first set of phase detection result and the second set of phase detection result, if the total number of times the speed-up message occurs is greater than the total number of times the speed-down message occurs by a difference exceeding a first tolerance value, the present disclosure may speed up timing (e.g., may increase frequency) of the first edge clock(s), so occurrence of the speed-up message may be lowered afterward; in both the first set of phase detection result and the second set of phase detection result, if the total number of times the speed-down message occurs is greater than the total number of time the speed-up message occurs by a difference exceeding a second tolerance value, the present disclosure may slow down timing (e.g., may decrease frequency) of the first edge clock(s), so occurrence of the speed-down message may be lowered afterward.

When dynamically adjusting the additional offset value of the second edge clock(s), if a number of times the speed-up message occurs in the first set of phase detection result is greater than a number of time the speed-down message occurs in the first set of phase detection result by a difference exceeding a first preset positive value, and/or a number of times the speed-down message occurs in the second set of phase detection result is greater than a number of times the speed-up message occurs in the second set of phase detection result by a difference exceeding a fourth preset positive value, then the present disclosure may increase the additional offset value; and, if the number of times the speed-down message occurs in the first set of phase detection result is greater than the number of times the speed-up message occurs in the first set of phase detection result by a difference exceeding a third preset positive value, and/or the total number of times the speed-up message occurs in the second set of phase detection result is greater than the number of times the speed-down message occurs in the second set of phase detection result by a difference exceeding a second preset positive value, then the present disclosure may decrease the additional offset value; on occasions other than the above two, the present disclosure may cause the additional offset value to remain unchanged.

Comparing to prior arts, the present disclosure may utilize two kinds of edge clocks to perform sampling and phase detection for reconstructing data clock(s) and obtaining two sets of phase detection results, may respectively apply two kinds of timing adjustments to cause the two kinds of edge clocks to be able to track edges of symbols of different data patterns, and may therefore cause the reconstructed data clock(s) to effectively approximate time axis center (e.g., the time point ts1 in FIG. 1b) of eye diagram, may reduce jitter, and may expand margins related to timing and margins related to signal value (margins along vertical axis of eye diagram).

While the present disclosure has been described in terms of what is presently considered to be the most practical and preferred embodiments, it is to be understood that the present disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wireline receiver with improved timing and related margins, comprising:
a data sampler configured for, when triggered by a data clock, sampling and comparing a receiver signal to determine whether the receiver signal exceeds a data threshold level, and accordingly contributing to forming of a data signal;
a first edge sampler configured for, when triggered by a first edge clock, sampling and comparing the receiver signal to determine whether the receiver signal exceeds a first threshold level, and accordingly providing a first edge signal;
a second edge sampler configured for, when triggered by a second edge clock, sampling and comparing the receiver signal to determine whether the receiver signal exceeds a second threshold level, and accordingly providing a second edge signal;
a base phase detection circuit, coupled to the data sampler, the first edge sampler and the second edge sampler, the base phase detection circuit being configured for providing a base timing control signal according to the data signal, the first edge signal and the second edge signal;
an additional phase detection circuit, configured for providing an additional timing control signal according to the data signal and at least one of the first edge signal and the second edge signal;
a clock circuit, coupled to the base phase detection circuit, the clock circuit being configured for providing the first edge clock and the data clock according to the base timing control signal, and causing a phase difference between the data clock and the first edge clock to equal a predetermined base offset value; and
a phase shifting circuit, coupled to the additional phase detection circuit, the phase shifting circuit being configured for providing the second edge clock by phase shifting, and causing a phase difference between the second edge clock and the first edge clock to equal an additional offset value; wherein:
the first threshold level and the second threshold level are different; and
the additional offset value is controlled by the additional timing control signal.

2. The wireline receiver of claim 1, wherein:
the base phase detection circuit comprises a first pattern phase detection unit; and
if the data signal matches a first pattern, then the first pattern phase detection unit is configured to assert a speed-up message or a speed-down message in the base timing control signal according to a current signal value of the first edge signal; if the data signal does not match the first pattern, the first pattern phase detection unit does not assert the speed-up message and the speed-down message in the base timing control signal.

3. The wireline receiver of claim 2, wherein:
if three consecutive signal values of the data signal equal a first definition value, the first definition value and a second definition value respectively, then the data signal matches the first pattern;
when the data signal matches the first pattern, if the current signal value of the first edge signal equals the second definition value, then the first pattern phase detection unit is configured to assert the speed-up message in the base timing control signal; otherwise, the first pattern phase detection unit is configured to assert the speed-down message in the base timing control signal.

4. The wireline receiver of claim 3, wherein:
if it is determined that the receiver signal exceeds the data threshold level, then the data sampler is configured to cause a current signal value of the data signal to equal the first definition value; otherwise, the data sampler is configured to cause the current signal value of the data signal to equal the second definition value.

5. The wireline receiver of claim 1, wherein:
the wireline receiver further comprises a third edge sampler;
the third edge sampler is configured to, when triggered by the first edge clock, sample and compare the receiver signal to determine whether the receiver signal exceeds a third threshold level, and accordingly provide a third edge signal;
the third threshold level differs from the first threshold level, and differs from the second threshold level;
when the base phase detection circuit provides the base timing control signal according to the data signal, the first edge signal and the second edge signal, the base phase detection circuit is configured to provide the base timing control signal according to the data signal, the first edge signal, the second edge signal and the third edge signal; and
when the additional phase detection circuit provides the additional timing control signal according to the data signal and at least one of the first edge signal and the second edge signal, the additional phase detection circuit is configured to provide the additional timing control signal according to the data signal and at least one of the first edge signal, the second edge signal and the third edge signal.

6. The wireline receiver of claim 5, wherein the second threshold level substantially equals an average of the first threshold level and the third threshold level.

7. The wireline receiver of claim 5, wherein:
the base phase detection circuit comprises a third pattern phase detection unit; and
if the data signal matches a third pattern, then the third pattern phase detection unit is configured to assert a speed-up message or a speed-down message in the base timing control signal according to a current signal value of the third edge signal; if the data signal does not match the third pattern, then the third pattern phase detection unit does not assert the speed-up message and the speed-down message in the base timing control signal.

8. The wireline receiver of claim 7, wherein:
if three consecutive signal values of the data signal equal a second definition value, the second definition value and a first definition value respectively, then the data signal matches the third pattern; and
when the data signal matches the third pattern, if the current signal value of the third edge signal equals the first definition value, then the third pattern phase detection unit is configured to assert the speed-up message in the base timing control signal; otherwise, the third pattern phase detection unit is configured to assert the speed-down message in the base timing control signal.

9. The wireline receiver of claim 1, wherein:
the base phase detection circuit comprises a second pattern phase detection unit; and
if the data signal matches a second pattern, then the second pattern phase detection unit is configured to assert a speed-up message or a speed-down message in the base timing control signal according to a current signal value of the second edge signal; if the data signal does not match the second pattern, the second pattern phase detection unit does not assert the speed-up message and the speed-down message in the base timing control signal.

10. The wireline receiver of claim 9, wherein:
if three consecutive signal values of the data signal equal a first definition value, a second definition value and the first definition value respectively, then the data signal matches the second pattern; and
when the data signal matches the second pattern, if the current signal value of the second edge signal equals the first definition value, then the second pattern phase detection unit is configured to assert the speed-up message in the base timing control signal; otherwise, the second pattern phase detection unit is configured to assert the speed-down message in the base timing control signal.

11. The wireline receiver of claim 1, wherein:
the base phase detection circuit comprises a fourth pattern phase detection unit; and
if the data signal matches a fourth pattern, then the fourth pattern phase detection unit is configured to assert a speed-up message or a speed-down message in the base timing control signal according to a current signal value of the second edge signal; if the data signal does not match the fourth pattern, the fourth pattern phase detection unit does not assert the speed-up message and the speed-down message in the base timing control signal.

12. The wireline receiver of claim 11, wherein:
if three consecutive signal values of the data signal equal a second definition value, a first definition value and the second definition value respectively, then the data signal matches the fourth pattern; and
when the data signal matches the fourth pattern, if the current signal value of the second edge signal equals the second definition value, then the fourth pattern phase detection unit is configured to assert the speed-up message in the base timing control signal; otherwise, the fourth pattern phase detection unit is configured to assert the speed-down message in the base timing control signal.

13. The wireline receiver of claim 1, wherein the data threshold level and the first threshold level are substantially equal.

14. The wireline receiver of claim 1, wherein the base offset value causes the data clock and the first edge clock to be orthogonal.

15. The wireline receiver of claim 1, wherein:
the additional phase detection circuit comprises a first counting circuit;
in response to a current signal value of the first edge signal, if three associated signal values of the data signal equal a first definition value, the first definition value and a second definition value respectively, then the data signal matches a first pattern;
when the data signal matches the first pattern and the current signal value of the first edge signal equals the second definition value, the first counting circuit is configured to increment a first speed-up accumulation count; when the data signal matches the first pattern and the current signal value of the first edge signal equals the first definition value, the first counting circuit is configured to increment a first speed-down accumulation count; when the data signal does not match the first pattern, the first counting circuit is configured to cause the first speed-up accumulation count and the first speed-down accumulation count to remain unchanged;
when the first speed-up accumulation count minus the first speed-down accumulation count exceeds a first preset positive value, the additional phase detection circuit is configured to cause the additional offset value to increase;
when the first speed-down accumulation count minus the first speed-up accumulation count exceeds a third preset positive value, the additional phase detection circuit is configured to cause the additional offset value to decrease; and
when the first speed-up accumulation count minus the first speed-down accumulation count does not exceed the first preset positive value, and the first speed-down accumulation count minus the first speed-up accumulation count does not exceed the third preset positive value, the additional phase detection circuit is configured to cause the additional offset value to remain unchanged.

16. The wireline receiver of claim 1, wherein:
the wireline receiver further comprises a third edge sampler;
the third edge sampler is configured to, when triggered by the first edge clock, sample and compare the receiver signal to determine whether the receiver signal exceeds a third threshold level, and accordingly provide a third edge signal;
the third threshold level differs from the first threshold level, and differs from the second threshold level;
the additional phase detection circuit comprises a first counting circuit;
in response to a current signal value of the first edge signal, if three associated signal values of the data signal equal a first definition value, the first definition value and a second definition value respectively, then the data signal matches a first pattern; if the three associated signal values of the data signal equal the second definition value, the second definition value and the first definition value respectively, then the data signal matches a third pattern;
when the data signal matches the first pattern and the current signal value of the first edge signal equals the second definition value, the first counting circuit is configured to increment a first speed-up accumulation count; when the data signal matches the first pattern and the current signal value of the first edge signal equals the first definition value, the first counting circuit is configured to increment a first speed-down accumulation count;
when the data signal matches the third pattern and a current value of the third edge signal equals the first definition value, the first counting circuit is configured to increment the first speed-up accumulation count; when the data signal matches the third pattern and the current signal value of the third edge signal equals the second definition value, the first counting circuit is configured to increments the first speed-down accumulation count;
when the data signal does not match the first pattern and does not match the third pattern, the first counting circuit is configured to cause the first speed-up accumulation count and the first speed-down accumulation count to remain unchanged;
when the first speed-up accumulation count minus the first speed-down accumulation count exceeds a first preset positive value, the additional phase detection circuit is configured to cause the additional offset value to increase;
when the first speed-down accumulation count minus the first speed-up accumulation count exceeds a third preset positive value, the additional phase detection circuit is configured to cause the additional offset value to decrease; and
when the first speed-up accumulation count minus the first speed-down accumulation count does not exceed the first preset positive value, and the first speed-down accumulation count minus the first speed-up accumulation count does not exceed the third preset positive value, the additional phase detection circuit is configured to cause the additional offset value to remain unchanged.

17. The wireline receiver of claim 1, wherein:
the additional phase detection circuit comprises a second counting circuit;
in response to a current signal value of the second edge signal, if three associated signal values of the data signal equal a first definition value, a second definition value and the first definition value respectively, then the data signal matches a second pattern;
when the data signal matches the second pattern and the current signal value of the second edge signal equals the first definition value, the second counting circuit is configured to increment a second speed-up accumulation count;
when the data signal matches the second pattern and the current signal value of the second edge signal equals the second definition value, the second counting circuit is configured to increment a second speed-down accumulation count; when the data signal does not match the second pattern, the second counting circuit is configured to cause the second speed-up accumulation count and the second speed-down accumulation count to remain unchanged;
when the second speed-up accumulation count minus the second speed-down accumulation count exceeds a second preset positive value, the additional phase detection circuit is configured to cause the additional offset value to decrease;
when the second speed-down accumulation count minus the second speed-up accumulation count exceeds a fourth preset positive value, the additional phase detection circuit is configured to cause the additional offset value to increase; and
when the second speed-up accumulation count minus the second speed-down accumulation count does not exceed the second preset positive value, and the second speed-down accumulation count minus the second speed-up accumulation count does not exceed the fourth preset positive value, the additional phase detection circuit is configured to cause the additional offset value to remain unchanged.

18. The wireline receiver of claim 1, wherein:
the additional phase detection circuit comprises a second counting circuit;
in response to a current signal value of the second edge signal, if three associated signal values of the data signal equal a first definition value, a second definition value and the first definition value respectively, then the data signal matches a second pattern; if the three associated signal values of the data signal equal the second definition value, the first definition value and the second definition value respectively, then the data signal matches a fourth pattern;
when the data signal matches the second pattern and the current signal value of the second edge signal equals the first definition value, the second counting circuit is configured to increment a second speed-up accumulation count;
when the data signal matches the second pattern and the current signal value of the second edge signal equals the second definition value, the second counting circuit is configured to increment a second speed-down accumulation count;
when the data signal matches the fourth pattern and the current signal value of the second edge signal equals the second definition value, the second counting circuit is configured to increment the second speed-up accumulation count; when the data signal matches the fourth pattern and the current signal value of the second edge signal equals the first definition value, the second counting circuit is configured to increment the second speed-down accumulation count;
when the data signal does not match the second pattern and does not match the fourth pattern, the second counting circuit is configured to cause the second speed-up accumulation count and the second speed-down accumulation count to remain unchanged;
when the second speed-up accumulation count minus the second speed-down accumulation count exceeds a second preset positive value, the additional phase detection circuit is configured to cause the additional offset value to decrease;
when the second speed-down accumulation count minus the second speed-up accumulation count exceeds a fourth preset positive value, the additional phase detection circuit is configured to cause the additional offset value to increase; and
when the second speed-up accumulation count minus the second speed-down accumulation count does not exceed the second preset positive value, and the second speed-down accumulation count minus the second speed-up accumulation count does not exceed the fourth preset positive value, the additional phase detection circuit is configured to cause the additional offset value to remain unchanged.

19. The wireline receiver of claim 1, wherein:
the additional phase detection circuit comprises a first counting circuit and a second counting circuit;
in response to a current signal value of the first edge signal, if three associated signal values of the data signal equal a first definition value, the first definition value and a second definition value respectively, then the data signal matches a first pattern;
when the data signal matches the first pattern and the current signal value of the first edge signal equals the second definition value, the first counting circuit is configured to increment a first speed-up accumulation count; when the data signal matches the first pattern and the current signal value of the first edge signal equals the first definition value, the first counting circuit is configured to increment a first speed-down accumulation count; when the data signal does not match the first pattern, the first counting circuit is configured to cause the first speed-up accumulation count and the first speed-down accumulation count to remain unchanged;
if the three associated signal values of the data signal equal a third definition value, a fourth definition value and the third definition value respectively, then the data signal matches a second pattern;
when the data signal matches the second pattern and the current signal value of the second edge signal equals the third definition value, the second counting circuit is configured to increment a second speed-up accumulation count; when the data signal matches the second pattern and the current signal value of the second edge signal equals the fourth definition value, the second counting circuit is configured to increment a second speed-down accumulation count; when the data signal does not match the second pattern, the second counting circuit is configured to cause the second speed-up accumulation count and the second speed-down accumulation count to remain unchanged;
when the first speed-up accumulation count minus the first speed-down accumulation count exceeds a first preset positive value, and the second speed-down accumulation count minus the second speed-up accumulation count exceeds a fourth preset positive value, the additional phase detection circuit is configured to cause the additional offset value to increase;
when the first speed-down accumulation count minus the first speed-up accumulation count exceeds a third preset positive value, and the second speed-up accumulation count minus the second speed-down accumulation count exceeds a second preset positive value, the additional phase detection circuit is configured to cause the additional offset value to decrease; and
when the first speed-down accumulation count minus the first speed-up accumulation count does not exceed the third preset positive value, or the first speed-up accumulation count minus the first speed-down accumulation count does not exceed the first preset positive value, or the second speed-up accumulation count minus the second speed-down accumulation count does not exceed the second preset positive value, or the second speed-down accumulation count minus the second speed-up accumulation count does not exceed the fourth preset positive value, the additional phase detection circuit is configured to cause the additional offset value to remain unchanged.

20. The wireline receiver of claim 1, wherein:
the wireline receiver further comprises a third edge sampler;
the additional phase detection circuit comprises a first counting circuit and a second counting circuit;
the third edge sampler is configured to, when triggered by the first edge clock, sample and compare the receiver signal to determine whether the receiver signal exceeds a third threshold level, and accordingly provide a third edge signal;
the third threshold level differs from the first threshold level, and differs from the second threshold level;
in response to a current signal value of the first edge signal, if three associated signal values of the data signal equal a first definition value, the first definition value and a second definition value respectively, then the data signal matches a first pattern; if the three associated signal values of the data signal equal the second definition value, the second definition value and the first definition value respectively, then the data signal matches a third pattern;
when the data signal matches the first pattern and the current signal value of the first edge signal equals the second definition value, the first counting circuit is configured to increment a first speed-up accumulation count; when the data signal matches the first pattern and the current signal value of the first edge signal equals the first definition value, the first counting circuit is configured to increment a first speed-down accumulation count; when the data signal matches the third pattern and a current signal value of the third edge signal equals the first definition value, the first counting circuit is configured to increment the first speed-up accumulation count; when the data signal matches the third pattern and the current signal value of the third edge signal equals the second definition value, the first counting circuit is configured to increment the first speed-down accumulation count;
when the data signal does not match the first pattern and does not match the third pattern, the first counting circuit is configured to cause the first speed-up accumulation count and the first speed-down accumulation count to remain unchanged;
if the three associated signal values of the data signal equal the first definition value, the second definition value and the first definition value respectively, then the data signal matches a second pattern; if the three associated signal values of the data signal equal the second definition value, the first definition value and the second definition value respectively, then the data signal matches a fourth pattern;
when the data signal matches the second pattern and a current signal value of the second edge signal equals the first definition value, the second counting circuit is configured to increment a second speed-up accumulation count;
when the data signal matches the second pattern and the current signal value of the second edge signal equals the second definition value, the second counting circuit is configured to increment a second speed-down accumulation count; when the data signal matches the fourth pattern and the current signal value of the second edge signal equals the second definition value, the second counting circuit is configured to increment the second speed-up accumulation count; when the data signal matches the fourth pattern and the current signal value of the second edge signal equals the first definition value, the second counting circuit is configured to increment the second speed-down accumulation count;
when the data signal does not match the second pattern and does not match the fourth pattern, the second counting circuit is configured to cause the second speed-up accumulation count and the second speed-down accumulation count to remain unchanged;
when the first speed-up accumulation count minus the first speed-down accumulation count exceeds a first preset positive value, and the second speed-down accumulation count minus the second speed-up accumulation count exceeds a fourth preset positive value, the additional phase detection circuit is configured to cause the additional offset value to increase;
when the first speed-down accumulation count minus the first speed-up accumulation count exceeds a third preset positive value, and the second speed-up accumulation count minus the second speed-down accumulation count exceeds a second preset positive value, the additional phase detection circuit is configured to cause the additional offset value to decrease; and
when the first speed-down accumulation count minus the first speed-up accumulation count does not exceed the third preset positive value, or the first speed-up accumulation count minus the first speed-down accumulation count does not exceed the first preset positive value, or the second speed-up accumulation count minus the second speed-down accumulation count does not exceed the second preset positive value, or the second speed-down accumulation count minus the second speed-up accumulation count does not exceed the fourth preset positive value, the additional phase detection circuit is configured to cause the additional offset value to remain unchanged.
